(19) United States
(12) Patent Application Publication
(10) Pub. No.: US 2026/0013395 A1
(43) Pub. Date: Jan. 8, 2026

(54) DISPLAY DEVICE AND ELECTRONIC DEVICE INCLUDING THE DISPLAY DEVICE

(71) Applicant: Samsung Display Co., Ltd., Yongin-si (KR)

(72) Inventors: HEEJIN KIM, Yongin-si (KR); SEULONG KIM, Yongin-si (KR); HYOUNGKUN KIM, Yongin-si (KR); HYERIM KIM, Yongin-si (KR); JIHYUN SEO, Yongin-si (KR); HANBYUL JANG, Yongin-si (KR); JAHYUN IM, Yongin-si (KR)

(21) Appl. No.: 19/257,122

(22) Filed: Jul. 1, 2025

(30) Foreign Application Priority Data
Jul. 5, 2024 (KR) 10-2024-0089244

(51) Int. Cl. H10K 85/60; C09K 11/02; C09K 11/06; H10K 50/12; H10K 59/35; H10K 85/30

(52) U.S. Cl. CPC H10K 85/6572; C09K 11/02; C09K 11/06; H10K 85/342; H10K 85/615; H10K 85/654; H10K 85/6574; H10K 85/658; C09K 2211/1007; C09K 2211/1014; C09K 2211/1022; C09K 2211/1029; C09K 2211/185; H10K 50/12; H10K 59/353

(57) ABSTRACT

A display device and an electronic device including the display device are disclosed. The display device may include first to third light emitting elements that correspond to first to third emission areas, respectively. Each of the first to third light emitting elements may include a first electrode, a second electrode opposite to the first electrode, a first emission unit provided between the first electrode and the second electrode and including a first emission layer, a charge generation layer provided on the first emission unit and including a p-type charge generation layer and an n-type charge generation layer, and a second emission unit provided on the charge generation layer and including a second emission layer. In at least two selected from among the first to third light emitting elements, the first emission layer and the second emission layer may each include a first light emitting material including a deuterium atom.

### CROSS-REFERENCE TO RELATED APPLICATIONS

The present application claims priority to and the benefit of Korean Patent Application No. 10-2024-0089244, filed on Jul. 5, 2024, in the Korean Intellectual Property Office, the entire disclosure of which is incorporated herein by reference.

### BACKGROUND

### 1. Field

One or more embodiments of the present disclosure relate to a display device and an electronic device including the display device, and, for example, to a display device including a light emitting element having a tandem structure and an electronic device including the display device.

### 2. Description of the Related Art

An organic light emitting element is a self-emissive type (or kind) element that has a fast response speed and is operated at a low voltage. Accordingly, a separate light source may not be provided in an organic light emitting display device including the organic light emitting element, and thus there are one or more advantages, for example, a small weight and a thin profile may be achieved, luminance is excellent or suitable, and no viewing angle dependency is found.

The organic light emitting element is an element that has an emission layer including an organic substance between an anode electrode and a cathode electrode. Holes provided from the anode electrode and electrons provided from the cathode electrode are combined with each other in the emission layer to form excitons, and then light that corresponds to energy between the holes and the electrons is generated from the excitons.

A tandem organic light emitting element has a structure in which a plurality of (e.g., two or more) stacks each including a hole transport layer/an emission layer/an electron transport layer are provided between an anode electrode and a cathode electrode, and a charge generation layer that assists generation and movement of charges is present in each space between the stacks.

### SUMMARY

One or more aspects of embodiments of the present disclosure are directed toward a display device including a light emitting element having improved or enhanced lifespan to have excellent or suitable display quality and an electronic device including the display device.

Additional aspects of embodiments will be set forth in part in the description which follows and, in part, will be apparent from the description or may be learned by practice of the presented embodiments of the disclosure.

One or more embodiments of the present disclosure provide a display device including a display element layer including a first emission area which emits light of a first color, a second emission area which emits light of a second color having a shorter wavelength than the first color, and a third emission area which emits light of a third color having a shorter wavelength than the second color, the first emission area, the second emission area, and the third emission area being spaced apart from each other on a plane (e.g., in a plan view). The display element layer may include a first light emitting element, a second light emitting element, and a third light emitting element that correspond to the first emission area, the second emission area, and the third emission area, respectively, and each of the first light emitting element, the second light emitting element, and the third light emitting element may include a first electrode, a second electrode that is opposite to (e.g., faces) the first electrode, a first emission unit disposed or provided between the first electrode and the second electrode and including a first emission layer, a charge generation layer disposed or provided on the first emission unit and including a positive type (or kind) (p-type or kind) charge generation layer and a negative type (or kind) (n-type or kin) charge generation layer, and a second emission unit disposed or provided on the charge generation layer and including a second emission layer. In at least two selected from among the first light emitting element, the second light emitting element, and the third light emitting element, the first emission layer and the second emission layer may each include a first light emitting material including a deuterium atom.

In one or more embodiments, the first light emitting element may emit red light of the first color, the second light emitting element may emit green light of the second color, the third light emitting element may emit blue light of the third color, the first emission layer and the second emission layer of the first light emitting element may not include the first light emitting material, and the first emission layer and the second emission layer of each of the second light emitting element and the third light emitting element may each include the first light emitting material.

In one or more embodiments, the first light emitting material may include at least one selected from among a first compound and/or a second compound. The first compound may include a deuterium atom, a carbazole moiety, and a nitrogen-containing moiety, and the second compound may include a deuterium atom and an anthracene moiety.

In one or more embodiments, the first emission layer may include a first red emission layer, a first green emission layer, and a first blue emission layer which correspond to the first emission area, the second emission area, and the third emission area, respectively, and the second emission layer may include a second red emission layer, a second green emission layer, and a second blue emission layer which correspond to the first emission area, the second emission area, and the third emission area, respectively. Each of the first green emission layer and the second green emission layer may include the first compound, and each of the first blue emission layer and the second blue emission layer may include the second compound.

In one or more embodiments, the first compound may be represented by Formula 1 to be described in one or more embodiments.

In one or more embodiments, the first compound may be represented by any one selected from among the compounds in Compound Group 1 to be described in one or more embodiments.

In one or more embodiments, a deuterium substitution rate of the first compound may be about 10% to about 100%.

In one or more embodiments, the second compound may be represented by Formula 2 to be described in one or more embodiments.

In one or more embodiments, the second compound may be represented by any one selected from among the compounds in Compound Group 2 to be described in one or more embodiments.

In one or more embodiments, a deuterium substitution rate of the second compound may be about 3% to about 100%.

In one or more embodiments, the first emission unit may further include a first hole transport region disposed or provided between the first electrode and the first emission layer and a first electron transport region disposed or provided between the first emission layer and the charge generation layer, and the second emission unit may further include a second hole transport region disposed or provided between the charge generation layer and the second emission layer and a second electron transport region disposed or provided between the second emission layer and the second electrode.

In one or more embodiments, each of the first hole transport region and the second hole transport region may include at least one selected from among a hole injection layer, a hole transport layer, an emission auxiliary layer, and/or an electron blocking layer.

In one or more embodiments, the first hole transport region may include a first hole injection layer, a first hole transport layer, and a first emission auxiliary layer which are disposed or provided in sequence on the first electrode, and the second hole transport region may include a second hole transport layer and a second emission auxiliary layer which are disposed or provided in sequence on the charge generation layer.

In one or more embodiments, each of the first hole injection layer, the first hole transport layer, and the second hole transport layer may be provided as a common layer on the first emission area, the second emission area, and the third emission area. The first emission auxiliary layer may include a first red emission auxiliary layer, a first green emission auxiliary layer, and a first blue emission auxiliary layer which correspond to the first emission area, the second emission area, and the third emission area, respectively, and the second emission auxiliary layer may include a second red emission auxiliary layer, a second green emission auxiliary layer, and a second blue emission auxiliary layer which correspond to the first emission area, the second emission area, and the third emission area, respectively. Each of the first green emission auxiliary layer, the second green emission auxiliary layer, the first blue emission auxiliary layer, and the second blue emission auxiliary layer may include the first light emitting material.

In one or more embodiments, each of the first green emission auxiliary layer and the second green emission auxiliary layer may include a first compound including a deuterium atom, a carbazole moiety, and a nitrogen-containing moiety, and each of the first blue emission auxiliary layer and the second blue emission auxiliary layer may include a second compound including a deuterium atom and an anthracene moiety.

In one or more embodiments, each of the first electron transport region and the second electron transport region may include at least one selected from among an electron injection layer, an electron transport layer, and/or a hole blocking layer.

In one or more embodiments, the first electron transport region may include a first electron transport layer, and the second electron transport region may include a second electron transport layer and a second electron injection layer which are disposed or provided in sequence.

In one or more embodiments, the n-type charge generation layer may be disposed or provided adjacent to the first emission unit, and the p-type charge generation layer may be disposed or provided adjacent to the second emission unit.

In one or more embodiments, at least one selected from the first emission layer and/or the second emission layer may further include at least one selected from among a compound represented by Formula HT-1, a compound represented by Formula ET-1, and/or a compound represented by Formula D-1.

In one or more embodiments, at least one selected from the first emission layer and/or the second emission layer may further include a compound represented by any one selected from among Formulae F-a to F-c.

In one or more embodiments of the present disclosure, a display device includes a display element layer including a red emission area, a green emission area, and a blue emission area which are disposed or provided apart from each other on a plane (e.g., in a plan view). The display element layer may include a first light emitting element, a second light emitting element, and a third light emitting element that correspond to the red emission area, the green emission area, and the blue emission area, respectively, and each of the first light emitting element, the second light emitting element, and the third light emitting element may include n emission units and n-1 charge generation layers, each of the n−1 charge generation layers is disposed or provided between the n emission units. n may be an integer of 2 or more, each of the n emission units may include a hole transport region, an emission layer, and an electron transport region, and each of the emission layer that corresponds to the green emission area and the emission layer that corresponds to the blue emission area may include a first light emitting material including a deuterium atom.

According to one or more embodiments, an electronic device includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a plan view of a display device according to one or more embodiments of the present disclosure;

FIG. 2 is a cross-sectional view of a display device according to one or more embodiments of the present disclosure;

FIGS. 3A-3D are each a schematic cross-sectional view illustrating a light emitting element according to one or more embodiments of the present disclosure;

FIG. 4 is a schematic cross-sectional view illustrating a light emitting element according to one or more embodiments of the present disclosure;

FIG. 5 is a view illustrating a vehicle in which a display device is disposed or provided according to one or more embodiments of the present disclosure;

FIG. 6A is a graph illustrating lifespan evaluation results for Example 1-1 and Comparative Example 1-1; and

FIG. 6B is a graph illustrating lifespan evaluation results for Example 2-1 and Comparative Example 2-1.

### DETAILED DESCRIPTION

The subject matter of the present disclosure will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete, and will fully convey the aspects and features of the present disclosure to those skilled in the art.

Like reference numbers or symbols refer to like elements in the drawings. In the drawings, the dimensions of layers and regions may be exaggerated for clarity of illustration.

It will be understood that, although the terms “first,” “second,” and/or the like may be used herein to describe one or more suitable elements, these elements should not be limited by these terms. These terms are only used to distinguish one element from another element. For example, a first element may be termed a second element without departing from the spirit and scope of the present disclosure, and similarly, a second element may be termed a first element.

As used herein, the singular forms are intended to include the plural forms as well, unless the context clearly indicates otherwise.

It will be further understood that the terms, such as “includes,” “has,” “including,” or “having,” if (e.g., when) used herein, specify the presence of stated features, numerals, steps, operations, elements, parts, or the combination thereof, but do not preclude the presence or addition of one or more other features, numerals, steps, operations, elements, parts, or the combination thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a part, such as a layer, a film, a region, or a plate, is referred to as being “on” or “above” another part, it may be directly on the other part, or an intervening layer may also be present therebetween. In contrast, if (e.g., when) an element, such as a layer, a film, a region, or a plate, is referred to as being “below” or “under” another part, it may be directly below the other element, or an intervening element may also be present therebetween. In one or more embodiments, if (e.g., when) an element is referred to as being “on” another element, it may be disposed or provided below the other element.

As used herein, the term “substituted or unsubstituted” may indicate that one is substituted or unsubstituted with at least one substituent selected from the group consisting of a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the substituents presented as an example herein may be substituted or unsubstituted. For example, a biphenyl group may be interpreted as an aryl group or as a phenyl group substituted with a phenyl group.

As used herein, the term “bonded to an adjacent group to form a ring” may indicate that one is bonded to an adjacent group to form a substituted or unsubstituted hydrocarbon ring or a substituted or unsubstituted heterocycle. The hydrocarbon ring includes an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In one or more embodiments, the rings formed by being bonded to each other may be linked to another ring to form a spiro structure.

As used herein, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In one or more embodiments, two methyl groups in 4,5-dimethylphenanthrene may be interpreted as mutually “adjacent groups”.

As used herein, examples of a halogen atom may include a fluorine atom, a chlorine atom, a bromine atom, and an iodine atom.

As used herein, an alkyl group may be linear or branched. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, a 3-methylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but are not limited thereto.

As used herein, a cycloalkyl group may refer to a cyclic alkyl group. The number of carbon atoms in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but are not limited thereto.

As used herein, an alkenyl group refers to a hydrocarbon group including at least one carbon double bond in the middle or end of an alkyl group having 2 or more carbon atoms. The alkenyl group may be linear or branched. The number of carbon atoms is not particularly limited, but may be 2 to 30, 2 to 20, or 2 to 10. Examples of the alkenyl group may include a vinyl group, a 1-butenyl group, a 1-pentenyl group, a 1,3-butadienyl group, a styrenyl group, a styryl vinyl group, and/or the like, but are not limited thereto.

As used herein, an alkynyl group refers to a hydrocarbon group including at least one carbon triple bond in the middle or end of an alkyl group having 2 or more carbon atoms. The alkynyl group may be linear or branched. The number of carbon atoms is not particularly limited, but may be 2 to 30, 2 to 20, or 2 to 10. Examples of the alkynyl group may include an ethynyl group, a propynyl group, and/or the like, but are not limited thereto.

As used herein, a hydrocarbon ring group refers to any suitable functional group or substituent derived from an aliphatic hydrocarbon ring. The hydrocarbon ring group may be a saturated hydrocarbon ring group having 5 to 20 ring-forming carbon atoms.

As used herein, an aryl group refers to any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenylyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but are not limited thereto.

As used herein, a fluorenyl group may be substituted, and two substituents may be bonded to each other to form a spiro structure. An example that the fluorenyl group is substituted is as follows. However, embodiments of the present disclosure are not limited thereto.

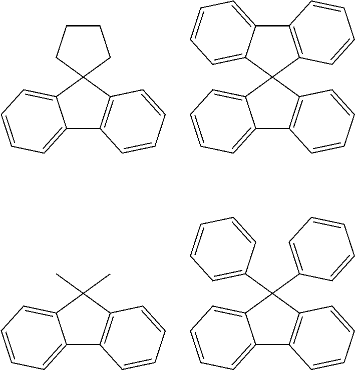

As used herein, a heterocyclic group refers to any suitable functional group or substituent derived from a ring containing at least one selected from among B, O, N, P, Si, and/or S as a hetero atom. The heterocyclic group may include an aliphatic heterocyclic group and an aromatic heterocyclic group. The aromatic heterocyclic group may be a heteroaryl group. The aliphatic heterocycle and the aromatic heterocycle may be monocyclic or polycyclic.

As used herein, the heterocyclic group may contain at least one selected from among B, O, N, P, Si, and/or S as a hetero atom. If (e.g., when) the heterocyclic group contains two or more hetero atoms, the two or more hetero atoms may be the same as or different from each other. The heterocyclic group may be a monocyclic heterocyclic group or a polycyclic heterocyclic group and include a heteroaryl group. The number of ring-forming carbon atoms in the heterocyclic group may be 2 to 30, 2 to 20, or 2 to 10.

As used herein, an aliphatic heterocyclic group may contain at least one selected from among B, O, N, P, Si, and/or S as a hetero atom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but are not limited to thereto.

As used herein, a heteroaryl group may contain at least one selected from among B, O, N, P, Si, and/or S as a hetero atom. If (e.g., when) the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a leucoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but are not limited thereto. In addition to the benzothiophene group and/or the like, the heteroaryl group containing S as a hetero atom may include a thienopyridine group, a thienopyrimidine group, a thienopyridazine group, a thienopyrazine group, a thienotriazine group, a thienotetrazine group, a thiazolopyridine group, a thiazolopyrimidine group, a thiazolopyridazine group, a thiazolopyrazine group, a thiazolotriazine group, a thiazolotetrazine group, a benzothiadiazole group, a thiadiazolepyridine group, a thiadiazolepyrimidine group, a thiadiazolepyridazine group, a thiadiazolepyrazine group, a thiadiazoletriazine group, a thiadiazoletetrazine group, and/or the like.

As used herein, the description of the aryl group as provided in one or more embodiments may be applied to an arylene group, except that the arylene group is a divalent group. The description of the heteroaryl group as provided in one or more embodiments may be applied to a heteroarylene group, except that the heteroarylene group is a divalent group.

As used herein, a silyl group may include an alkyl silyl group and an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but are not limited thereto.

As used herein, the number of carbon atoms in a carbonyl group is not particularly limited, but may be 1 to 40, 1 to 30, or 1 to 20. For example, the carbonyl group may have the following structure, but is not limited thereto.

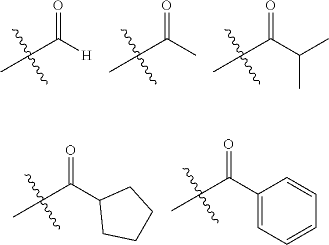

As used herein, the number of carbon atoms in a sulfinyl group and a sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

As used herein, a thio group may include an alkyl thio group and an aryl thio group. The thio group may indicate the one that a sulfur atom is bonded to an alkyl group or an aryl group as defined in one or more embodiments. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but are not limited to thereto.

As used herein, an oxy group may indicate the one that an oxygen atom is bonded to an alkyl group or aryl group as defined in one or more embodiments. The oxy group may include an alkoxy group and an aryl oxy group. The alkoxy group may be linear, branched, or cyclic. The number of carbon atoms in the alkoxy group is not particularly limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but are not limited thereto.

As used herein, a boron group may refer to one that a boron atom is bonded to an alkyl group or aryl group as defined in one or more embodiments. The boron group may include an alkyl boron group and an aryl boron group. Examples of the boron group may include a dimethyl boron group, a diethyl boron group, a t-butyl methyl boron group, a diphenyl boron group, a phenyl boron group, and/or the like, but are not limited thereto.

As used herein, the number of carbon atoms in an amine group is not particularly limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but are not limited thereto.

As used herein, the examples of the alkyl group as provided in one or more embodiments may also apply to an alkyl group of an alkylthio group, an alkyl sulfoxy group, an alkylaryl group, an alkyl boron group, an alkyl silyl group, and an alkyl amine group.

As used herein, the examples of the aryl group as provided in one or more embodiments may also apply to an aryl group of an aryloxy group, an arylthio group, an aryl sulfoxy group, an aryl boron group, an aryl silyl group, and an aryl amine group.

As used herein, a direct linkage may refer to a single bond (e.g., a single covalent bond).

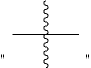

In one or more embodiments, in the present description, and “-*” each represents a position to be linked.

Hereinafter, one or more embodiments of the present disclosure will be described in more detail with reference to the accompanying drawings.

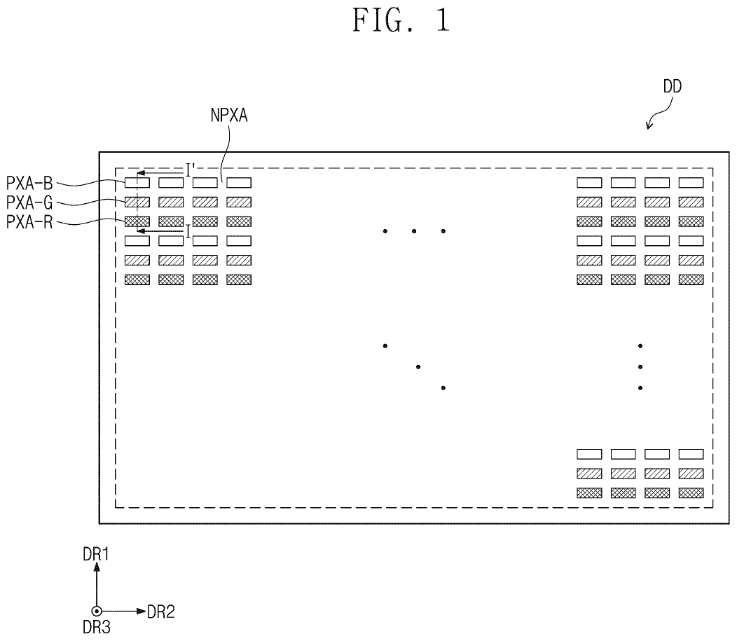

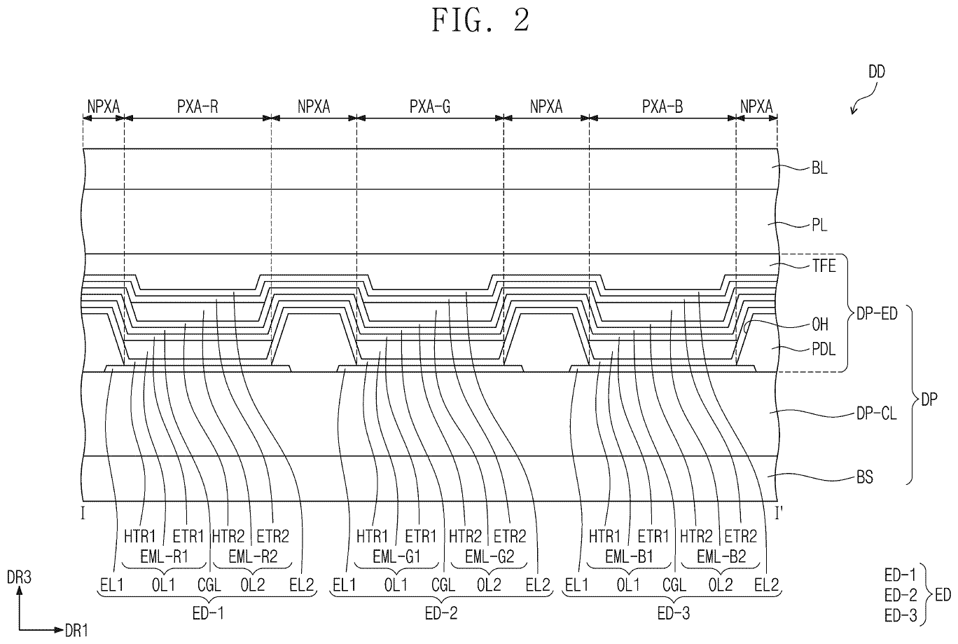

FIG. 1 is a plan view illustrating a display device DD according to one or more embodiments. FIG. 2 is a cross-sectional view of the display device DD according to one or more embodiments. FIG. 2 is a cross-sectional view illustrating a portion that corresponds to the line I-I′ in FIG. 1.

The display device DD may include a display panel DP and an optical layer PL disposed or provided on the display panel DP. The display panel DP may include a light emitting element ED. The display panel DP may include a plurality of light emitting elements ED-1, ED-2, and ED-3. The optical layer PL may be disposed or provided on the display panel DP and control reflected light from the display panel DP due to external light. The optical layer PL may, for example, include a polarizing layer or include a color filter layer. In one or more embodiments, the optical layer PL may not be provided in the display device DD according to one or more embodiments.

A base substrate BL may be disposed or provided on the optical layer PL. The base substrate BL may be a member that provides a base surface on which the optical layer PL is disposed or provided. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be disposed or provided between a display element layer DP-ED and the base substrate BL. The filling layer may be an organic material layer. The filling layer may include at least one selected from among an acryl-based resin, a silicone-based resin, and/or an epoxy-based resin.

The display panel DP may include a base layer BS and a circuit layer DP-CL and the display element layer DP-ED which are provided on the base layer BS. The display element layer DP-ED may include pixel defining films PDL, the light emitting elements ED-1, ED-2, and ED-3 disposed or provided between the pixel defining films PDL, and an encapsulation layer TFE disposed or provided on the light emitting elements ED-1, ED-2, and ED-3.

The base layer BS may be a member that provides a base surface on which the display element layer DP-ED is disposed or provided. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

1 In one or more embodiments, the circuit layer DP-CL may be disposed or provided on the base layer BS, and the circuit layer DP-CL may include a plurality of transistors. The transistors may each include a control electrode, an input electrode, and an output electrode. For example, the circuit layer DP-CL may include a switching transistor and a driving transistor to drive the light emitting elements ED-1, ED-2, and ED-3 of the display element layer DP-ED.

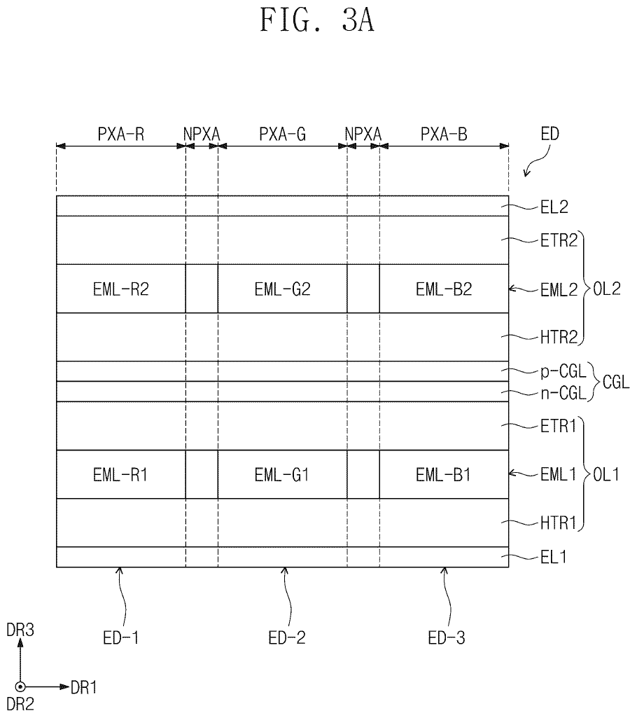

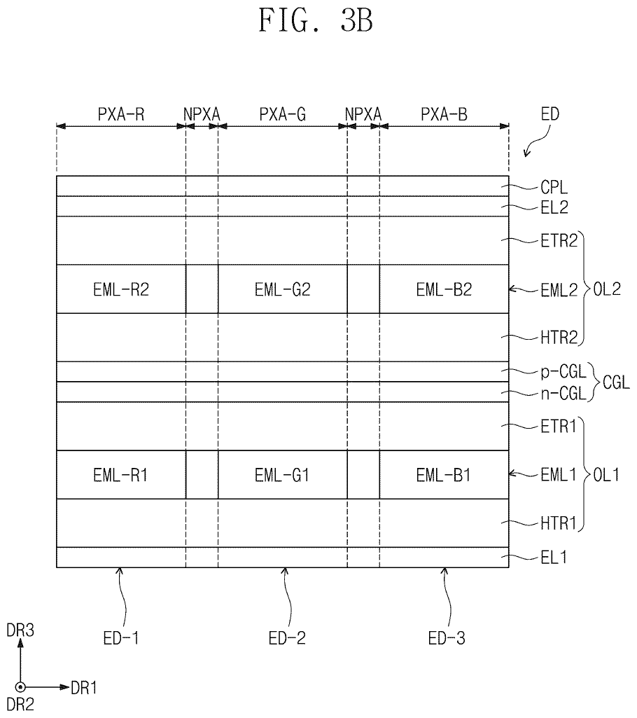

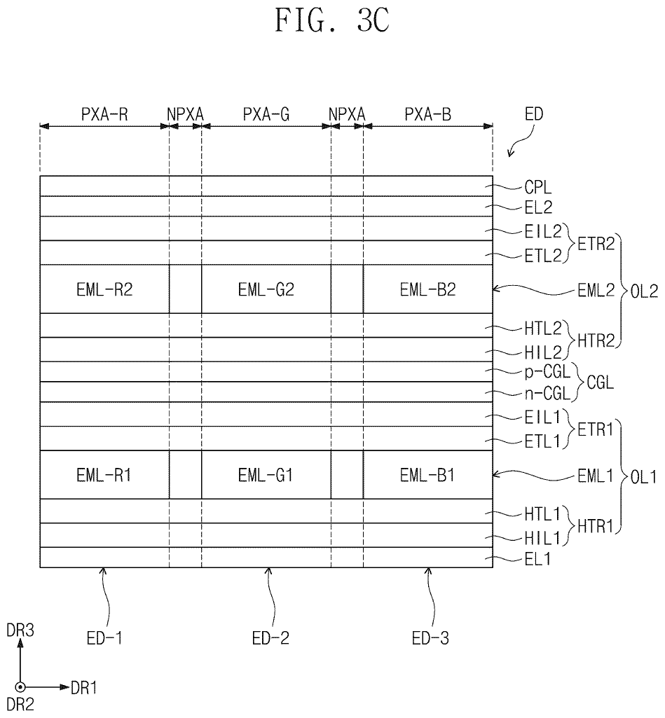

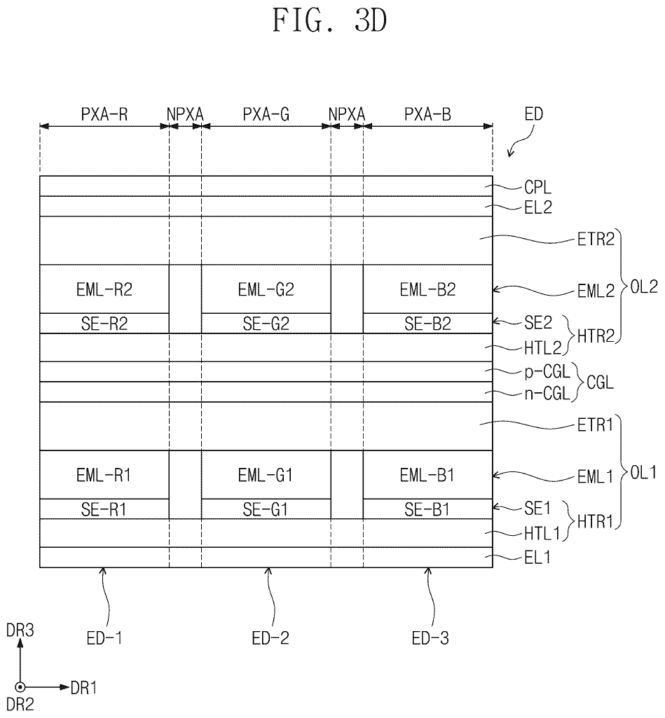

The light emitting element ED may include a first light emitting element ED-1, a second light emitting element ED-2, and a third light emitting element ED-3. Each of the light emitting elements ED-1, ED-2, and ED-3 may have a structure of a light emitting element ED according to one or more embodiments in FIGS. 3A to 3D, which will be described in more detail in one or more embodiments. Each of the light emitting elements ED-1, ED-2, and ED-3 may include a first electrode EL1, a first emission unit OL1, a charge generation unit CGL, a second emission unit OL2, and a second electrode EL2. Each of the light emitting elements ED-1, ED-2, and ED-3 may be a light emitting element having a tandem structure. In each of the light emitting elements ED-1, ED-2, and ED-3, the two emission units may emit light in substantially the same wavelength region.

The first emission unit OL1 may include a first hole transport region HTR1, first emission layers EML-R1, EML-G1, and EML-B1, and a first electron transport region ETR1. The second emission unit OL2 may include a second hole transport region HTR2, second emission layers EML-R2, EML-G2, and EML-B2, and a second electron transport region ETR2. FIG. 2 illustrates one or more embodiments in which the first emission layer and the second emission layer (e.g., EML-R1, EML-G1, EML-B1, EML-R2, EML-G2, and EML-B2) of the light emitting elements ED-1, ED-2, and ED-3 are disposed or provided within opening portions OH defined in the pixel defining films PDL, and the first hole transport region HTR1, the second hole transport region HTR2, the first electron transport region ETR1, the second electron transport region ETR2, the charge generation unit CGL, and the second electrode EL2 are each provided as a common layer in the entirety of the light emitting elements ED-1, ED-2, and ED-3. However, embodiments of the present disclosure are not limited thereto, and, in one or more embodiments, at least one or more of the first hole transport region HTR1, the second hole transport region HTR2, the first electron transport region ETR1, the second electron transport region ETR2, and the charge generation unit CGL may be provided as pattern layers patterned inside the opening portions OH defined in the pixel defining films PDL. In the present disclosure, the term “common layer” may indicate a layer that is provided, in common, to the entirety of the light emitting elements ED-1, ED-2, and ED-3 and constitutes substantially one component, and the term “pattern layers” may indicate layers that are provided apart from each other by being patterned inside the opening portions OH defined in the pixel defining films PDL. For example, in one or more embodiments, the first hole transport region HTR1, the second hole transport region HTR2, the first emission layer, the second emission layer (e.g., EML-R1, EML-G1, EML-B1, EML-R2, EML-G2, and EML-B2), the charge generation unit CGL, the first electron transport region ETR1, and the second electron transport region ETR2 of the light emitting elements ED-1, ED-2, and ED-3 may be patterned by an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may have a single-layer structure or a structure in which a plurality of layers are stacked. The encapsulation layer TFE may include at least one insulation (e.g., electrical insulation) layer. The encapsulation layer TFE according to one or more embodiments may include at least one inorganic film (hereinafter referred to as an inorganic encapsulation film). In one or more embodiments, the encapsulation layer TFE according to one or more embodiments may include at least one organic film (hereinafter referred to as an organic encapsulation film) and at least one inorganic encapsulation film.

The inorganic encapsulation film may protect the display element layer DP-ED from moisture/oxygen, and the organic encapsulation layer may protect the display element layer DP-ED from foreign matter, such as dust particles. The inorganic encapsulation film may include a silicon nitride, a silicon oxynitride, a silicon oxide, a titanium oxide, an aluminum oxide, and/or the like, and is not particularly limited thereto. The organic encapsulation layer may include an acryl-based compound, an epoxy-based compound, and/or the like. The organic encapsulation layer may include a photopolymerizable organic material and is not particularly limited.

The encapsulation layer TFE may be disposed or provided on the second electrode EL2 and fill the opening portions OH.

Referring to FIGS. 1 and 2, the display device DD may include non-emission areas NPXA and emission areas PXA-R, PXA-G, and PXA-B. Each of the emission areas PXA-R, PXA-G, and PXA-B may be an area through which light generated from each of the light emitting elements ED-1, ED-2, and ED-3 is emitted. The emission areas PXA-R, PXA-G, and PXA-B may be spaced and/or apart (e.g., spaced apart or separated) from each other on a plane (e.g., in a plan view).

Each of the emission areas PXA-R, PXA-G, and PXA-B may be an area divided by the pixel defining film PDL. The non-emission areas NPXA may each be an area between neighboring emission areas PXA-R, PXA-G, and PXA-B and may be an area that corresponds to the pixel defining film PDL. In the present disclosure, each of the emission areas PXA-R, PXA-G, and PXA-B may correspond to a pixel. The pixel defining film PDL may divide the light emitting elements ED-1, ED-2, and ED-3. Each of the first emission layers EML-R1, EML-G1, and EML-B1 and the second emission layers EML-R2, EML-G2, and EML-B2 of the light emitting elements ED-1, ED-2, and ED-3 may be divided by being disposed or provided in the opening portion OH defined in the pixel defining film PDL.

The emission areas PXA-R, PXA-G, and PXA-B may be divided into a plurality of groups according to colors of light generated in the light emitting elements ED-1, ED-2, and ED-3. A first emission area PXA-R may emit light of a first color. A second emission area PXA-G may emit light of a second color having a shorter wavelength than the first color. A third emission area PXA-B may emit light of a third color having a shorter wavelength than the second color. The light of the first color may be red light, the light of the second color may be green light, and the light of the third color may be blue light. In the display device DD according to one or more embodiments as illustrated in FIGS. 1 and 2, three emission areas PXA-R, PXA-G, and PXA-B that emit the red light, the green light, and the blue light are illustrated as an example. For example, the display device DD according to one or more embodiments may include the first emission area PXA-R as a red emission area, the second emission area PXA-G as a green emission area, and the third emission area PXA-B as a blue emission area, which are distinguished from each other.

In the display device DD according to one or more embodiments, the plurality of light emitting elements ED-1, ED-2, and ED-3 may emit light in different wavelength regions. The display device DD may include the first light emitting element ED-1 which emits the light of the first color, the second light emitting element ED-2 which emits the light of the second color having the shorter wavelength than the first color, and the third light emitting element ED-3 which emits the light of the third color having the shorter wavelength than the second color. For example, the display device DD may include the first light emitting element ED-1 which emits the red light, the second light emitting element ED-2 which emits the green light, and the third light emitting element ED-3 which emits the blue light. In the display device DD according to one or more embodiments, the first emission area PXA-R that corresponds to the red emission area, the second emission area PXA-G that corresponds to the green emission area, and the third emission area PXA-B that corresponds to the blue emission area may correspond to the first light emitting element ED-1, the second light emitting element ED-2, and the third light emitting element ED-3, respectively. However, embodiments of the present disclosure are not limited thereto, and the first light emitting element ED-1, the second light emitting element ED-2, and the third light emitting element ED-3 may emit light in substantially the same wavelength region, or at least one thereof may emit light in a different wavelength region.

The emission areas PXA-R, PXA-G, and PXA-B in the display device DD according to one or more embodiments may be arranged or provided in the form of a stripe. Referring to FIG. 1, a plurality of first emission areas PXA-R, a plurality of second emission areas PXA-G, and a plurality of third emission areas PXA-B may be arranged or provided along a first directional axis DR1. In one or more embodiments, the first emission area PXA-R, the second emission area PXA-G, and the third emission area PXA-B may be alternately arranged or provided in this order along the first directional axis DR1.

All the emission areas PXA-R, PXA-G, and PXA-B as illustrated in FIGS. 1 and 2 may have substantially the same/similar surface areas. However, embodiments of the present disclosure are not limited thereto, and the surface areas of the emission areas PXA-R, PXA-G, and PXA-B may be different according to a wavelength range of emitted light. In one or more embodiments, the surface areas of the emission areas PXA-R, PXA-G, and PXA-B may each refer to a surface area if (e.g., when) viewed on a plane (e.g., in a plan view) defined by the first directional axis DR1 and the second directional axis DR2.

An arrangement shape of the emission areas PXA-R, PXA-G, and PXA-B is not limited to one or more embodiments as illustrated in FIG. 1, and the order in which the first emission area PXA-R, the second emission area PXA-G, and the third emission area PXA-B are arranged or provided may be provided through one or more suitable combinations according to characteristics of display quality desired or required by the display device DD. For example, the emission areas PXA-R, PXA-G, and PXA-B may have a PENTILER (e.g., an RGBG matrix, RGBG structure, or RGBG matrix structure) arrangement shape and/or a DIAMOND PIXEL™ arrangement shape. PENTILE® is a duly registered trademark of Samsung Display Co., Ltd. and DIAMOND PIXEL™ is a trademark of Samsung Display Co., Ltd.

In one or more embodiments, the surface areas of the emission areas PXA-R, PXA-G, and PXA-B may be different. For example, in one or more embodiments, the surface area of the second emission area PXA-G may be smaller than the surface area of the third emission area PXA-B, but embodiments of the present disclosure are not limited thereto.

FIGS. 3A to 3D are each a schematic cross-sectional view illustrating a light emitting element ED according to one or more embodiments. The light emitting element ED may include a first light emitting element ED-1, a second light emitting element ED-2, and a third light emitting element ED-3. In FIGS. 3A to 3D, each of the first light emitting element ED-1, the second light emitting element ED-2, and the third light emitting element ED-3 may be illustrated as including two emission units OL1 and OL2. For example, each of the first light emitting element ED-1, the second light emitting element ED-2, and the third light emitting element ED-3 may be illustrated as including a first emission unit OL1 and a second emission unit OL2. However, embodiments of the present disclosure are not limited thereto, and each of the first light emitting element ED-1, the second light emitting element ED-2, and the third light emitting element ED-3 may include three or more emission units.

Referring to FIG. 3A, the light emitting element ED according to one or more embodiments may include a first electrode EL1, a first emission unit OL1, a charge generation unit CGL, a second emission unit OL2, and a second electrode EL2. Each of the first light emitting element ED-1, the second light emitting element ED-2, and the third light emitting element ED-3 may include the first electrode EL1, the first emission unit OL1, the charge generation unit CGL, the second emission unit OL2, and the second electrode EL2 which are stacked in sequence in a third direction DR3.

In the light emitting element ED according to one or more embodiments, the first emission unit OL1 may include a first hole transport region HTR1, a first emission layer EML1, and a first electron transport region ETR1 which are stacked in sequence, and the second emission unit OL2 may include a second hole transport region HTR2, a second emission layer EML2, and a second electron transport region ETR2 which are stacked in sequence. Each of the first hole transport region HTR1 and the first electron transport region ETR1 of the first emission unit OL1 may be provided as a common layer to the entirety of the first light emitting element ED-1, the second light emitting element ED-2, and the third light emitting element ED-3. The first emission layer EML1 of the first emission unit OL1 may be provided as a pattern layer that corresponds to each of the first light emitting element ED-1, the second light emitting element ED-2, and the third light emitting element ED-3. Each of the second hole transport region HTR2 and the second electron transport region ETR2 of the second emission unit OL2 may be provided as a common layer to the entirety of the first light emitting element ED-1, the second light emitting element ED-2, and the third light emitting element ED-3. The second emission layer EML2 of the second emission unit OL2 may be provided as a pattern layer that corresponds to each of the first light emitting element ED-1, the second light emitting element ED-2, and the third light emitting element ED-3.

Compared to FIG. 3A, FIG. 3B illustrates a cross-sectional view of a light emitting element ED further including a capping layer CPL on the second electrode EL2. Compared to FIG. 3B, FIG. 3C illustrates a cross-sectional view of a light emitting element ED according to one or more embodiments in which the first hole transport region HTR1 and the second hole transport region HTR2 include a first hole injection layer HIL1 and a second hole injection layer HIL2 and a first hole transport layer HTL1 and a second hole transport layer HTL2, respectively, and the first electron transport region ETR1 and the second electron transport region ETR2 include a first electron injection layer EIL1 and a second electron injection layer EIL2 and a first electron transport layer ETL1 and a second electron transport layer ETL2, respectively. Compared to FIG. 3B, FIG. 3D illustrates a cross-sectional view of a light emitting element ED according to one or more embodiments in which the first hole transport region HTR1 and the second hole transport region HTR2 include a first emission auxiliary layer SE1 and a second emission auxiliary layer SE2 and a first hole transport layer HTL1 and a second hole transport layer HTL2, respectively.

Hereinafter, each of the components included in the light emitting element ED will be described in more detail with reference to FIGS. 3A to 3D.

The first electrode EL1 may have conductivity (e.g., electrical conductivity). The first electrode EL1 may be made of a metal material, a metal alloy, or a conductive (e.g., electrically conductive) compound. The first electrode EL1 may be an anode or a cathode. However, embodiments of the present disclosure are not limited thereto. The first electrode EL1 may be a pixel electrode. The first electrode EL1 may be a transmissive electrode, a semi-transmissive electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

If (e.g., when) the first electrode EL1 is the transmissive electrode, the first electrode EL1 may include a transparent (e.g., substantially transparent) metal oxide, for example, indium tin oxide (ITO), indium zinc oxide (IZO), zinc oxide (e.g., ZnO), indium tin zinc oxide (ITZO), and/or the like. If (e.g., when) the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, or a compound or mixture thereof (e.g., mixture of Ag and Mg). In one or more embodiments, the first electrode EL1 may have a multilayer structure including a reflective film and/or a semi-transmissive film, each of which is made of the material as described in one or more embodiments, and a transparent (e.g., substantially transparent) conductive (e.g., electrically conductive) film made of indium tin oxide (ITO), indium zinc oxide (IZO), zinc oxide (e.g., ZnO), indium tin zinc oxide (ITZO), and/or the like. For example, the first electrode EL1 may have a three-layer structure of ITO/Ag/ITO, but embodiments of the present disclosure are not limited thereto. Also, the first electrode EL1 may include the metal material as described in one or more embodiments, a combination of two or more metal materials selected from among the metal materials as described in one or more embodiments, an oxide of the metal materials as described in one or more embodiments, and/or the like. The first electrode EL1 may have a thickness of about 700 Å to about 10,000 Å. For example, the thickness of the first electrode EL1 may be about 1000 Å to about 3000 Å.

The first emission unit OL1 may be provided on the first electrode EL1. The charge generation unit CGL may be provided on the first emission unit OL1. The charge generation unit CGL may be provided on the first electron transport region ETR1 of the first emission unit OL1. The second emission unit OL2 may be provided on the charge generation unit CGL.

The first emission unit OL1 may include the first hole transport region HTR1, the first emission layer EML1, and the first electron transport region ETR1 which are stacked in sequence on the first electrode EL1. The second emission unit OL2 may include the second hole transport region HTR2, the second emission layer EML2, and the second electron transport region ETR2 which are stacked in sequence on the charge generation unit CGL.

At least one selected from among the first hole transport region HTR1, the first emission layer EML1, and/or the first electron transport region ETR1 of the first emission unit OL1 may include a light emitting material including a deuterium atom. At least one selected from among the second hole transport region HTR2, the second emission layer EML2, and/or the second electron transport region ETR2 of the second emission unit OL2 may include a light emitting material including a deuterium atom. For example, in the first emission unit OL1, the first emission layer EML1 may include the light emitting material including a deuterium atom, and in the second emission unit OL2, the second emission layer EML2 may include the light emitting material including a deuterium atom. Hereinafter, the light emitting material including a deuterium atom may be referred to as a “first light emitting material”.

In one or more embodiments, the first light emitting material may be included in each of the first emission layer EML1 and the second emission layer EML2 disposed or provided in substantially the same emission area among the first emission area PXA-R, the second emission area PXA-G, and the third emission area PXA-B. For example, the first light emitting material may be included in each of the first emission layer EML1 and the second emission layer EML2 disposed or provided to correspond to the second emission area PXA-G. In one or more embodiments, the first light emitting material may be included in each of the first emission layer EML1 and the second emission layer EML2 disposed or provided to correspond to the third emission area PXA-B. The respective first light emitting materials included in the first emission layer EML1 and the second emission layer EML2 may be different or alternatively, substantially the same. The respective first light emitting materials included in the first emission layer EML1 and the second emission layer EML2 will be described in more detail in one or more embodiments.

The hole transport regions HTR1 and HTR2 may each include at least one selected from among the hole injection layers HIL1 and HIL2, the hole transport layers HTL1 and HTL2, the emission auxiliary layers SE1 and SE2, and/or an electron blocking layer. For example, the first hole transport region HTR1 may include at least one selected from among the first hole injection layer HIL1, the first hole transport layer HTL1, the first emission auxiliary layer SE1, and/or the electron blocking layer. The second hole transport region HTR2 may include at least one selected from among the second hole injection layer HIL2, the second hole transport layer HTL2, the second emission auxiliary layer SE2, and/or the electron blocking layer.

Each of the hole transport regions HTR1 and HTR2 may have a thickness of, for example, about 50 Å to about 15,000 Å. Each of the hole transport regions HTR1 1 and HTR2 may have a single layer made of a single material, or a single layer made of a plurality of different materials, or a multilayer structure having a plurality of layers made of a plurality of different materials.

For example, the hole transport regions HTR1 and HTR2 may have single-layer structures of the hole injection layers HIL1 and HIL2 or the hole transport layers HTL1 and HTL2, respectively, or alternatively, may each have a single-layer structure made of a hole injection material and a hole transport material. In one or more embodiments, each of the hole transport regions HTR1 and HTR2 may have a single-layer structure made of a plurality of different materials, or a structure in which the hole injection layers HIL1 and HIL2/hole transport layers HTL1 and HTL2, the hole injection layers HIL1 and HIL2/hole transport layers HTL1 and HTL2/emission auxiliary layers SE1 and SE2, the hole transport layers HTL1 and HTL2/emission auxiliary layers SE1 and SE2, or the hole injection layers HIL1 and HIL2/hole transport layers HTL1 and HTL2/electron blocking layers are stacked in sequence on the first electrode EL1.

However, embodiments of the present disclosure are not limited thereto. In a case where the hole transport regions HTR1 and HTR2 include the emission auxiliary layers SE1 and SE2, respectively, the emission auxiliary layers SE1 and SE2 may each be a pattern layer patterned inside the opening portion OH (see FIG. 2). For example, the emission-auxiliary layers SE1 and SE2 may include red emission auxiliary layers SE-R1 and SE-R2 that overlap the first emission area PXA-R, green emission auxiliary layers SE-G1 and SE-G2 that overlap the second emission area PXA-G, and blue emission auxiliary layers SE-B1 and SE-B2 that overlap the third emission area PXA-B, respectively. The first emission auxiliary layer SE1 may include a first red emission auxiliary layer SE-R1, a first green emission auxiliary layer SE-G1, and a first blue emission auxiliary layer SE-B1. The second emission auxiliary layer SE2 may include a second red emission auxiliary layer SE-R2, a second green emission auxiliary layer SE-G2, and a second blue emission auxiliary layer SE-B2. The emission auxiliary layers SE1 and SE2 may compensate a resonance distance according to wavelengths of light emitted from the emission layers EML1 and EML2, and adjust the hole charge balance to increase or enhance light-emission efficiency. In one or more embodiments, the emission auxiliary layers SE1 and SE2 may serve to prevent electrons from being injected (or reduce a degree to or occurrence of which electrons are injected) into the hole transport regions HTR1 and HTR2, respectively.

Each of hole transport regions HTR1 and HTR2 may be formed or provided using one or more suitable methods, such as a vacuum deposition method, a spin coating method, a cast method, a Langmuir-Blodgett (LB) method, an inkjet printing method, a laser printing method, and/or a laser induced thermal imaging (LITI) method.

Each of hole transport regions HTR1 and HTR2 may include a compound represented by Formula H-1.

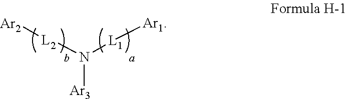

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. If (e.g., when) a or b is an integer of 2 or more, two or more L₁ and L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In one or more embodiments, in Formula H-1, Ars may be a substituted or unsubstituted aryl group having 6 to 30 ring-forming carbon atoms or a substituted or unsubstituted heteroaryl group having 2 to 30 ring-forming carbon atoms.

The compound represented by Formula H-1 as described in one or more embodiments may be a monoamine compound. In one or more embodiments, the compound represented by Formula H-1 as described in one or more embodiments may be a diamine compound in which at least one selected from among Ar₁ to Ars includes an amine group as a substituent. The compound represented by Formula H-1 as described in one or more embodiments may be a carbazole-based compound including a substituted or unsubstituted carbazole group in at least one selected from Ar₁ and/or Ar₂, or a fluorene-based compound including a substituted or unsubstituted fluorene group in at least one selected from Ar₁ and/or Ar₂.

The compound represented by Formula H-1 may be represented by any one selected from among the compounds in Compound Group H as described in one or more embodiments. However, the compounds listed in Compound Group H herein are examples, and the compound represented by Formula H-1 is not limited to those listed in Compound Group H herein.

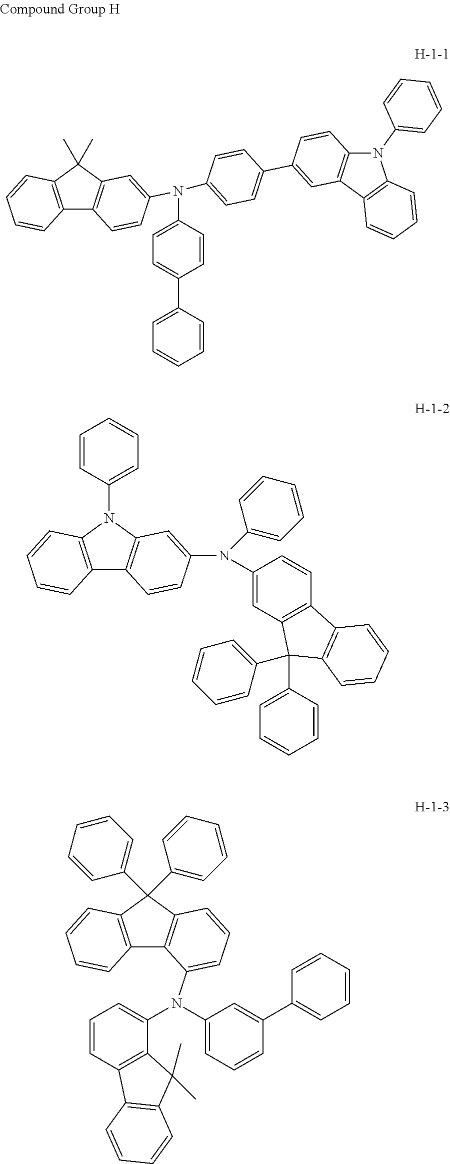 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

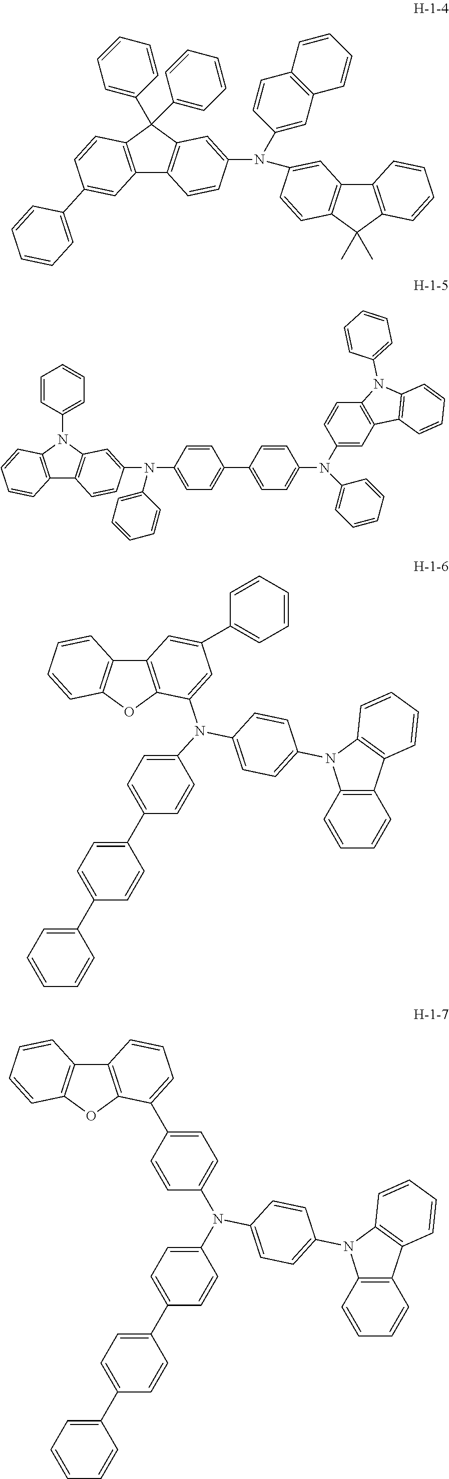 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

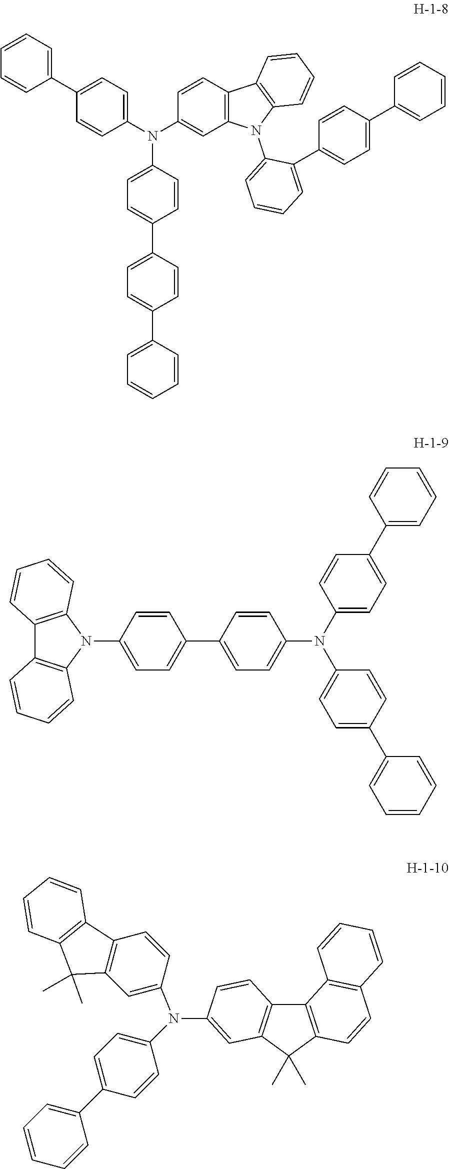 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

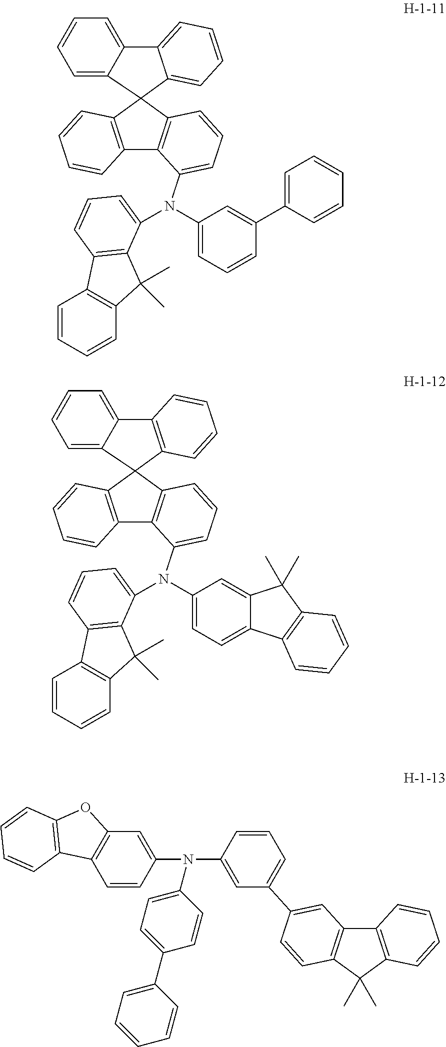

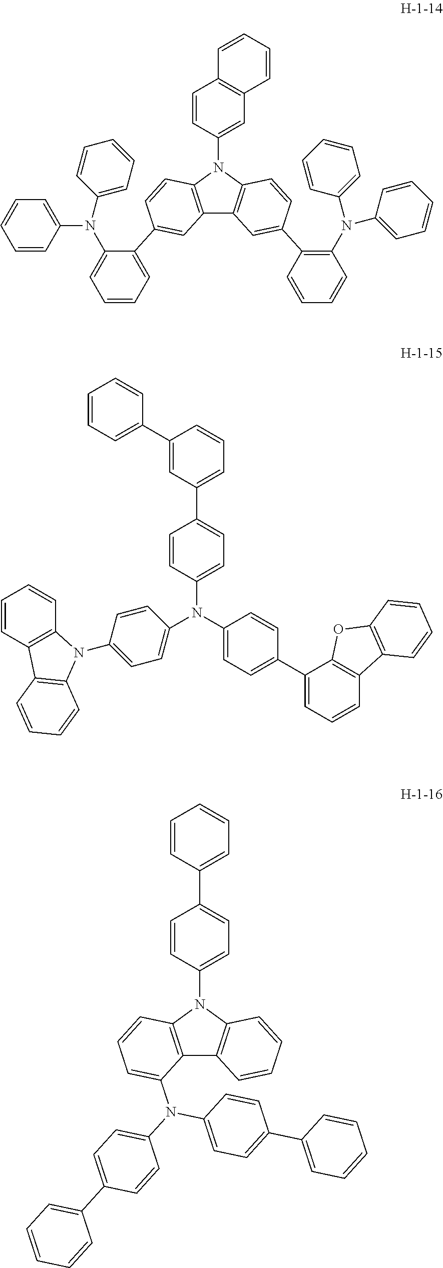 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

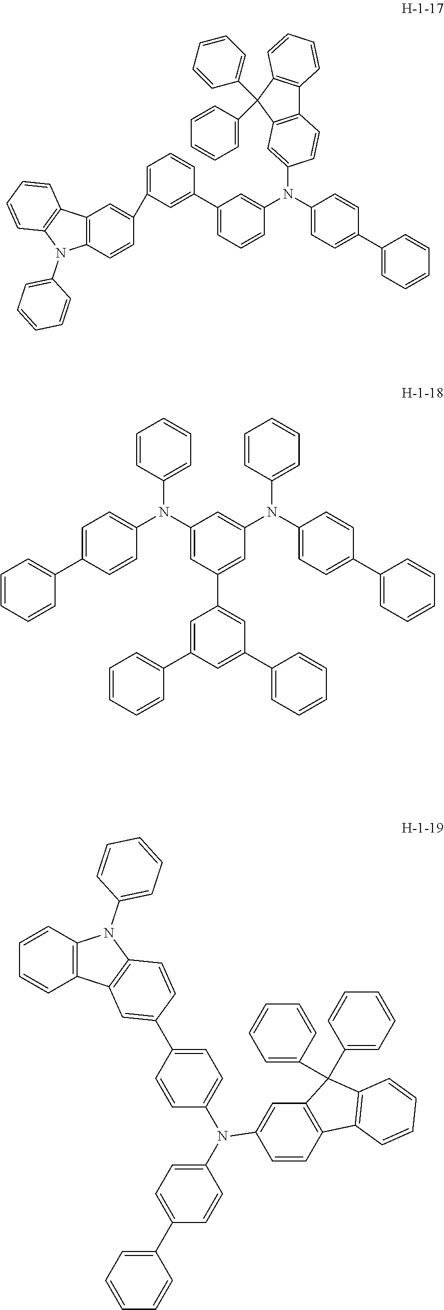 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

Each of the hole transport regions HTR1 and HTR2 may further include a phthalocyanine compound, such as copper phthalocyanine, (N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino]triphenylamine (m-MTDATA), 4,4′,4″-Tris(N,N-diphenylamino) triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphorsulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HATCN), and/or the like.

Each of the hole transport regions HTR1 and HTR2 may further include a carbazole derivative, such as 1,3-bis(N-carbazolyl)benzene (mCP), N-phenyl carbazole and/or polyvinyl carbazole, a fluorene-based derivative, a triphenylamine-based derivative, such as N,N′-bis(3-methylphenyl)-N, N′-diphenyl-[1,1′-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD) and/or the like.

In one or more embodiments, each of the hole transport regions HTR1 and HTR2 may further include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

In each of the hole transport regions HTR1 and HTR2, the compounds of the hole transport region as described in one or more embodiments may be included in at least one selected from among the hole injection layers HIL1 and HIL2, the hole transport layers HTL1 and HTL2, the emission auxiliary layers SE1 and SE2, and/or the electron blocking layers.

Each of the hole transport regions HTR1 and HTR2 may have a thickness of about 100 Å to about 10,000 Å, for example, about 100 Å to about 5,000 Å. In a case where the hole transport regions HTR1 and HTR2 include the hole injection layers HIL1 and HIL2, respectively, the hole injection layers HIL1 and HIL2 may each have a thickness of, for example, about 30 Å to about 1,000 Å. In a case where the hole transport regions HTR1 and HTR2 include the hole transport layers HTL1 and HTL2, respectively, the hole transport layers HTL1 and HTL2 may each have a thickness of, for example, about 30 Å to about 1,000 Å. For example, in a case where the hole transport regions HTR1 and HTR2 each include the electron blocking layer, the electron blocking layer may have a thickness of about 10 Å to about 1,000 Å. If (e.g., when) the thicknesses of each of the hole transport regions HTR1 and HTR2, the hole injection layers HIL1 and HIL2, the hole transport layers HTL1 and HTL2, and the electron blocking layer satisfies the foregoing ranges, satisfactory or suitable hole transport properties may be obtained without a substantial increase in driving voltage.

Each of the hole transport regions HTR1 and HTR2 may further include a p-dopant in addition to the materials as described in one or more embodiments. The p-dopant may be uniformly or non-uniformly dispersed in each of the hole transport regions HTR1 and HTR2. The p-type dopant may include at least one selected from among halogenated metal compounds, quinone derivatives, metal oxides, and/or cyano group-containing compounds, but embodiments of the present disclosure are not limited thereto. For example, the p-type dopant may include halogenated metal compounds, such as CuI and/or RbI, quinone derivatives, such as tetracyanoquinodimethane (TCNQ) and/or 2,3,5,6-tetrafluoro-7,7,8,8-tetracyanoquinodimethane (F4-TCNQ), metal oxides, such as tungsten oxides and/or molybdenum oxides, cyano group-containing compounds, such as dipyrazino[2,3-f: 2′,3′-h]quinoxaline-2,3,6,7,10,11-hexacarbonitrile (HAT-CN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

The emission layers EML1 and EML2 may include red emission layers EML-R1 and EML-R2 that overlap the first emission area PXA-R, green emission layers EML-G1 and EML-G2 that overlap the second emission area PXA-G, and blue emission layers EML-B1 and EML-B2 that overlap the third emission area PXA-B, respectively.

The red emission layers EML-R1 and EML-R2, the green emission layers EML-G1 and EML-G2, and the blue emission layers EML-B1 and EML-B2 may be disposed or provided apart from each other. For example, the first emission layer EML1 may include a first red emission layer EML-R1, a first green emission layer EML-G1, and a first blue emission layer EML-B1 which are disposed or provided apart from each other in the first direction DR1. The second emission layer EML2 may include a second red emission layer EML-R2, a second green emission layer EML-G2, and a second blue emission layer EML-B2 which are disposed or provided apart from each other in the first direction DR1.

The first red emission layer EML-R1 and the second red emission layer EML-R2 may be disposed or provided apart from each other in the third direction DR3 (or a thickness direction). In one or more embodiments, the first green emission layer EML-G1 and the second green emission layer EML-G2 may be disposed or provided apart from each other in the third direction DR3, and the first blue emission layer EML-B1 and the second blue emission layer EML-B2 may be disposed or provided apart from each other in the third direction DR3. The first light emitting element ED-1 may include the red emission layers EML-R1 and EML-R2 that correspond to the first emission area PXA-R, the second light emitting element ED-2 may include the green emission layers EML-G1 and EML-G2 that correspond to the second emission area PXA-G, and the third light emitting element ED-3 may include the blue emission layers EML-B1 and EML-B2 that correspond to the third emission area PXA-B.

Each of the emission layers EML1 and EML2 may have a thickness of, for example, about 100 Å to about 1,000 Å or about 100 Å to about 300 Å. Each of the emission layers EML1 and EML2 may have a single layer made of a single material, or a single layer made of a plurality of different materials, or a multilayer structure having a plurality of layers made of a plurality of different materials.

In one or more embodiments, in at least one selected from among the first light emitting element ED-1, the second light emitting element ED-2, and the third light emitting element ED-3, the emission layers EML1 and EML2 may each include a hole transporting host, an electron transporting host, and a dopant. The respective hole transporting hosts, electron transporting hosts, and dopants included in the first emission layer EML1 and the second emission layer EML2 may be substantially the same or different.

In the emission layers EML1 and EML2, the hole transporting host and the electron transporting host may form an exciplex. Herein, triplet state energy of the exciplex formed by the hole transporting host and the electron transporting host may correspond to a difference in energy level between a lowest unoccupied molecular orbital (LUMO) of the electron transporting host and a highest occupied molecular orbital (HOMO) of the hole transporting host.

For example, an absolute value of a triplet energy level of the exciplex formed by the hole transporting host and the electron transporting host may be about 2.4 eV to about 3.0 eV. The triplet energy of the exciplex may have a smaller value than an energy gap of each host material. The exciplex may have the triplet energy of about 3.0 eV or less that is an energy gap of the hole transporting host and the electron transporting host. However, this is illustrative, and embodiments of the present disclosure are not limited thereto.

In one or more embodiments, a compound represented by Formula HT-1 herein may be used as a hole transporting host material of the emission layers EML1 and EML2. The compound represented by Formula HT-1 may be included in at least one selected from the first emission layer EML1 and/or the second emission layer EML2.

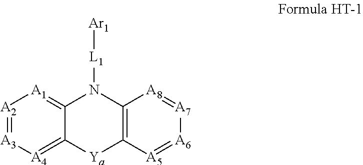

In Formula HT-1, A1 to A₈ may each independently be N or CR₅₁. For example, A₁ to A₈ may be all CR₅₁. In one or more embodiments, one selected from among A₁ to A₈ may be N, and the remainder may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group, and/or the like, but embodiments of the present disclosure are not limited thereto.

In Formula HT-1, Ya may be a direct linkage, CR₅₂R₅₃, or SiR₅₄R₅₅. For example, two benzene rings linked to a nitrogen atom in Formula HT-1 may refer to those linked via a direct linkage,

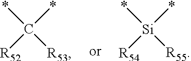

In Formula HT-1, if (e.g., when) Yₐ is a direct linkage, a second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the compound represented by Formula HT-1 may be represented by any one selected from among the compounds represented in Compound Group HT. The emission layers EML1 and EML2 may each include at least one selected from among the compounds represented in Compound Group HT as a hole transporting host material.

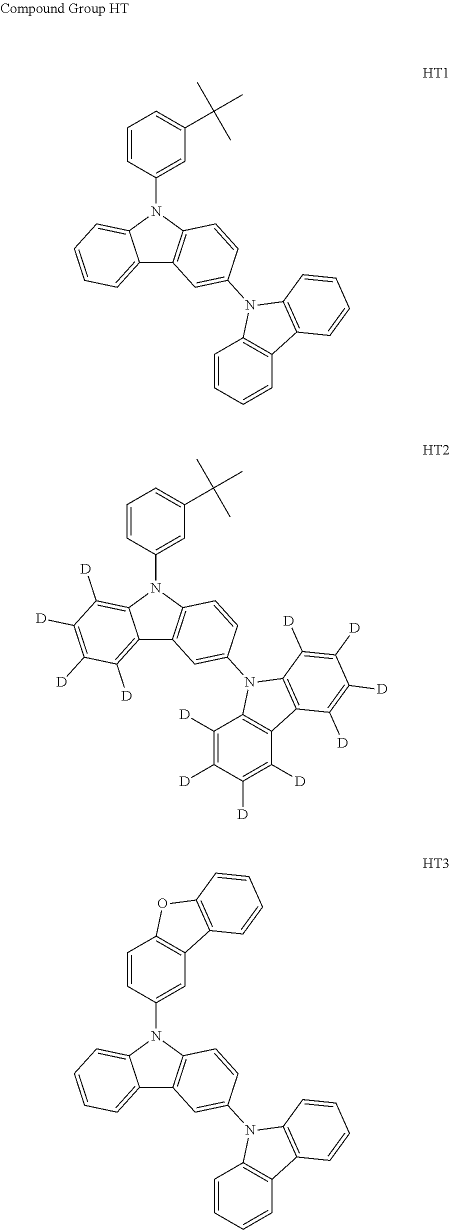 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

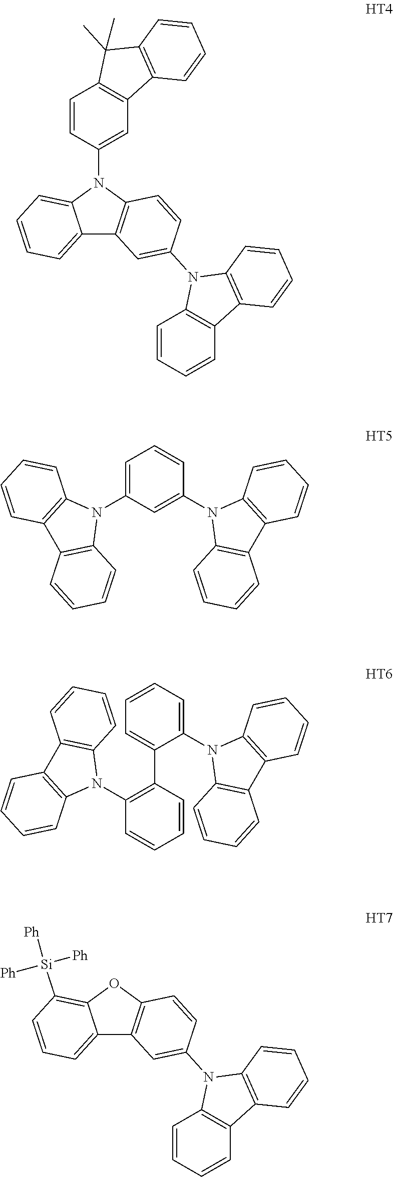 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

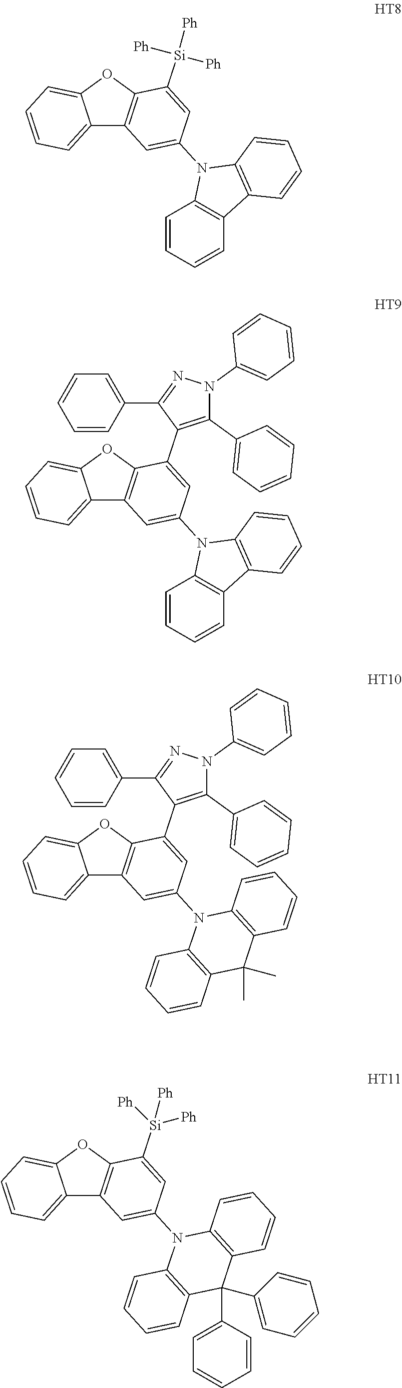 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

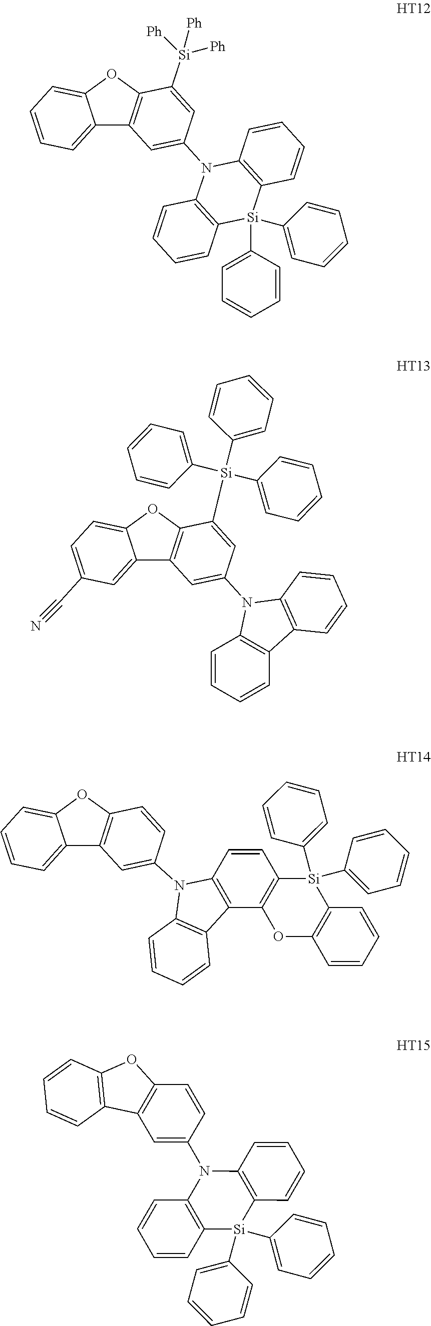 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

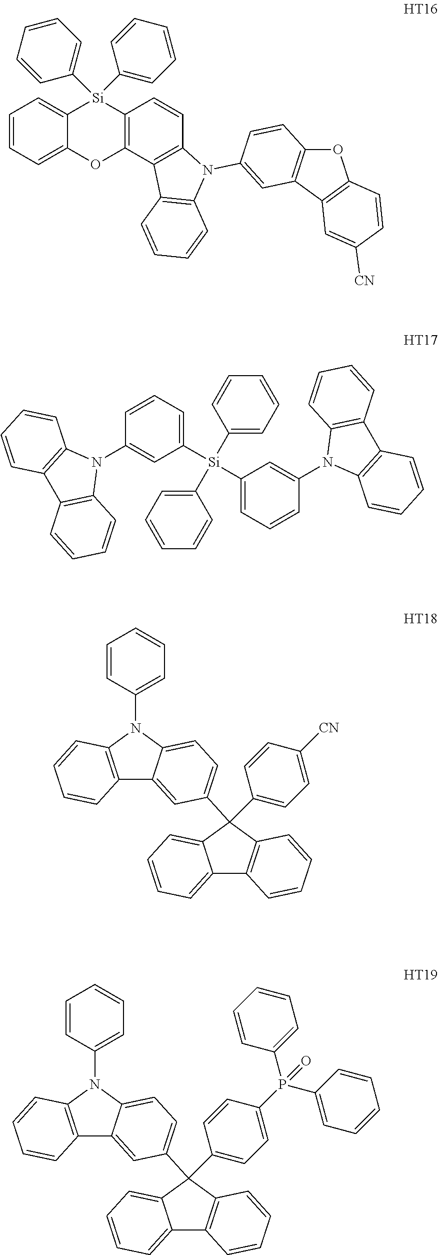 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

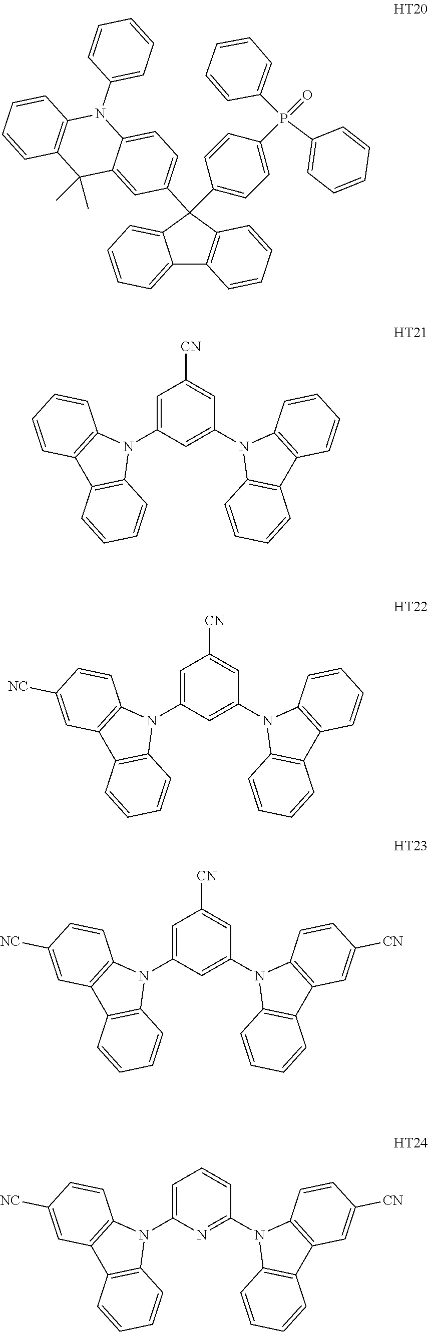 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

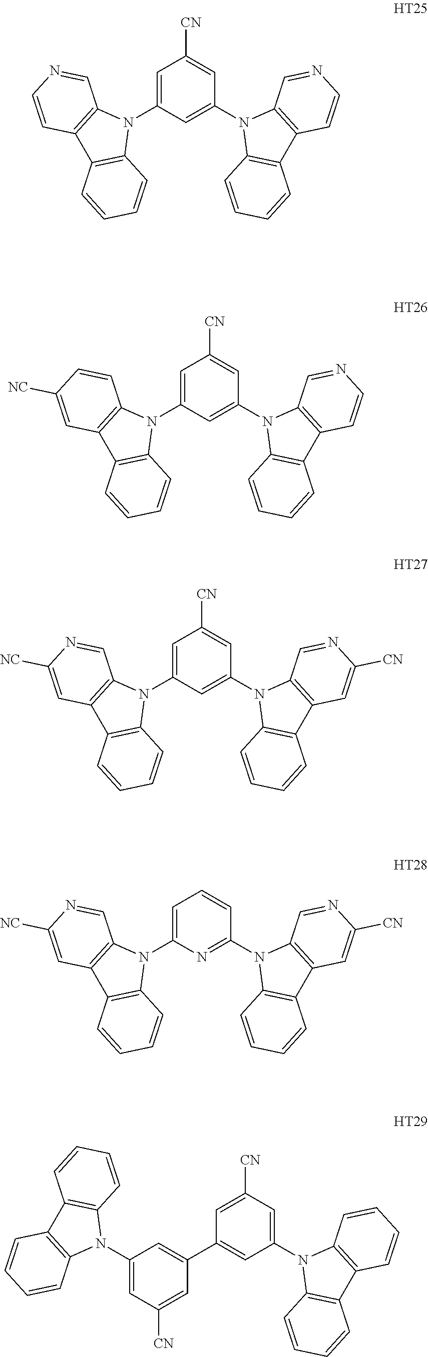 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

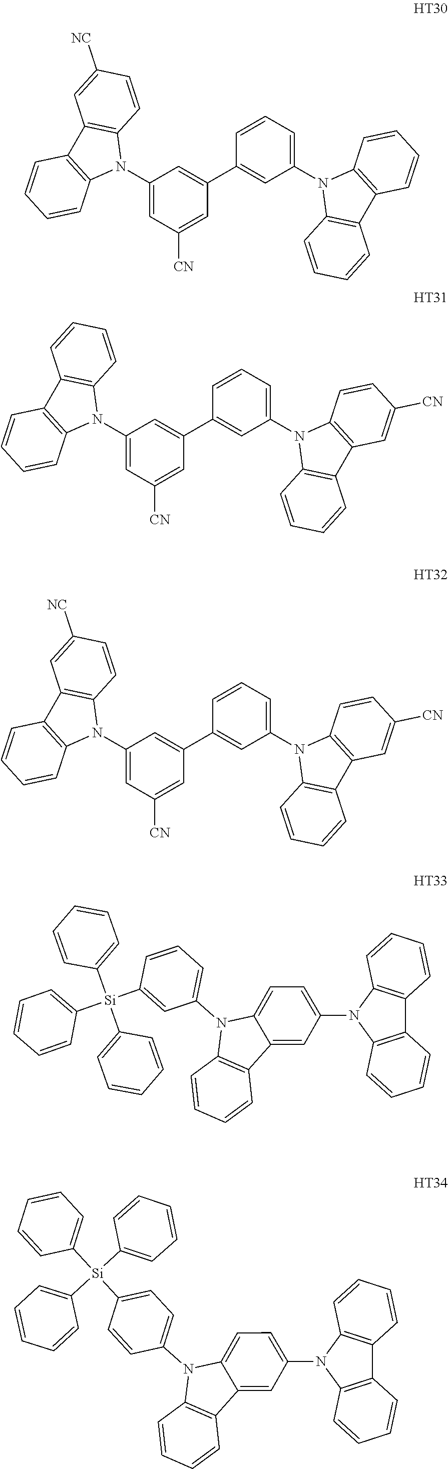 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

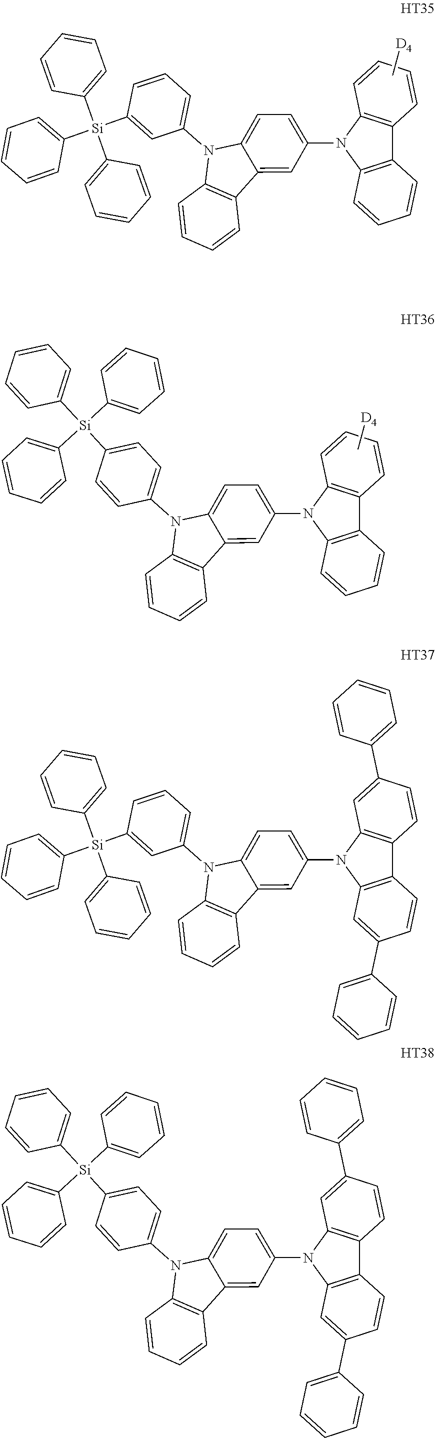

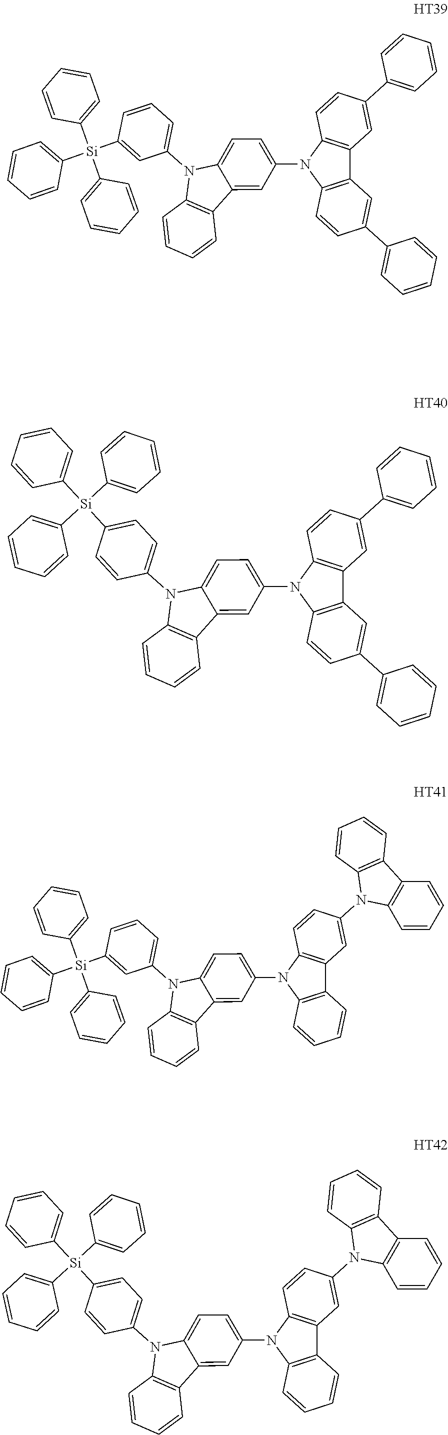 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

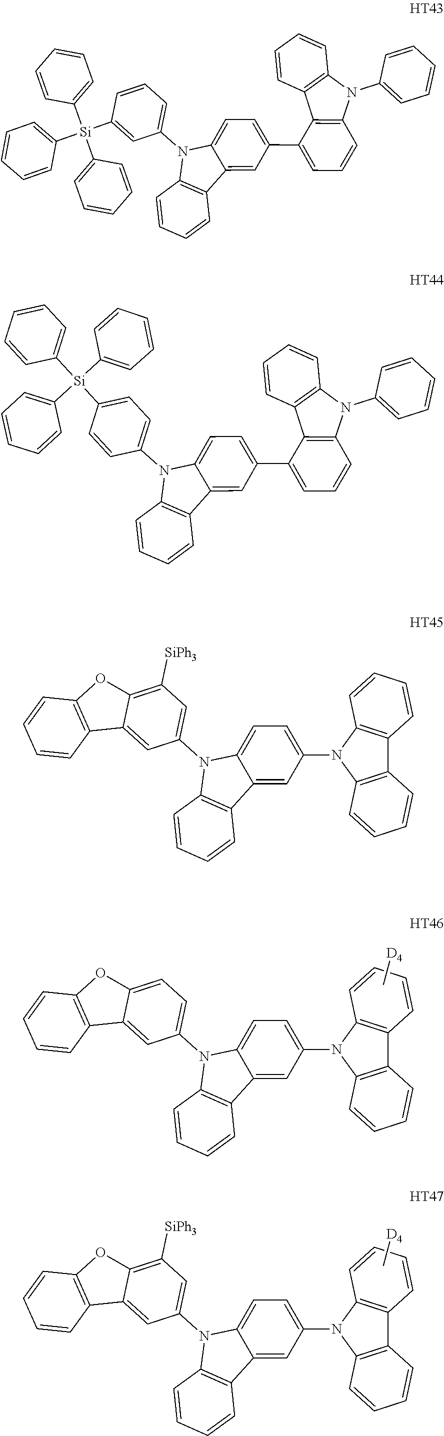

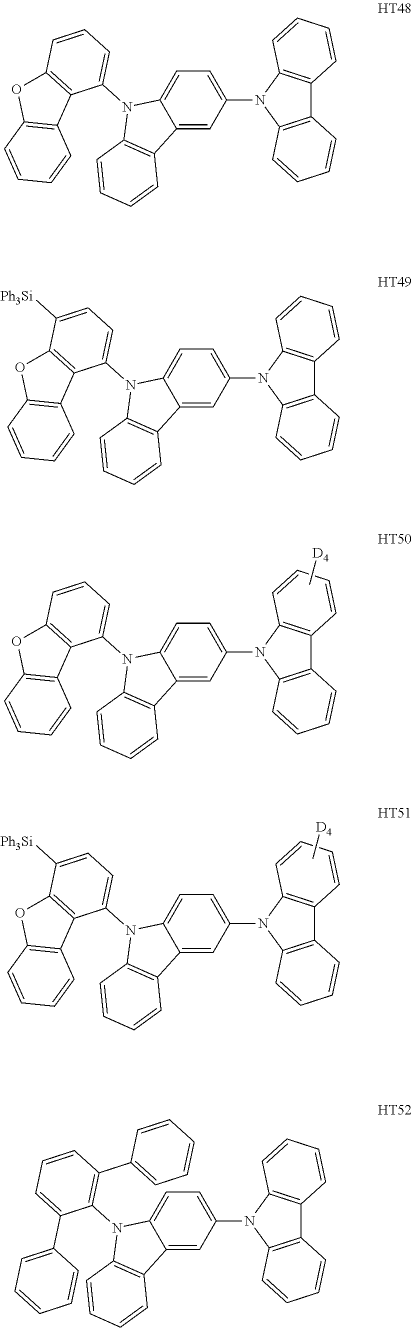

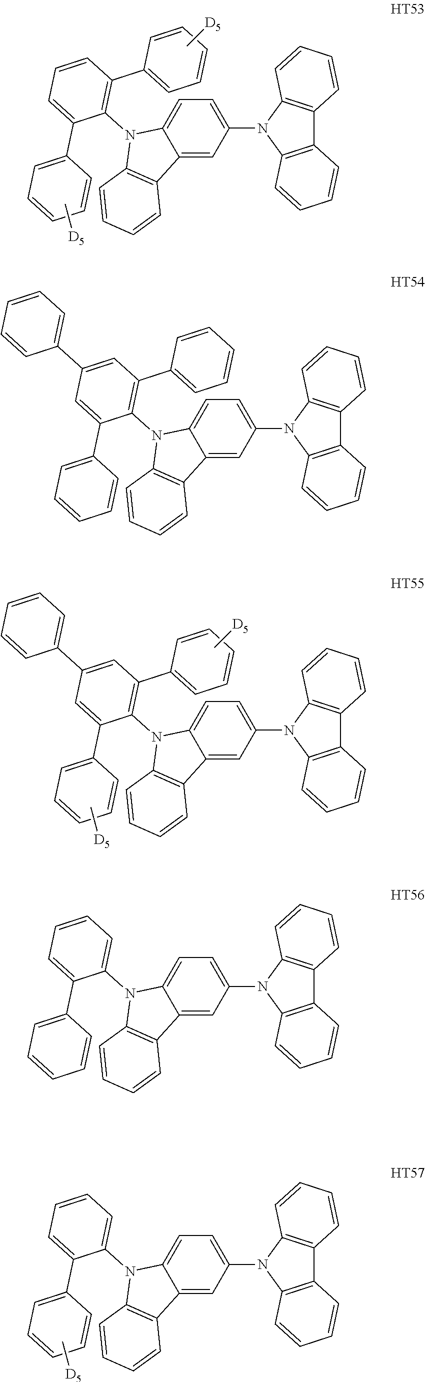

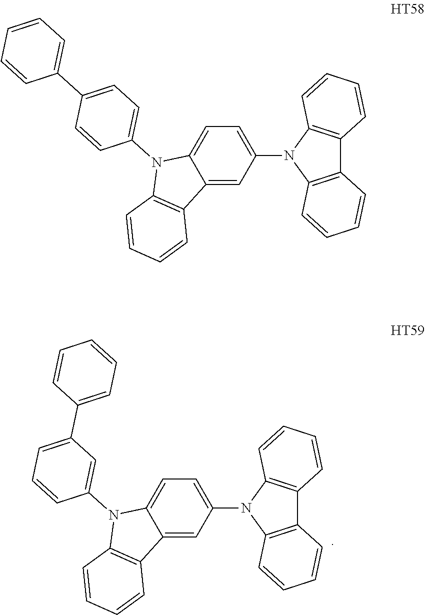 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the compounds provided as examples in Compound Group HT, “D” may indicate a deuterium atom, and “Ph” may indicate a substituted or unsubstituted phenyl group. For example, in the compounds provided as examples in Compound Group HT, “Ph” may be an unsubstituted phenyl group.

In one or more embodiments, the emission layers EML1 and EML2 may include a compound represented by Formula ET-1. For example, the compound represented by Formula ET-1 may be used as an electron transporting host material of the emission layers EML1 and EML2. The compound represented by Formula ET-1 may be included in at least one selected from among the first emission layer EML1 and/or the second emission layer EML2.

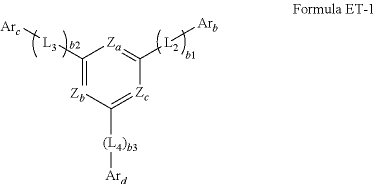

In Formula ET-1, at least one selected from among Zₐ to Z_{c} may be N, and the remainder may be CRₐ₆. For example, one selected from among Zₐ to Z_{c} may be N, and the other two may each independently be CRₐ₆. In one or more embodiments, a third compound represented by Formula ET-1 may include a pyridine moiety. In one or more embodiments, two selected from among Zₐ to Z_{c} may be N, and the remainder may be CRₐ₆. In one or more embodiments, the third compound represented by Formula ET-1 may include a pyrimidine moiety. In one or more embodiments, Za to Zc may be all N. In one or more embodiments, the third compound represented by Formula ET-1 may include a triazine moiety.

In Formula ET-1, Rₐ₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar_{b} to Ar_{d} may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Arb to Ard may be substituted or unsubstituted phenylene groups or substituted or unsubstituted carbazole groups.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. If (e.g., when) b1 to b3 are each an integer of 2 or more, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In one or more embodiments, the compound represented by Formula ET-1 may be represented by any one selected from among the compounds in Compound Group ET. The emission layers EML1 and EML2 may include at least one selected from among the compounds represented in Compound Group ET as the electron transporting host material.

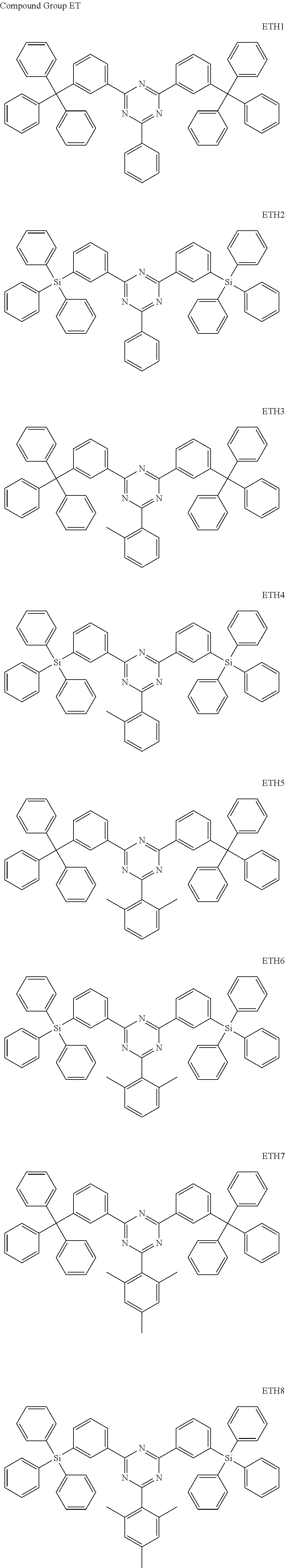

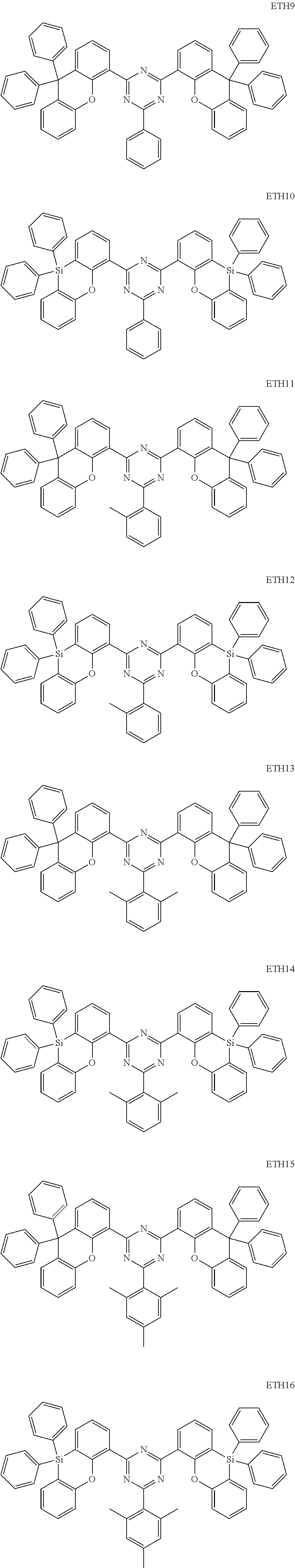

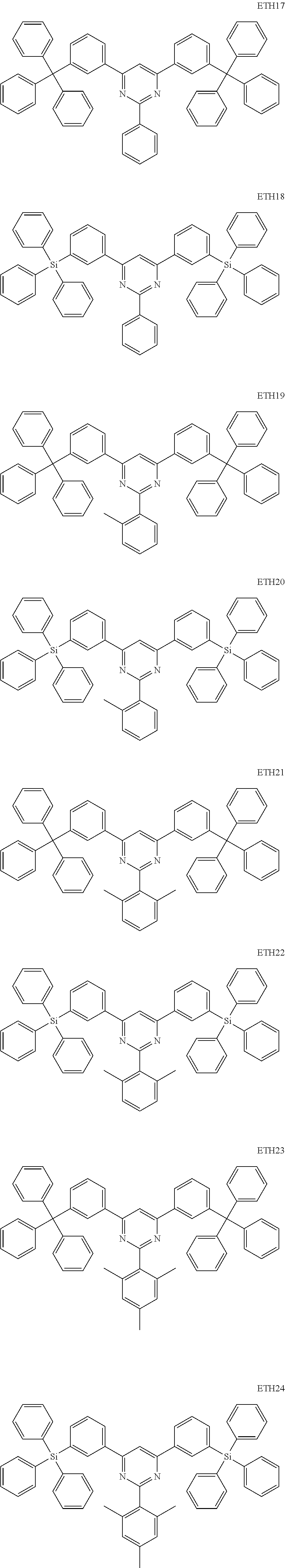

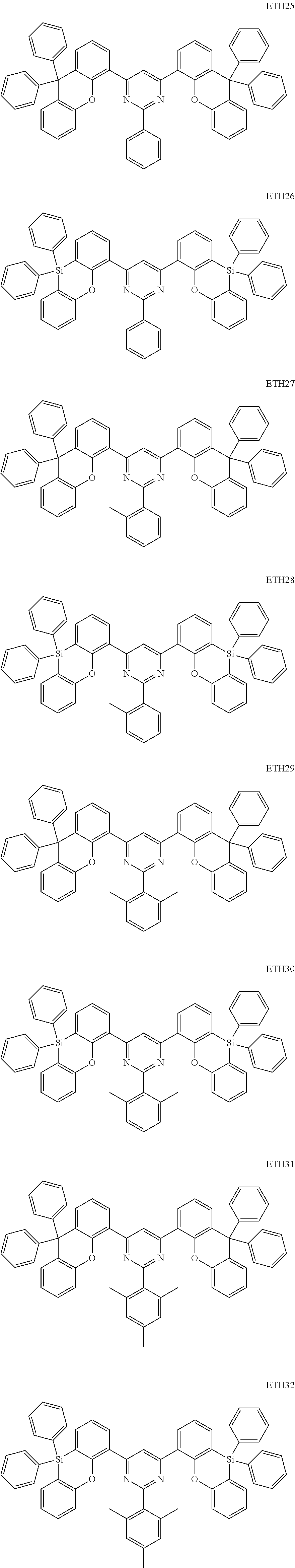

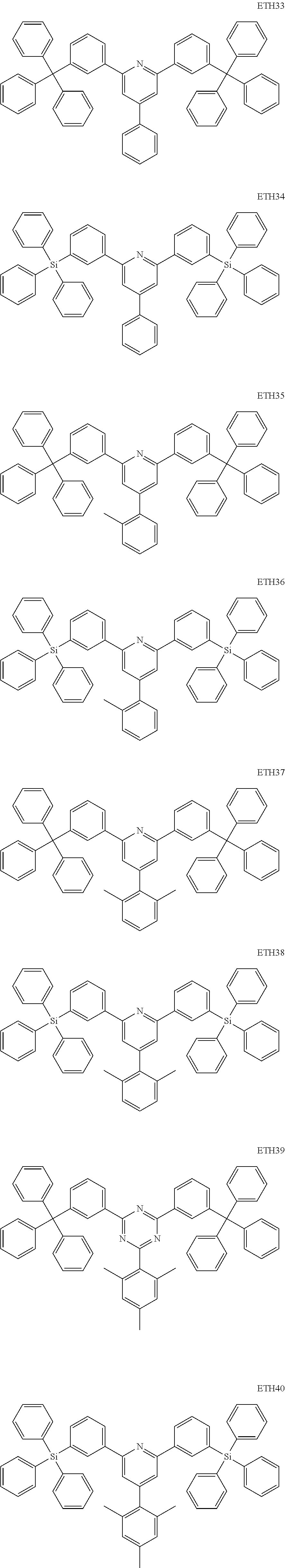

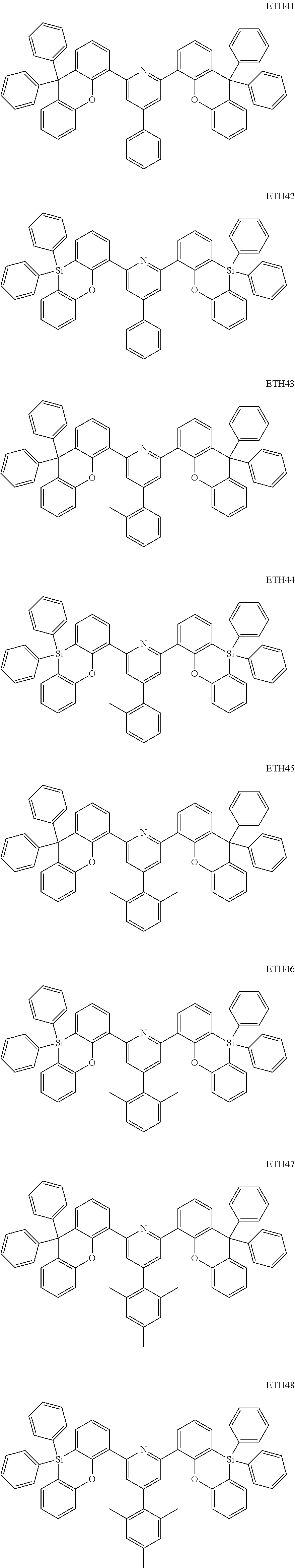

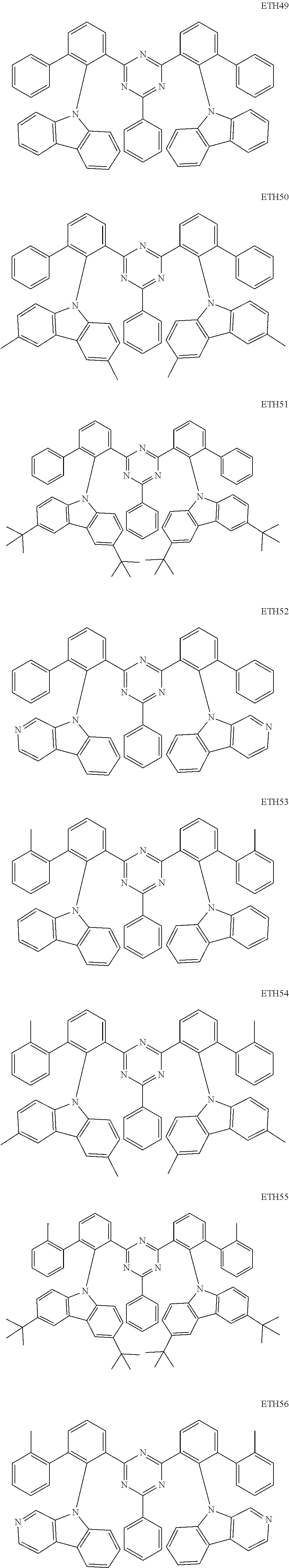

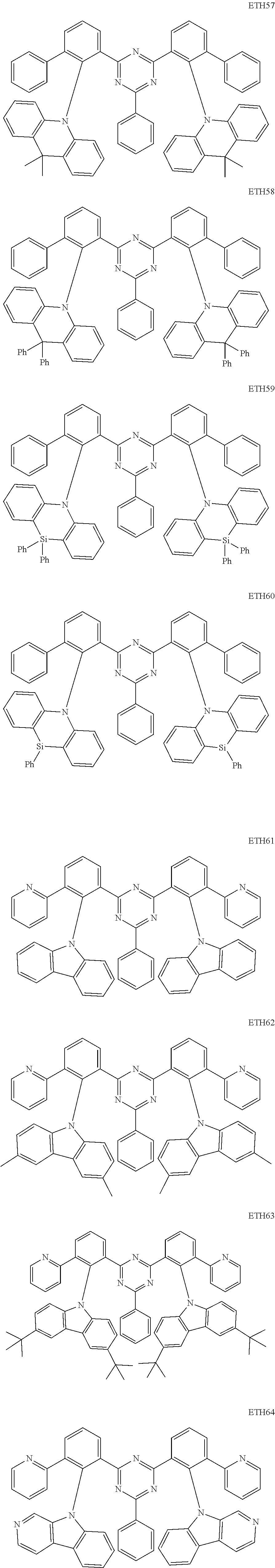

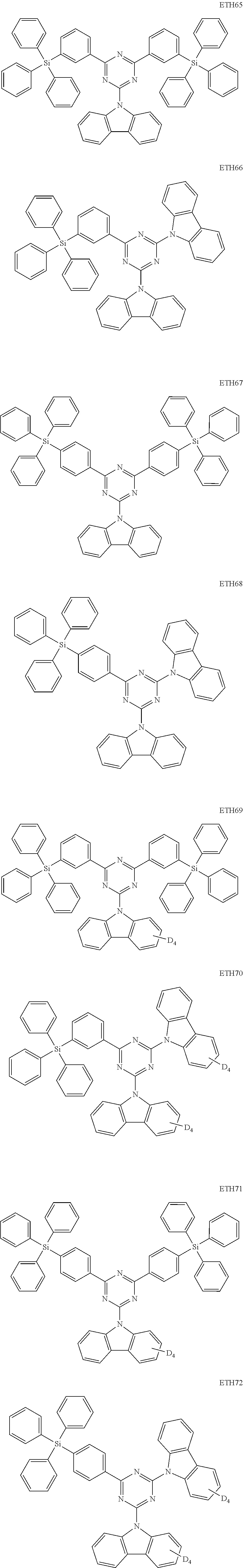

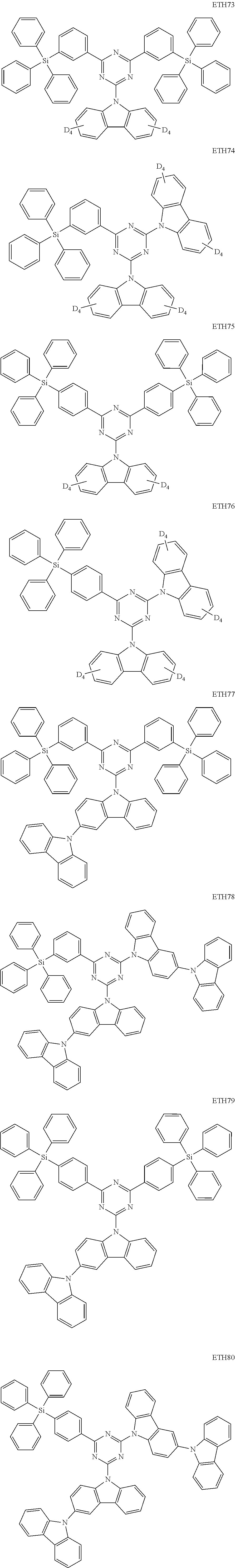

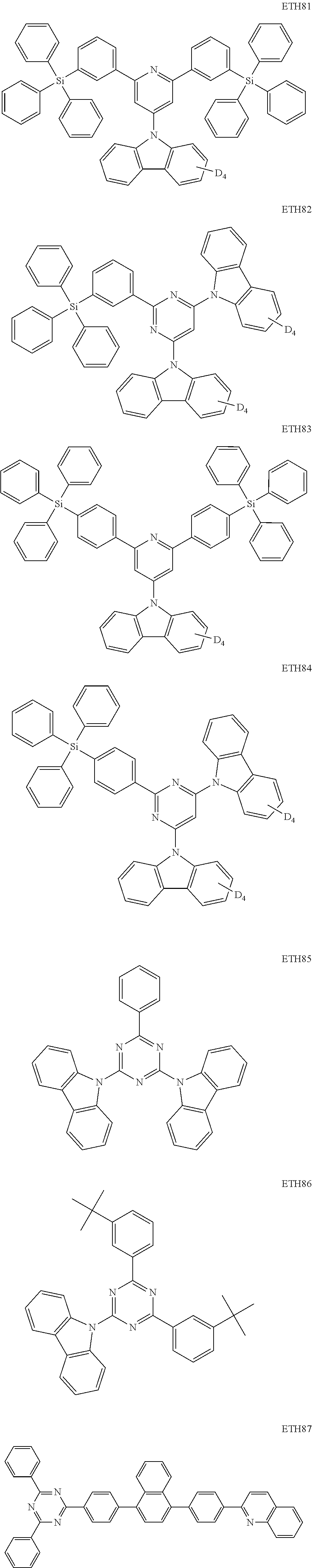

In the compounds provided as examples in Compound Group ET, “D” indicates a deuterium atom, and “Ph” indicates an unsubstituted phenyl group.

In one or more embodiments, in at least two selected from among the first light emitting element ED-1, the second light emitting element ED-2, and the third light emitting element ED-3, the emission layers EML1 and EML2 may include the first light emitting materials. For example, in the light emitting element ED according to one or more embodiments, the first green emission layer EML-G1 and the second green emission layer EML-G2 of the second light emitting element ED-2 may include the first light emitting materials, and the first blue emission layer EML-B1 and the second blue emission layer EML-B2 of the third light emitting element ED-3 may include the first light emitting materials. The first red emission layer EML-R₁ and the second red emission layer EML-R₂ of the first light emitting element ED-1 may not include the first light emitting materials. However, embodiments of the present disclosure are not limited thereto, and the first red emission layer EML-R₁ and the second red emission layer EML-R₂ may also include the first light emitting materials as desired or necessary.

In one or more embodiments, the first light emitting material may include at least one selected from the first compound and/or the second compound. The first light emitting material may be used as the electron transporting host material. The first compound may include a deuterium atom, a carbazole moiety, and a nitrogen-containing moiety. The second compound may include a deuterium atom and an anthracene moiety. For example, the first compound may be a compound in which at least one deuterium atom is substituted in the electron transporting host material including a carbazole moiety and a nitrogen-containing moiety. The second compound may be a compound in which at least one deuterium atom is substituted in the electron transporting host material including an anthracene moiety.

The first compound may have one or more suitable chemical structures without limit to the types or kinds as long as the first compound may include a carbazole moiety and a nitrogen-containing moiety as a partial structure. For example, the first compound may include a carbazole moiety, such as carbazole, indolocarbazole, benzofurocarbazole, and/or indenocarbazole, and may include a nitrogen-containing moiety, such as pyridine, pyrimidine, triazine, diazafluorene, phenanthridine, phenanthroline, leucoline, quinazoline, naphthyridine, and/or benzofuropyrimidine. In one or more embodiments, each of a carbazole moiety and a nitrogen-containing moiety included in the first compound may include, as a substituent, an alkyl group, an aryl group, a heteroaryl group, and/or the like. This first compound may include a deuterium atom as a substituent. In the first compound, at least one selected from a carbazole moiety and/or a nitrogen-containing moiety may include a deuterium atom as a substituent or include a substituent including a deuterium atom.

The second compound may have one or more suitable chemical structures without limit to the types or kinds as long as the second compound may include an anthracene moiety as a partial structure. In one or more embodiments, an anthracene moiety included in the second compound may include, as a substituent, an aryl group, a heteroaryl group, and/or the like. This second compound may include a deuterium atom as a substituent. For example, in the second compound, the anthracene moiety may include a deuterium atom as a substituent, or include a substituent including a deuterium atom.

In one or more embodiments, the first compound may be represented by Formula 1. The first compound may be represented by Formula 1 may be included in each of the first green emission layer EML-G1 and the second green emission layer EML-G2 of the second light emitting element ED-2. However, embodiments of the present disclosure are not limited thereto. For example, the first light emitting material may also be included in each of the first green emission auxiliary layer SE-G1 and the second green emission auxiliary layer SE-G2. The first compound represented by Formula 1 may be included in each of the first green emission auxiliary layer SE-G1 and the second green emission auxiliary layer SE-G2.

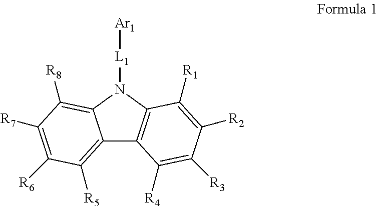

In Formula 1, L₁ may be a direct linkage or a substituted or unsubstituted arylene group having 6 to 30 ring-forming carbon atoms. For example, L₁ may be a direct linkage, a substituted or unsubstituted phenylene group, or a substituted or unsubstituted naphthylene group. However, embodiments of the present disclosure are not limited thereto.

In Formula 1, R₁ to R₈ may each independently be a hydrogen atom, a deuterium atom, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

For example, R₁ to R₈ may each independently be a hydrogen atom, a deuterium atom, a substituted or unsubstituted phenyl group, a substituted or unsubstituted carbazole group, or a substituted or unsubstituted fluorenyl group. In one or more embodiments, adjacent groups of R₁ to R₈ may be bonded to each other to form a substituted or unsubstituted hydrocarbon ring or a substituted or unsubstituted heterocycle.

In Formula 1, Ar₁ may be a substituted or unsubstituted aryl group having 6 to 30 ring-forming carbon atoms, or a substituted or unsubstituted heteroaryl group having 3 to 30 ring-forming carbon atoms, or be represented by Formula 1-A.

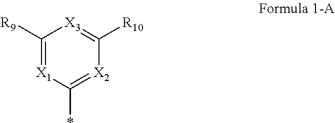

In Formula 1-A, at least one selected from among X₁ to X₃ may be a nitrogen atom (N), and the remainder of X₁ to X₃ which are not nitrogen atoms (N) may be CR₁₁. For example, any one selected from among X₁ to X₃ may be N, and the other two selected from among X₁ to X₃ which are not nitrogen atoms (N) may be all CR₁₁. If (e.g., when) two selected from among X₁ to X₃ are CR₁₁, two R₁₁ may be the same or different from each other. However, embodiments of the present disclosure are not limited thereto. Two selected from among X₁ to X₃ may be N, or all of X₁ to X₃ may be N.

In Formula 1-A, R₉ to R₁₁ may each independently be a hydrogen atom, a deuterium atom, a substituted or unsubstituted amine group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₉ to R₁₁ may each independently be a hydrogen atom, a deuterium atom, a substituted or unsubstituted phenyl group, a substituted or unsubstituted biphenyl group, a substituted or unsubstituted naphthyl group, a substituted or unsubstituted carbazole group, a substituted or unsubstituted dibenzofuran group, a substituted or unsubstituted dibenzothiophene group, or a substituted or unsubstituted pyridine group, or bonded to an adjacent group to form a ring.

In one or more embodiments, Ar₁ in Formula 1 may be a substituted or unsubstituted phenyl group, a substituted or unsubstituted biphenyl group, a substituted or unsubstituted naphthyl group, a substituted or unsubstituted pyridine group, a substituted or unsubstituted pyrimidine group, a substituted or unsubstituted triazine group, a substituted or unsubstituted diazafluorene group, a substituted or unsubstituted phenanthridine, a substituted or unsubstituted phenanthroline, a substituted or unsubstituted leucoline group, a substituted or unsubstituted quinazoline group, a substituted or unsubstituted naphthyridine, or a substituted or unsubstituted benzofuropyrimidine group. However, embodiments of the present disclosure are not limited thereto.

1 For example, Ar₁ may be represented by any one selected from among Substituent Group 1, but embodiments of the present disclosure are not limited thereto. In Substituent Group 1, “-*” may represent a position linked to Formula 1.

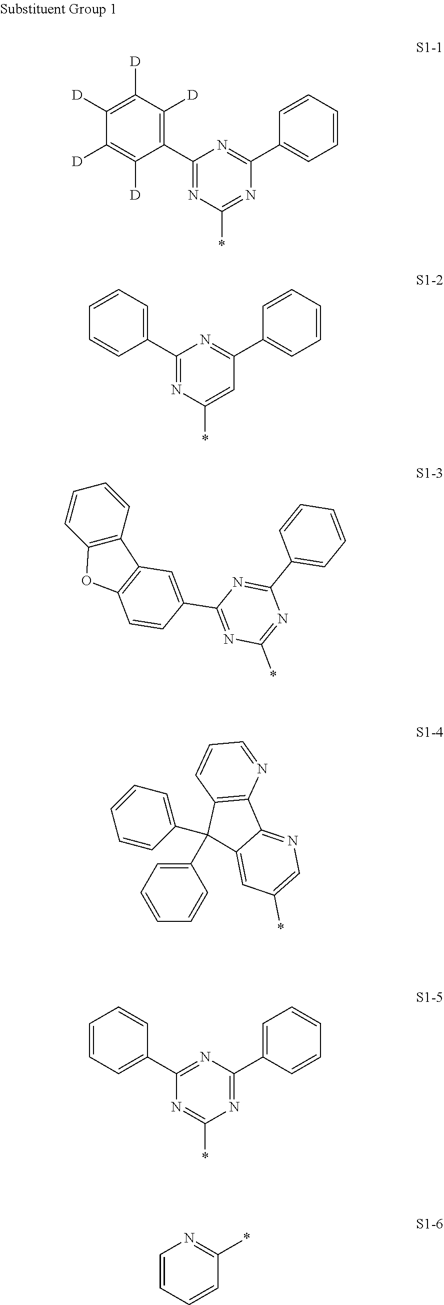 [SMILES: *c1nc(-c2ccccc2)nc(-c2c([2H])c([2H])c([2H])c([2H])c2[2H])n1 ; *c1cc(-c2ccccc2)nc(-c2ccccc2)n1 ; *c1nc(-c2ccccc2)nc(-c2ccc3oc4ccccc4c3c2)n1 ; *c1cnc2c(c1)C(c1ccccc1)(c1ccccc1)c1cccnc1-2 ; *c1nc(-c2ccccc2)nc(-c2ccccc2)n1 ; *c1ccccn1]

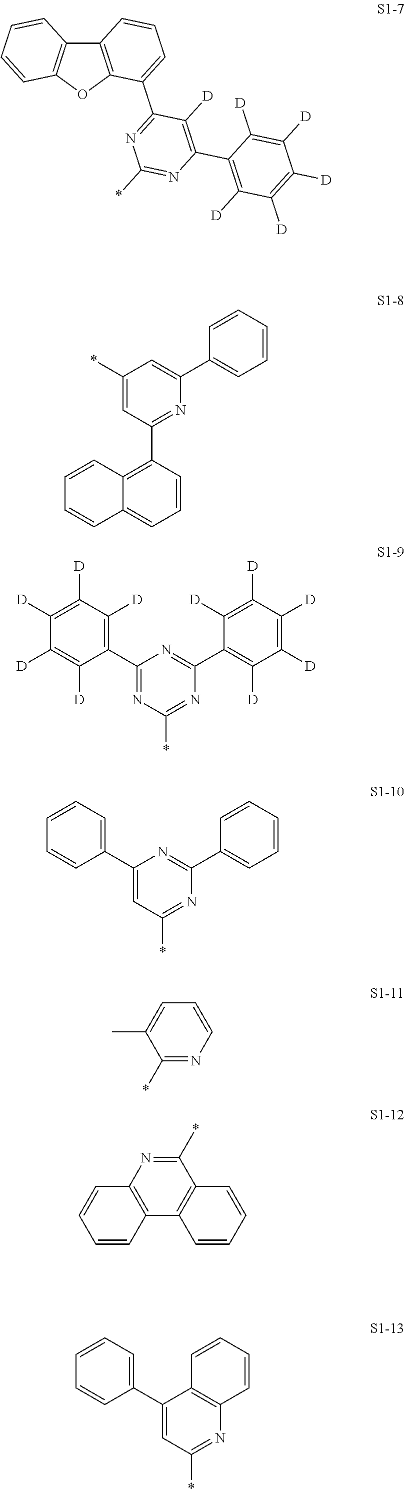

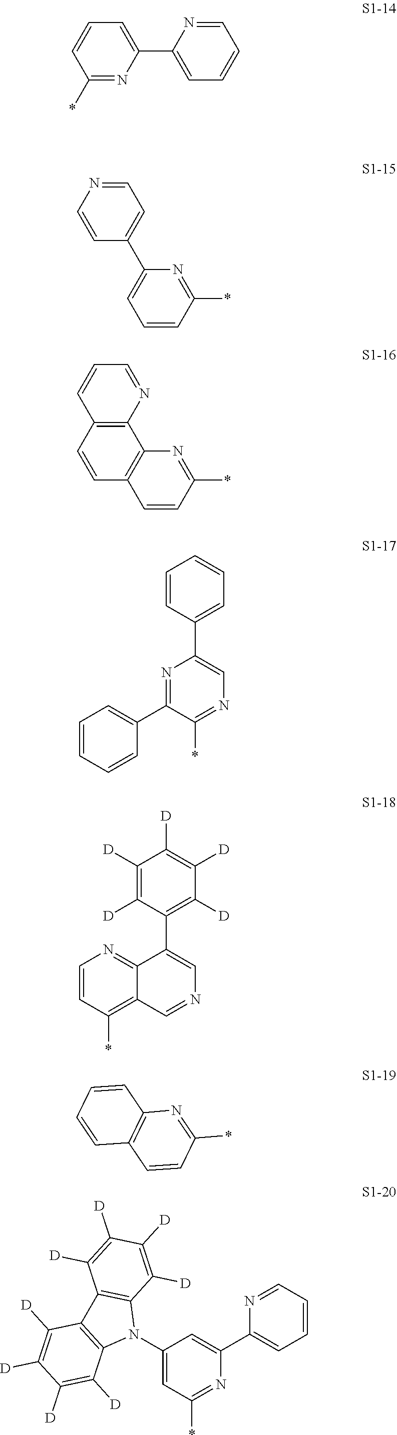

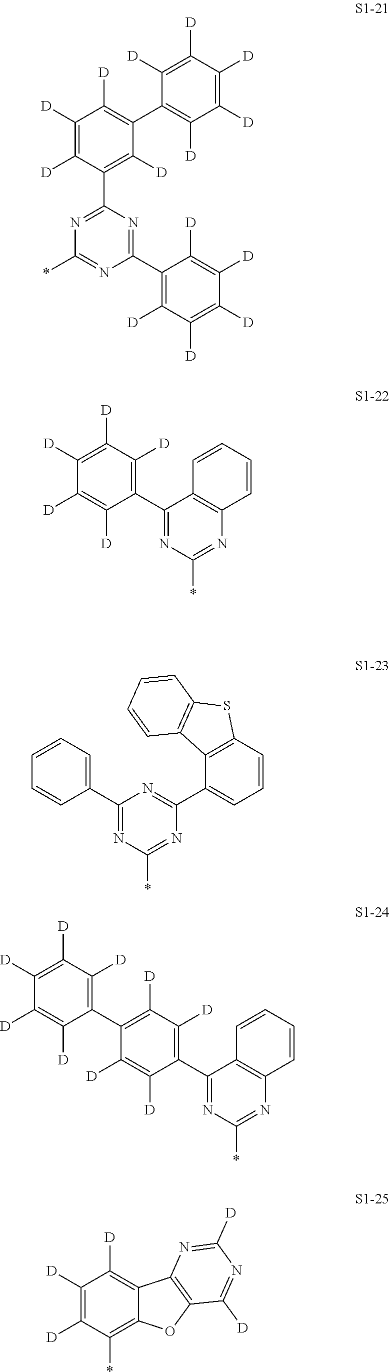 [SMILES: *c1nc(-c2c([2H])c([2H])c([2H])c([2H])c2[2H])nc(-c2c([2H])c([2H])c([2H])c(-c3c([2H])c([2H])c([2H])c([2H])c3[2H])c2[2H])n1 ; *c1nc(-c2c([2H])c([2H])c([2H])c([2H])c2[2H])c2ccccc2n1 ; *c1nc(-c2ccccc2)nc(-c2cccc3sc4ccccc4c23)n1 ; *c1nc(-c2c([2H])c([2H])c(-c3c([2H])c([2H])c([2H])c([2H])c3[2H])c([2H])c2[2H])c2ccccc2n1 ; *c1c([2H])c([2H])c([2H])c2c1oc1c([2H])nc([2H])nc12]

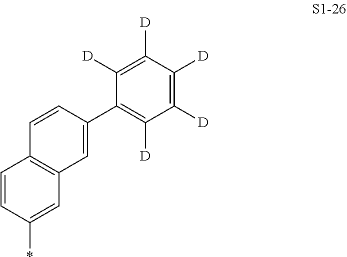 [SMILES: *c1ccc2ccc(-c3c([2H])c([2H])c([2H])c([2H])c3[2H])cc2c1]

In one or more embodiments, if (e.g., when) Ar₁ in Formula 1 is not represented by Formula 1-A, at least one selected from among Ar₁ and R₁ to R₈ may be a substituted or unsubstituted heteroaryl group having 2 to 30 ring-forming carbon atoms including a nitrogen atom as a ring-forming atom, or include, as a substituent, a substituted or unsubstituted heteroaryl group having 2 to 30 ring-forming carbon atoms including a nitrogen atom as a ring-forming atom. For example, Ar₁ in Formula 1 may not be represented by Formula 1-A, and, in one or more embodiments, Ar₁ may be a heteroaryl group including a nitrogen atom as a ring-forming atom, for example, a substituted or unsubstituted benzofuropyrimidine group, and/or the like. In one or more embodiments, Ar₁ in Formula 1 may be a substituted or unsubstituted aryl group having 6 to 30 ring-forming carbon atoms, and, in one or more embodiments, at least one selected from among R₁ to R₈ may be a substituted or unsubstituted heteroaryl group including a nitrogen atom as a ring-forming atom, or include, as a substituent, a substituted or unsubstituted heteroaryl group including a nitrogen atom as a ring-forming atom.

In one or more embodiments, at least one selected from among L₁, R₁ to R₈, and/or Ar₁ in Formula 1 may be a deuterium atom or include a substituent including a deuterium atom. As the first compound represented by Formula 1 includes a deuterium atom in a molecule thereof, a molecular structure may be substantially stabilized. Accordingly, lifespan of the light emitting element ED including the first compound may be improved or enhanced.

In one or more embodiments, the first compound may include at least one deuterium atom. A deuterium substitution rate of the first compound represented by Formula 1 may be about 10% to about 100%. The “deuterium substitution rate” used herein refers to a percentage (%) at which a deuterium atom is inserted in place of a hydrogen atom in a compound. The deuterium substitution rate may be measured using, for example, a nuclear magnetic resonance (e.g., ¹H NMR) spectroscopy. For example, if (e.g., when) the “deuterium substitution rate” is analyzed using the nuclear magnetic resonance (e.g., ¹H NMR) spectroscopy, the deuterium substitution rate may be calculated from an integrated quantity of total peaks through an integration ratio in 1H NMR.

The first compound may include at least one deuterium atom and be included in the first green emission layer EML-G1 and the second green emission layer EML-G2 of the second light emitting element ED-2. If (e.g., when) the first compounds are included in the first green emission layer EML-G1 and the second green emission layer EML-G2, a deuterium substitution rate of the first compound included the first green emission layer EML-G1 and a deuterium substitution rate of the first compound included the second green emission layer EML-G2 may be substantially the same or different. For example, the deuterium substitution rate of the first compound included the first green emission layer EML-G1 may be greater than the deuterium substitution rate of the first compound included the second green emission layer EML-G2. In one or more embodiments, the deuterium substitution rate of the first compound included the first green emission layer EML-G1 may be less than the deuterium substitution rate of the first compound included the second green emission layer EML-G2.

The first compound represented by Formula 1 may be represented by any one selected from among the compounds in Compound Group 1. However, the compounds listed in Compound Group 1 herein are examples, and the first compound represented by Formula 1 is not limited to those listed in Compound Group 1. In Compound Group 1, “D” is a deuterium atom.

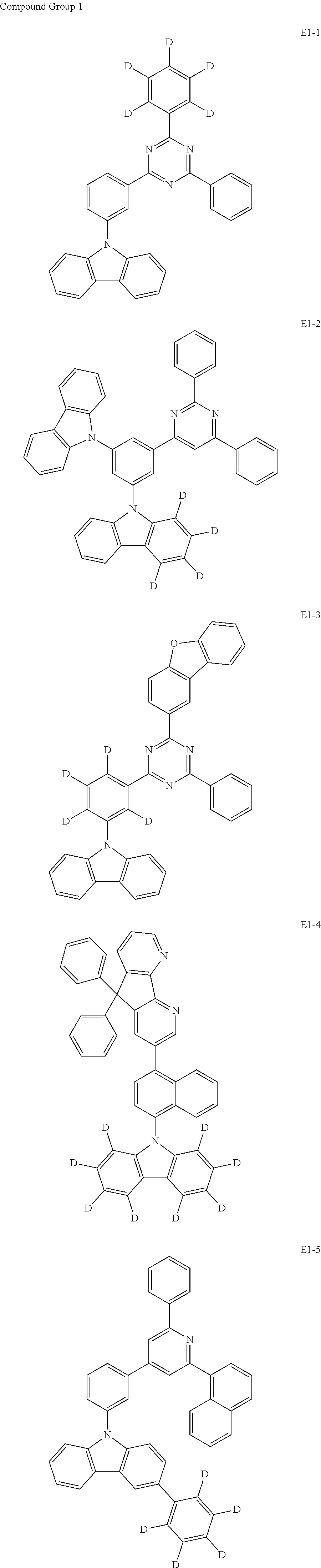

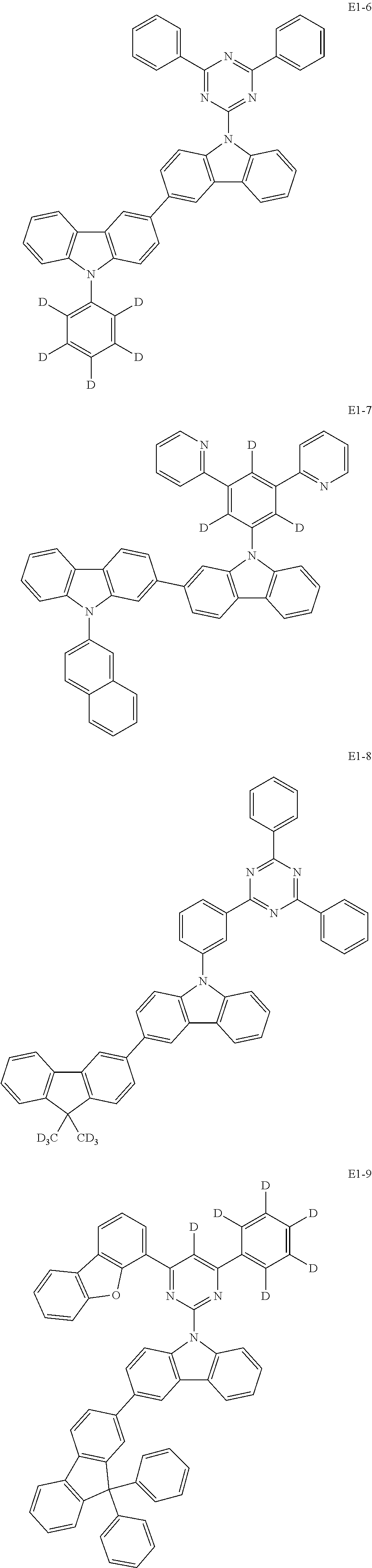 [SMILES: [2H]c1c([2H])c([2H])c(-n2c3ccccc3c3cc(-c4ccc5c(c4)c4ccccc4n5-c4nc(-c5ccccc5)nc(-c5ccccc5)n4)ccc32)c([2H])c1[2H] ; [2H]c1c(-c2ccccn2)c([2H])c(-n2c3ccccc3c3ccc(-c4ccc5c6ccccc6n(-c6ccc7ccccc7c6)c5c4)cc32)c([2H])c1-c1ccccn1 ; [2H]C([2H])([2H])C1(C([2H])([2H])[2H])c2ccccc2-c2cc(-c3ccc4c(c3)c3ccccc3n4-c3cccc(-c4nc(-c5ccccc5)nc(-c5ccccc5)n4)c3)ccc21 ; [2H]c1c(-c2c([2H])c([2H])c([2H])c([2H])c2[2H])nc(-n2c3ccccc3c3cc(-c4ccc5c(c4)C(c4ccccc4)(c4ccccc4)c4ccccc4-5)ccc32)nc1-c1cccc2c1oc1ccccc12]

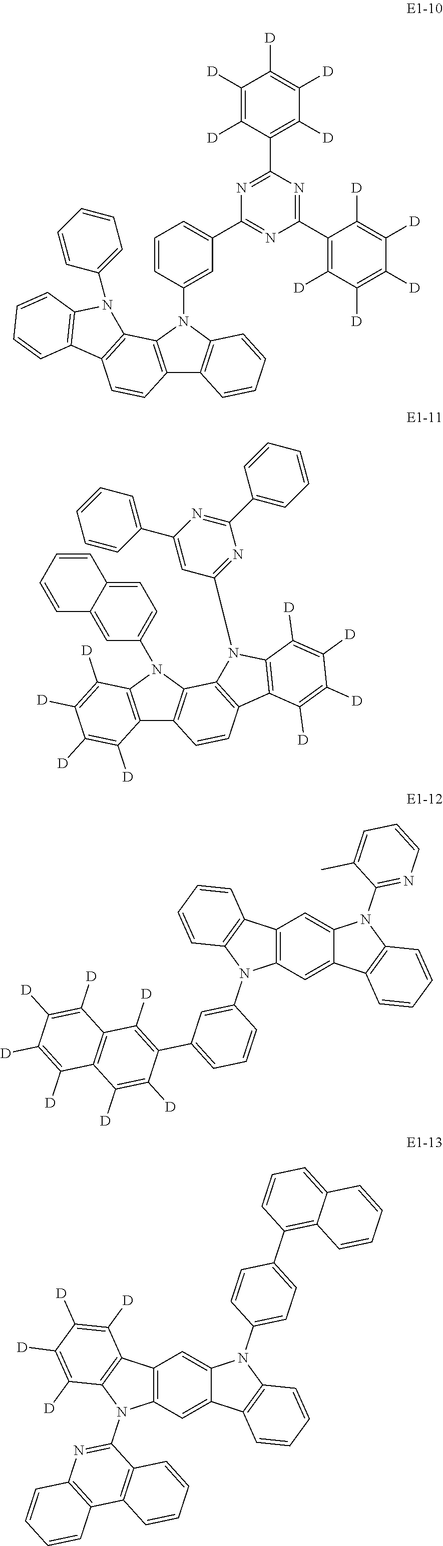 [SMILES: [2H]c1c([2H])c([2H])c(-c2nc(-c3cccc(-n4c5ccccc5c5ccc6c7ccccc7n(-c7ccccc7)c6c54)c3)nc(-c3c([2H])c([2H])c([2H])c([2H])c3[2H])n2)c([2H])c1[2H] ; [2H]c1c([2H])c([2H])c2c(c1[2H])c1ccc3c4c([2H])c([2H])c([2H])c([2H])c4n(-c4cc(-c5ccccc5)nc(-c5ccccc5)n4)c3c1n2-c1ccc2ccccc2c1 ; [2H]c1c([2H])c([2H])c2c([2H])c(-c3cccc(-n4c5ccccc5c5cc6c(cc54)c4ccccc4n6-c4ncccc4C)c3)c([2H])c([2H])c2c1[2H] ; [2H]c1c([2H])c([2H])c2c(c1[2H])c1cc3c(cc1n2-c1nc2ccccc2c2ccccc12)c1ccccc1n3-c1ccc(-c2cccc3ccccc23)cc1]

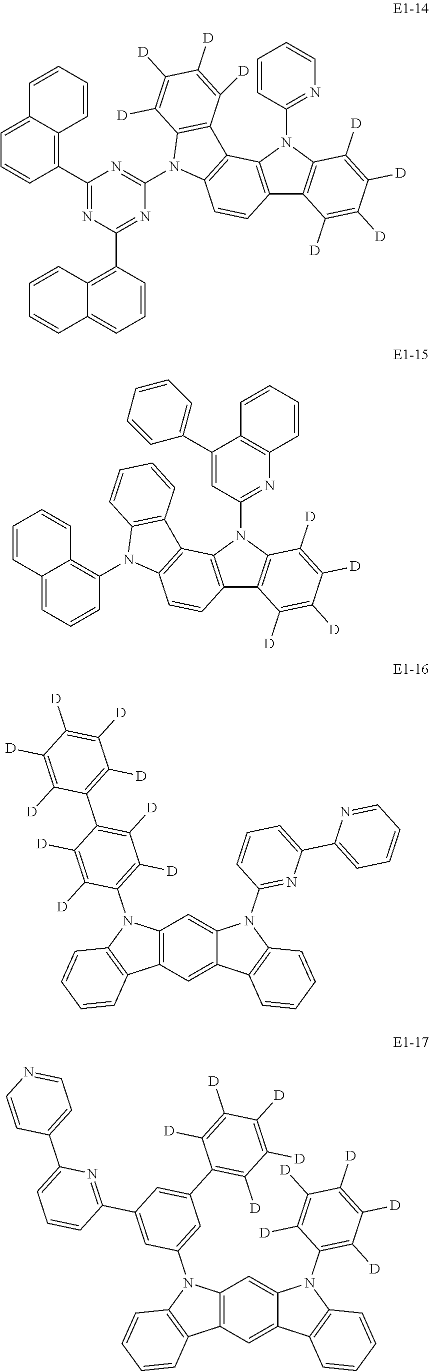 [SMILES: [2H]c1c([2H])c([2H])c2c(c1[2H])c1c(ccc3c4c([2H])c([2H])c([2H])c([2H])c4n(-c4ccccn4)c31)n2-c1nc(-c2cccc3ccccc23)nc(-c2cccc3ccccc23)n1 ; [2H]c1c([2H])c([2H])c2c(c1[2H])c1ccc3c(c4ccccc4n3-c3cccc4ccccc34)c1n2-c1cc(-c2ccccc2)c2ccccc2n1 ; [2H]c1c([2H])c([2H])c(-c2c([2H])c([2H])c(-n3c4ccccc4c4cc5c6ccccc6n(-c6cccc(-c7ccccn7)n6)c5cc43)c([2H])c2[2H])c([2H])c1[2H] ; [2H]c1c([2H])c([2H])c(-c2cc(-c3cccc(-c4ccncc4)n3)cc(-n3c4ccccc4c4cc5c6ccccc6n(-c6c([2H])c([2H])c([2H])c([2H])c6[2H])c5cc43)c2)c([2H])c1[2H]]

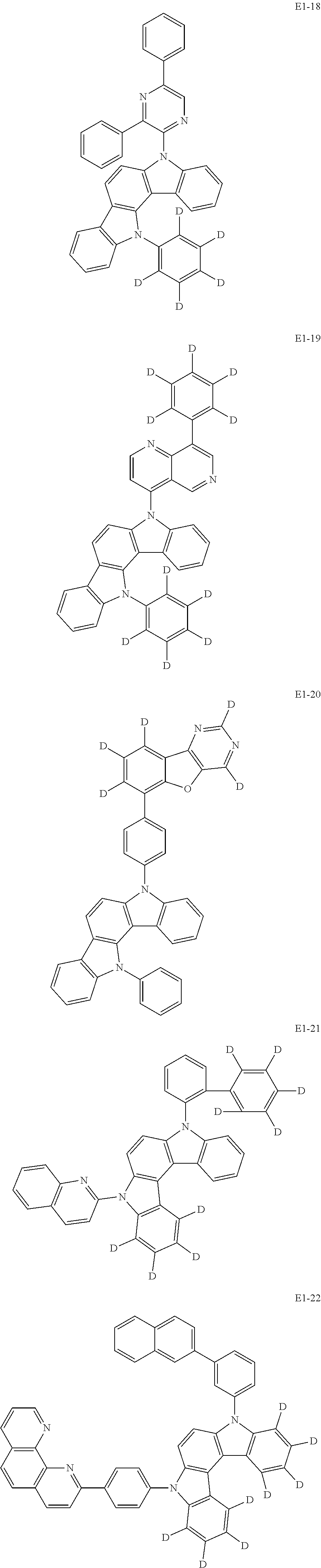

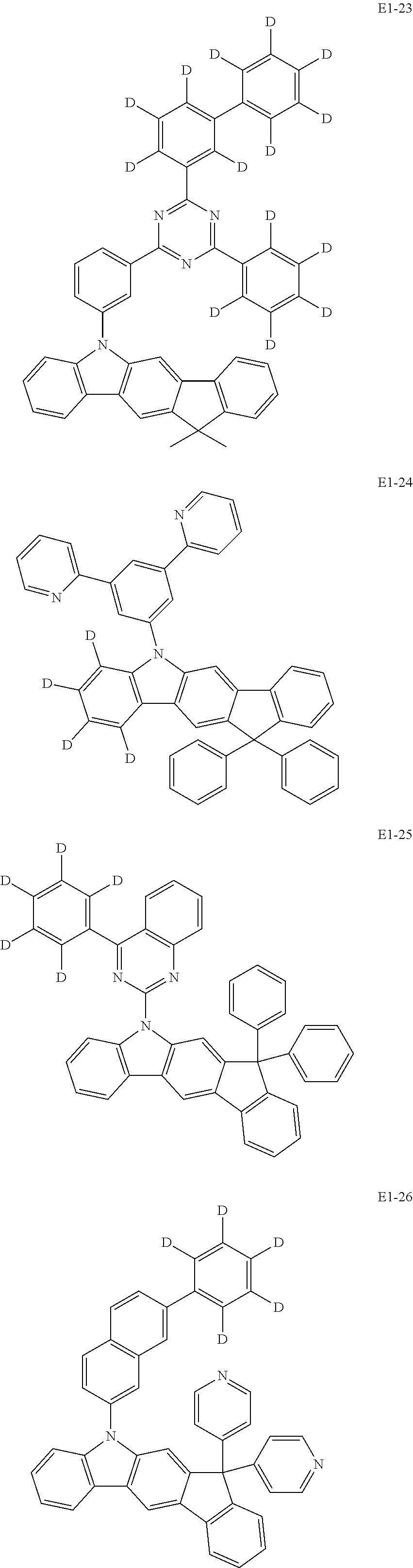 [SMILES: [2H]c1c([2H])c([2H])c(-c2nc(-c3cccc(-n4c5ccccc5c5cc6c(cc54)-c4ccccc4C6(C)C)c3)nc(-c3c([2H])c([2H])c([2H])c(-c4c([2H])c([2H])c([2H])c([2H])c4[2H])c3[2H])n2)c([2H])c1[2H] ; [2H]c1c([2H])c([2H])c2c(c1[2H])c1cc3c(cc1n2-c1cc(-c2ccccn2)cc(-c2ccccn2)c1)-c1ccccc1C3(c1ccccc1)c1ccccc1 ; [2H]c1c([2H])c([2H])c(-c2nc(-n3c4ccccc4c4cc5c(cc43)C(c3ccccc3)(c3ccccc3)c3ccccc3-5)nc3ccccc23)c([2H])c1[2H] ; [2H]c1c([2H])c([2H])c(-c2ccc3ccc(-n4c5ccccc5c5cc6c(cc54)C(c4ccncc4)(c4ccncc4)c4ccccc4-6)cc3c2)c([2H])c1[2H]]

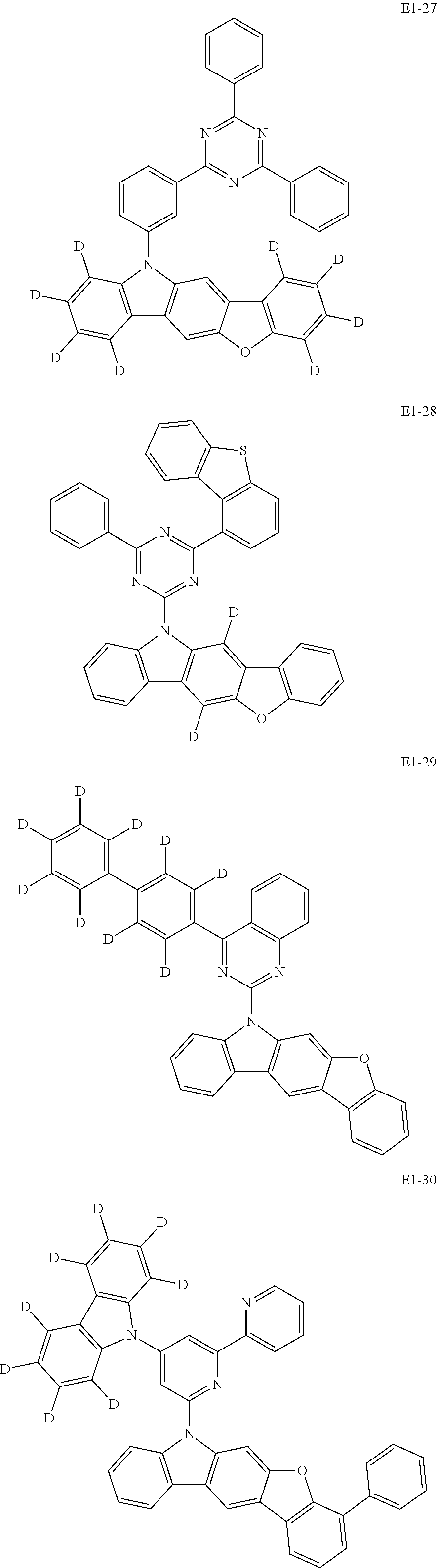 [SMILES: [2H]c1c([2H])c([2H])c2c(oc3cc4c5c([2H])c([2H])c([2H])c([2H])c5n(-c5cccc(-c6nc(-c7ccccc7)nc(-c7ccccc7)n6)c5)c4cc32)c1[2H] ; [2H]c1c2oc3ccccc3c2c([2H])c2c1c1ccccc1n2-c1nc(-c2ccccc2)nc(-c2cccc3sc4ccccc4c23)n1 ; [2H]c1c([2H])c([2H])c(-c2c([2H])c([2H])c(-c3nc(-n4c5ccccc5c5cc6c(cc54)oc4ccccc46)nc4ccccc34)c([2H])c2[2H])c([2H])c1[2H] ; [2H]c1c([2H])c([2H])c2c(c1[2H])c1c([2H])c([2H])c([2H])c([2H])c1n2-c1cc(-c2ccccn2)nc(-n2c3ccccc3c3cc4c(cc32)oc2c(-c3ccccc3)cccc24)c1]

The light emitting element ED according to one or more embodiments may include, as the first light emitting material, at least one selected from among the compounds in Compound Group 1. For example, in the light emitting element ED according to one or more embodiments, the first green emission layer EML-G1 and the second green emission layer EML-G2 of the second light emitting element ED-2 may each include at least one selected from among the compounds in Compound Group 1. The first green emission layer EML-G1 and the second green emission layer EML-G2 may include substantially the same first compound. However, embodiments of the present disclosure are not limited thereto, and the first green emission layer EML-G1 and the second green emission layer EML-G2 may include different first compounds. As the first green emission layer EML-G1 and the second green emission layer EML-G2 of the second light emitting element ED-2 include the first compound represented by Formula 1, the light emitting element ED according to one or more embodiments may be improved or enhanced in lifespan.

In one or more embodiments, the second compound may be represented by Formula 2. The second compound represented by Formula 2 may be included in each of the first blue emission layer EML-B1 and the second blue emission layer EML-B2 of the third light emitting element ED-3. However, embodiments of the present disclosure are not limited thereto, and the second compound represented by Formula 2 may also be included in each of the first blue emission auxiliary layer SE-B1 and the second blue emission auxiliary layer SE-B2.

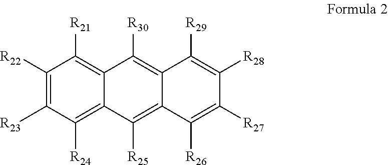

In Formula 2, R₂₁ to R₃₀ may each independently be a hydrogen atom, a deuterium atom, a substituted or unsubstituted aryl group having 6 to 30 ring-forming carbon atoms, or a substituted or unsubstituted heteroaryl group having 5 to 30 ring-forming carbon atoms. For example, R₂₁ to R₃₀ may each independently be a hydrogen atom, a deuterium atom, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted dibenzofuran group, a substituted or unsubstituted dibenzothiophene group, or a substituted or unsubstituted fluorenyl group.

In one or more embodiments, at least one selected from among R₂₁ to R₃₀ in Formula 2 may be a deuterium atom or include a substituent including a deuterium atom. As the second compound represented by Formula 2 includes a deuterium atom in a molecule thereof, a molecular structure may be substantially stabilized. Accordingly, the light emitting element ED including the second compound may be improved or enhanced in lifespan.

In one or more embodiments, the second compound may include at least one deuterium atom, and be included in each of the first blue emission layer EML-B1 and the second blue emission layer EML-B2 of the third light emitting element ED-3. A deuterium substitution rate with respect to the second compound may about 3% to about 100%. For example, in the aspect of improvement or enhancement in lifespan of a device, the deuterium substitution rate of the second compound may about 30% to about 100%. As the deuterium substitution rate of the second compound increase, an effect of improving or enhancing the lifespan due to deuterium may increase or enhance. In the case where the second compounds are included in the first blue emission layer EML-B1 and the second blue emission layer EML-B2, a deuterium substitution rate of the second compound included the first blue emission layer EML-B1 and a deuterium substitution rate of the second compound included the second blue emission layer EML-B2 may be substantially the same or different. For example, the deuterium substitution rate of the second compound included the first blue emission layer EML-B1 may be greater than the deuterium substitution rate of the second compound included the second blue emission layer EML-B2. In one or more embodiments, the deuterium substitution rate of the second compound included the first blue emission layer EML-B1 may be less than the deuterium substitution rate of the second compound included the second blue emission layer EML-B2.

In one or more embodiments, Formula 2 may be represented by Formula 2-1.

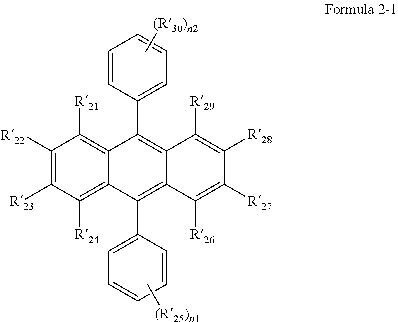

In Formula 2-1, R′₂₁ to R′₂₄ and R′₂₆ to R′₂₉ may each independently be a hydrogen atom or a deuterium atom. R′₂₅ and R′₃₀ may each independently be a hydrogen atom, a deuterium atom, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 15 ring-forming carbon atoms, or a substituted or unsubstituted heteroaryl group having 2 to 15 ring-forming carbon atoms, or bonded to an adjacent group to form a ring. Each of R′₂₅ and R′₃₀ may be bonded to an adjacent group to form a saturated hydrocarbon ring, an unsaturated hydrocarbon ring, a substituted heterocycle, or an unsubstituted heterocycle.

In Formula 2-1, n1 and n2 may each independently be an integer of 0 to 5. If (e.g., when) n1 and n2 are each an integer of 2 or more, each of two or more R′₂₅ and two or more R′₃₀ may be all the same or at least one thereof may be different from the remainder. In one or more embodiments, a case where n1 is 0 may be the same as a case where n1 is 5, and five R′₂₅ may be all hydrogen atoms. It may be understood that the case where n1 is 0 corresponds to a case where R′₂₅ is not substituted in Formula 2-1. In one or more embodiments, a case where n2 is 0 may be the same as a case where n2 is 5, and five R's are all hydrogen atoms. It may be understood that the case where n2 is 0 corresponds to a case where R′₃₀ is not substituted in Formula 2-1.

The second compound represented by Formula 2 may be represented by any one selected from among the compounds in Compound Group 2. However, the compounds listed in Compound Group 2 herein are examples, and the second compound represented by Formula 2 is not limited to those listed in Compound Group 2. In Compound Group 2, “D” is a deuterium atom.

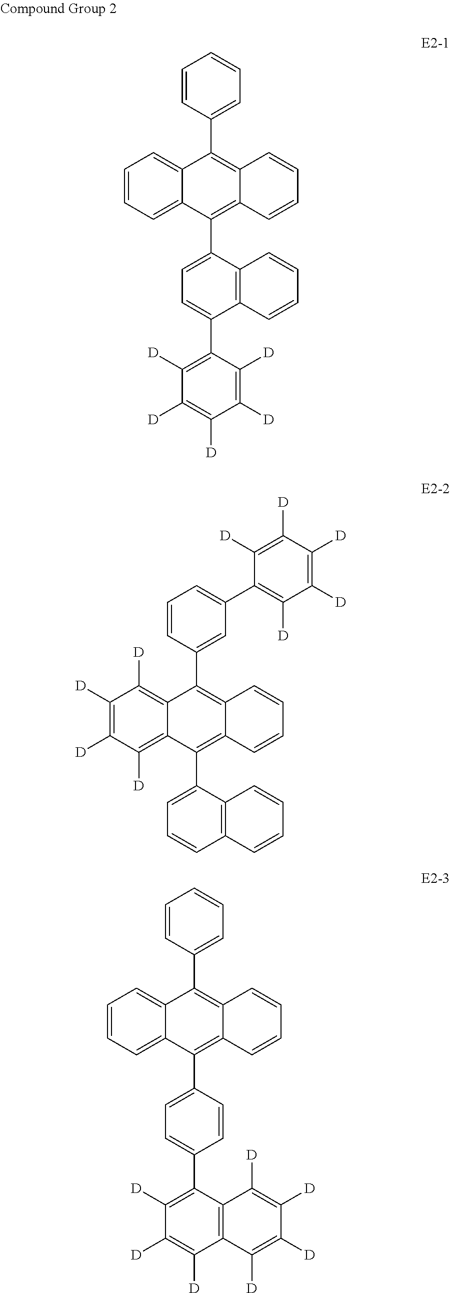

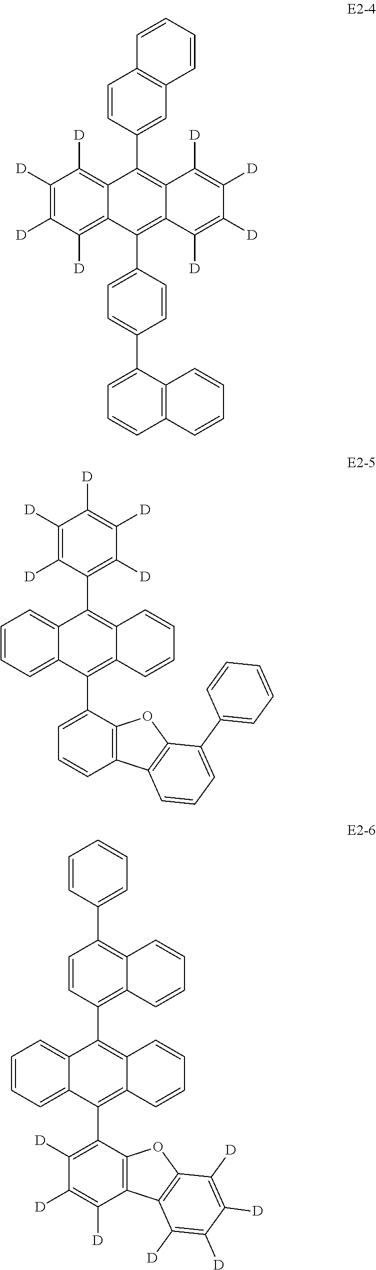 [SMILES: [2H]c1c([2H])c([2H])c2c(-c3ccc4ccccc4c3)c3c([2H])c([2H])c([2H])c([2H])c3c(-c3ccc(-c4cccc5ccccc45)cc3)c2c1[2H] ; [2H]c1c([2H])c([2H])c(-c2c3ccccc3c(-c3cccc4c3oc3c(-c5ccccc5)cccc34)c3ccccc23)c([2H])c1[2H] ; [2H]c1c([2H])c([2H])c2c(oc3c(-c4c5ccccc5c(-c5ccc(-c6ccccc6)c6ccccc56)c5ccccc45)c([2H])c([2H])c([2H])c32)c1[2H]]

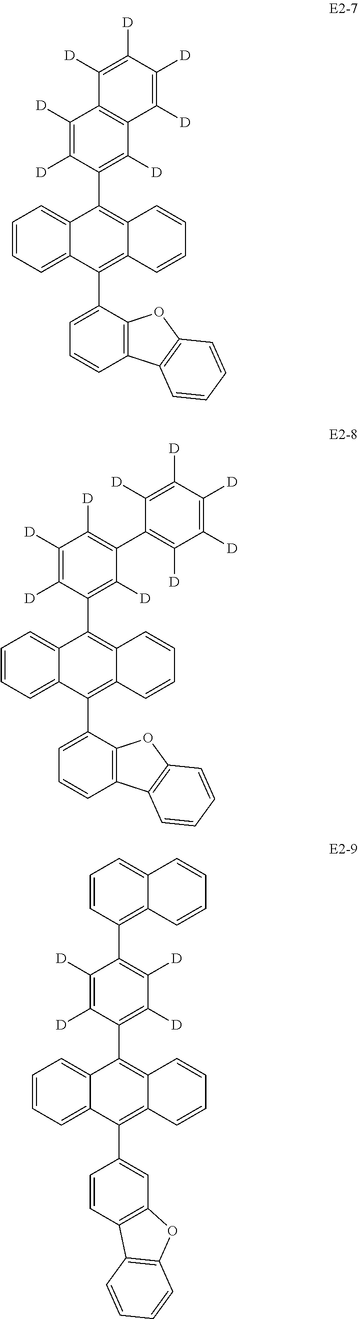

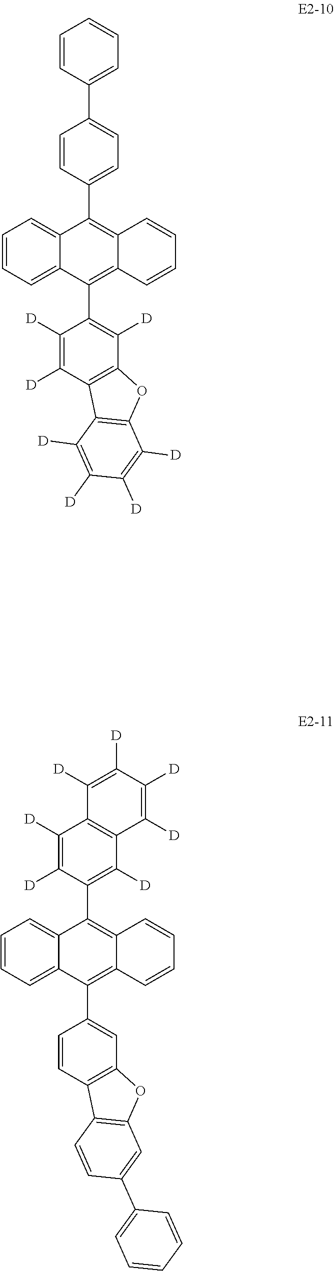 [SMILES: [2H]c1c([2H])c([2H])c2c(oc3c([2H])c(-c4c5ccccc5c(-c5ccc(-c6ccccc6)cc5)c5ccccc45)c([2H])c([2H])c32)c1[2H] ; [2H]c1c([2H])c([2H])c2c([2H])c(-c3c4ccccc4c(-c4ccc5c(c4)oc4cc(-c6ccccc6)ccc45)c4ccccc34)c([2H])c([2H])c2c1[2H]]

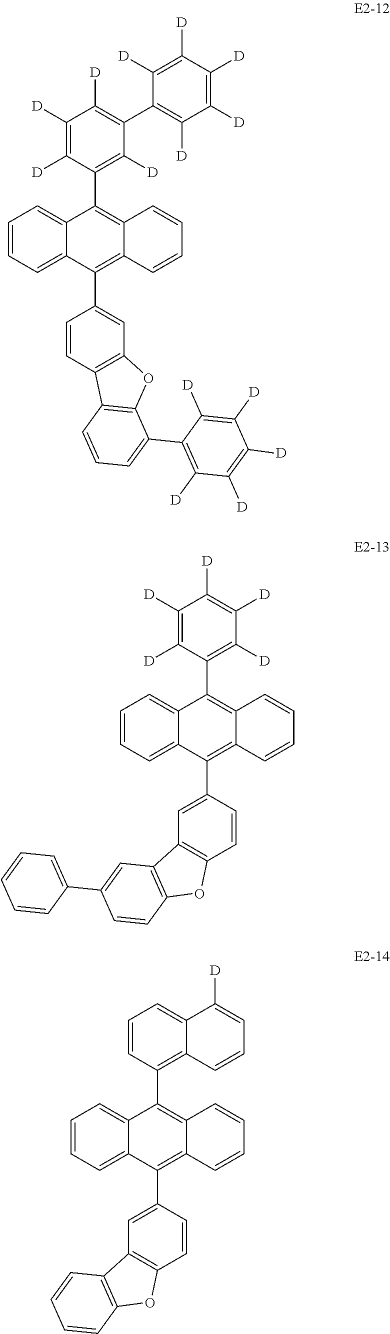 [SMILES: [2H]c1c([2H])c([2H])c(-c2c([2H])c([2H])c([2H])c(-c3c4ccccc4c(-c4ccc5c(c4)oc4c(-c6c([2H])c([2H])c([2H])c([2H])c6[2H])cccc45)c4ccccc34)c2[2H])c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H] ; [2H]c1cccc2c(-c3c4ccccc4c(-c4ccc5oc6ccccc6c5c4)c4ccccc34)cccc12]

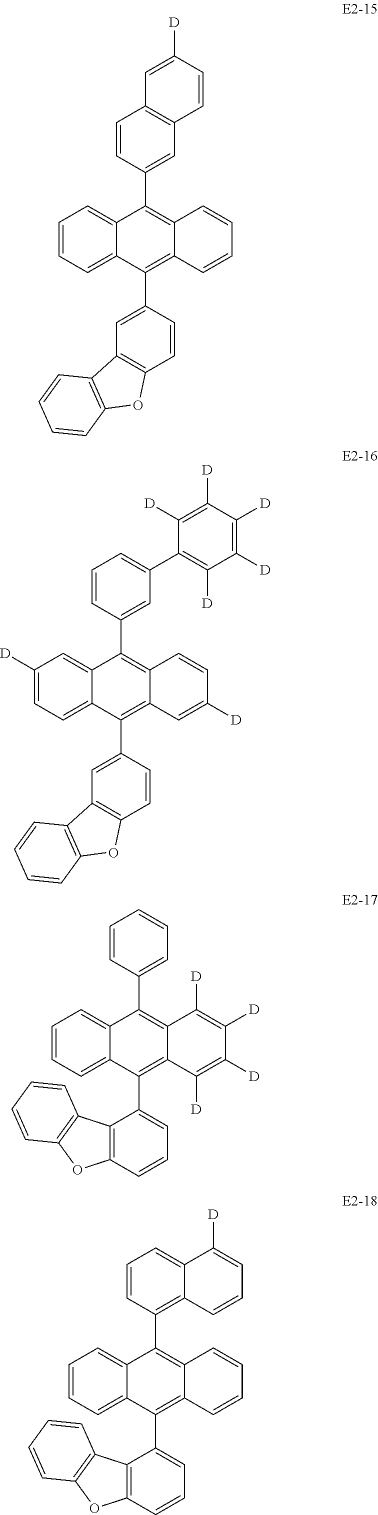 [SMILES: [2H]c1ccc2cc(-c3c4ccccc4c(-c4ccc5oc6ccccc6c5c4)c4ccccc34)ccc2c1 ; [2H]c1ccc2c(-c3ccc4oc5ccccc5c4c3)c3cc([2H])ccc3c(-c3cccc(-c4c([2H])c([2H])c([2H])c([2H])c4[2H])c3)c2c1 ; [2H]c1c([2H])c([2H])c2c(-c3cccc4oc5ccccc5c34)c3ccccc3c(-c3ccccc3)c2c1[2H] ; [2H]c1cccc2c(-c3c4ccccc4c(-c4cccc5oc6ccccc6c45)c4ccccc34)cccc12]

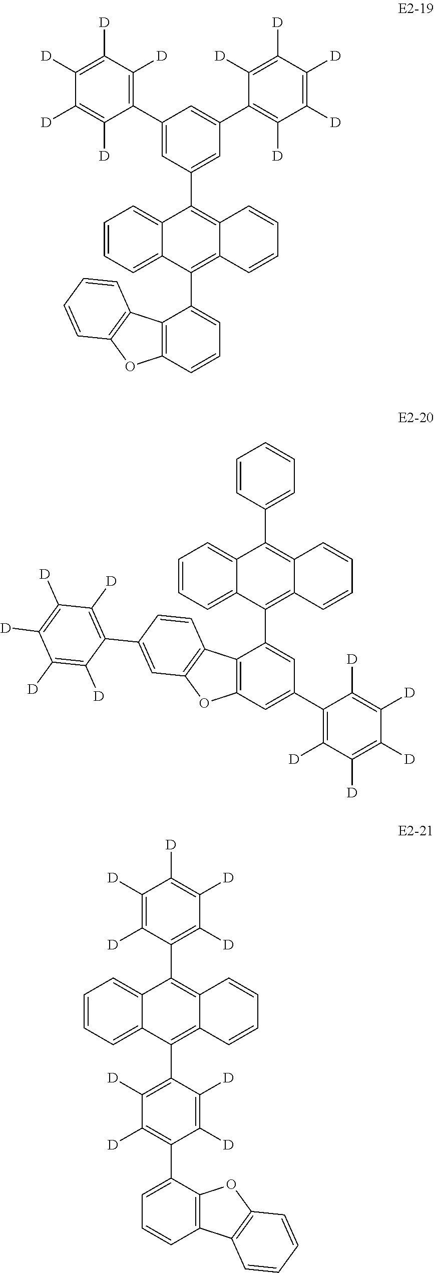 [SMILES: [2H]c1c([2H])c([2H])c(-c2cc(-c3c([2H])c([2H])c([2H])c([2H])c3[2H])cc(-c3c4ccccc4c(-c4cccc5oc6ccccc6c45)c4ccccc34)c2)c([2H])c1[2H] ; [2H]c1c([2H])c([2H])c(-c2ccc3c(c2)oc2cc(-c4c([2H])c([2H])c([2H])c([2H])c4[2H])cc(-c4c5ccccc5c(-c5ccccc5)c5ccccc45)c23)c([2H])c1[2H] ; [2H]c1c([2H])c([2H])c(-c2c3ccccc3c(-c3c([2H])c([2H])c(-c4cccc5c4oc4ccccc45)c([2H])c3[2H])c3ccccc23)c([2H])c1[2H]]

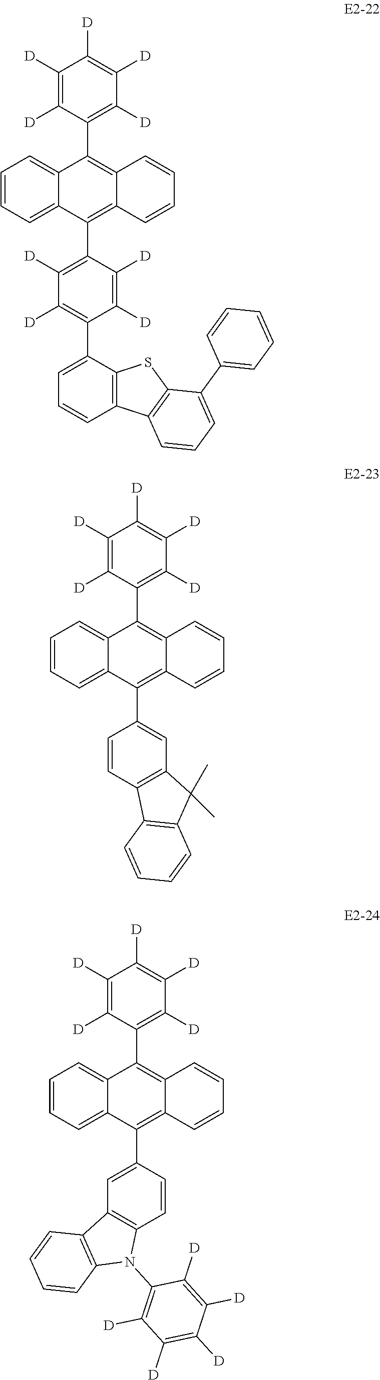 [SMILES: [2H]c1c([2H])c([2H])c(-c2c3ccccc3c(-c3c([2H])c([2H])c(-c4cccc5c4sc4c(-c6ccccc6)cccc45)c([2H])c3[2H])c3ccccc23)c([2H])c1[2H] ; [2H]c1c([2H])c([2H])c(-c2c3ccccc3c(-c3ccc4c(c3)C(C)(C)c3ccccc3-4)c3ccccc23)c([2H])c1[2H] ; [2H]c1c([2H])c([2H])c(-c2c3ccccc3c(-c3ccc4c(c3)c3ccccc3n4-c3c([2H])c([2H])c([2H])c([2H])c3[2H])c3ccccc23)c([2H])c1[2H]]

The light emitting element ED according to one or more embodiments may include, as the first light emitting material, at least one selected from among the compounds in Compound Group 2. For example, in the light emitting element ED, the first blue emission layer EML-B1 and the second blue emission layer EML-B2 of the third light emitting element ED-3 may include at least one selected from among the compounds in Compound Group 2. The first blue emission layer EML-B1 and the second blue emission layer EML-B2 may include substantially the same second compound. However, embodiments of the present disclosure are not limited thereto, and the first blue emission layer EML-B1 and the second blue emission layer EML-B2 may include different second compounds. As the first blue emission layer EML-B1 and the second blue emission layer EML-B2 of the third light emitting element ED-3 include the second compounds represented by Formula 2, the light emitting element ED according to one or more embodiments may be improved or enhanced in lifespan.

In one or more embodiments, the emission layers EML1 and EML2 may each include a phosphorescent sensitizer. For example, the emission layers EML1 and EML2 may each include an organometallic complex including platinum (Pt) as a central metal atom and ligands bonded to the central metal atom. In the light emitting element ED according to one or more embodiments, the emission layers EML1 and EML2 may include a compound represented by Formula D-1. At least one selected from the first emission layer EML1 and/or the second emission layer EML2 may include the compound represented by Formula D-1.

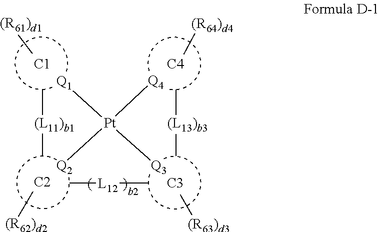

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

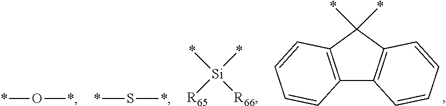

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” represents a site linked to one of C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₆₁ to R₆₆ may each be bonded to an adjacent group to form a ring. R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) d1 to d4 are each 0, the compound represented by Formula D-1 may be unsubstituted with R₆₁ to R₆₄. A case where d1 to d4 are each 0, and R₆₁ to R₆₄ are each a hydrogen atom may be substantially the same the case where d1 to d4 are each 0. If (e.g., when) d1 to d4 are each an integer of 2 or more, each of two or more R₆₁ to two or more R₆₄ may be all the same, or at least one selected from among two or more R₆₁ to two or more R₆₄ may be different.

In Formula D-1, C1 to C4 may each independently be a substituted or unsubstituted hydrocarbon ring or a substituted or unsubstituted heterocycle, represented by any one selected from among C-1 to C-4.

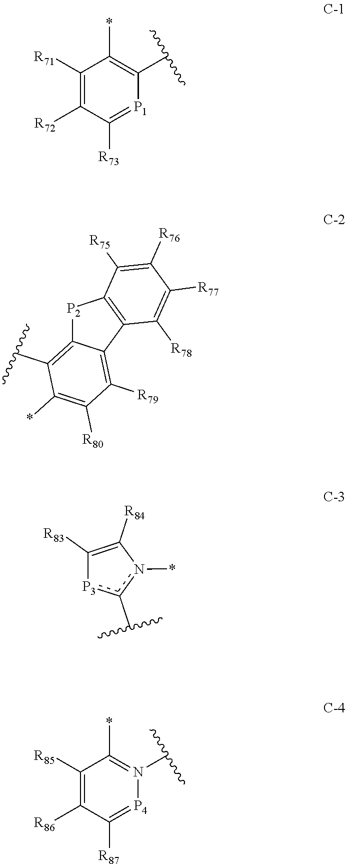

In C-1 to C-4, P1— may be C—* or CR₇₄, P2 may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group or 2 to 30 ring-forming carbon atoms, or bonded to an adjacent group to form a ring.

In C-1 to C-4

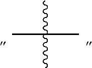

is a part connected with Pt that is a central metal atom, and “-*” corresponds to a part connected with neighboring ring groups (C1 to C4) or linkers (L₁₁ to L₁₃).

In one or more embodiments, the compound represented by Formula D-1 may be represented by at least one selected from among the compounds represented in Compound Group AD. The emission layers EML1 and EML2 may include at least one selected from among the compounds represented in Compound Group AD herein as a phosphorescent sensitizer material.

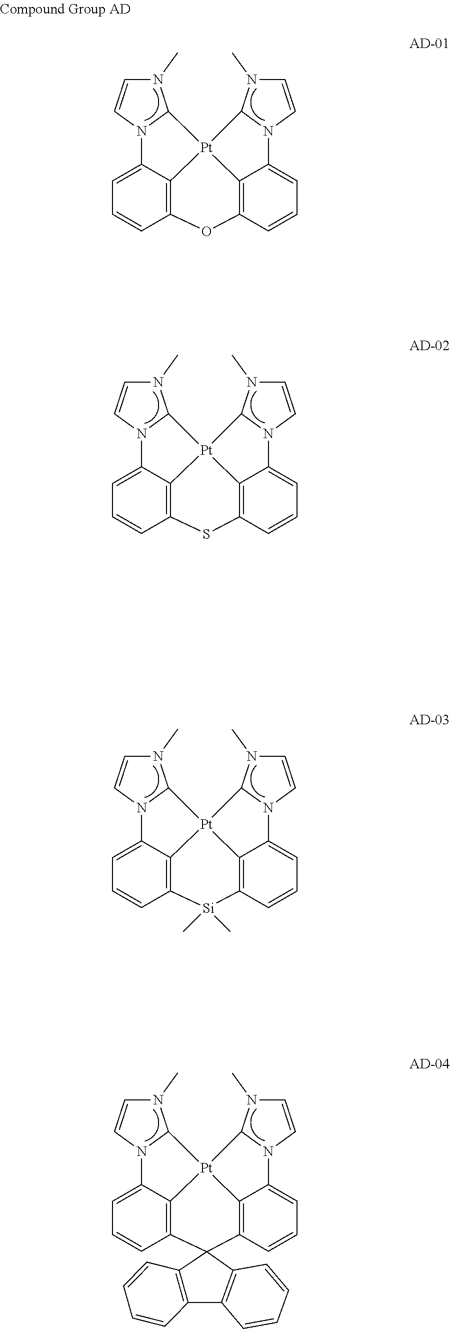

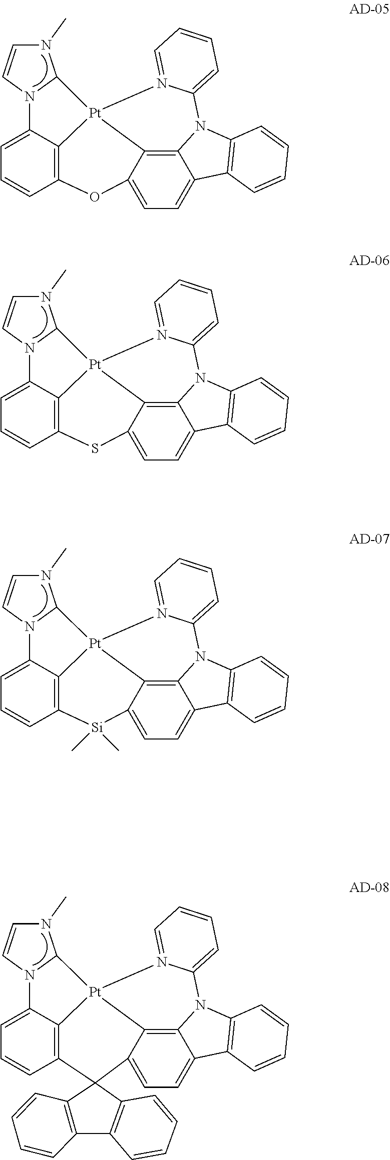

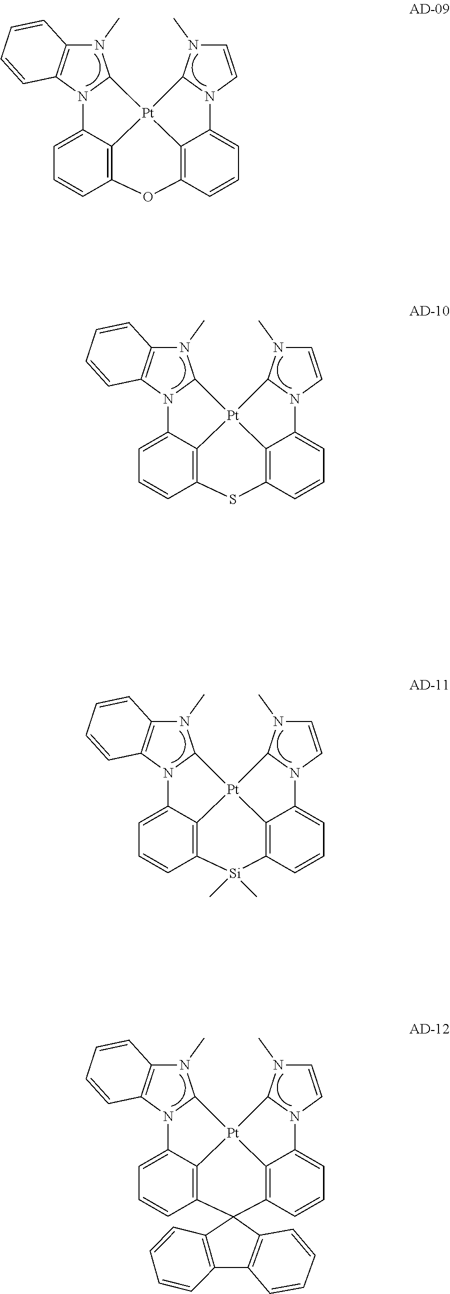

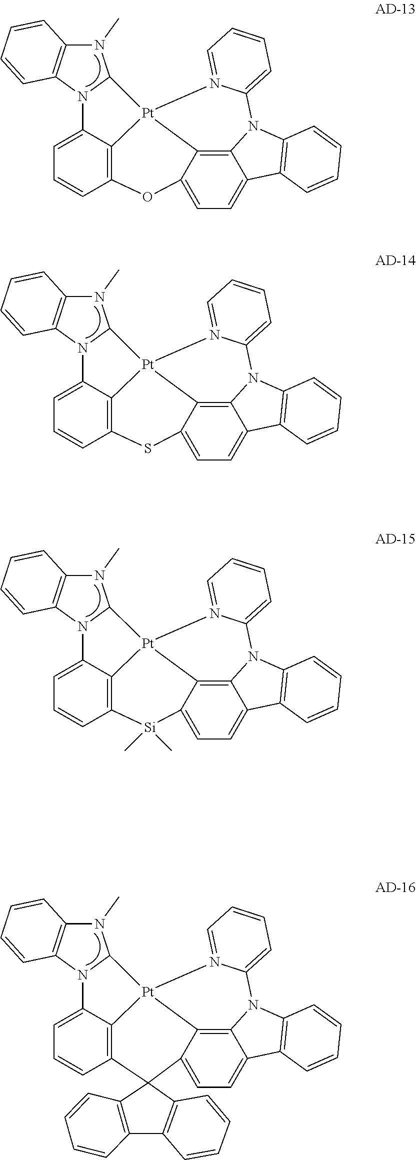

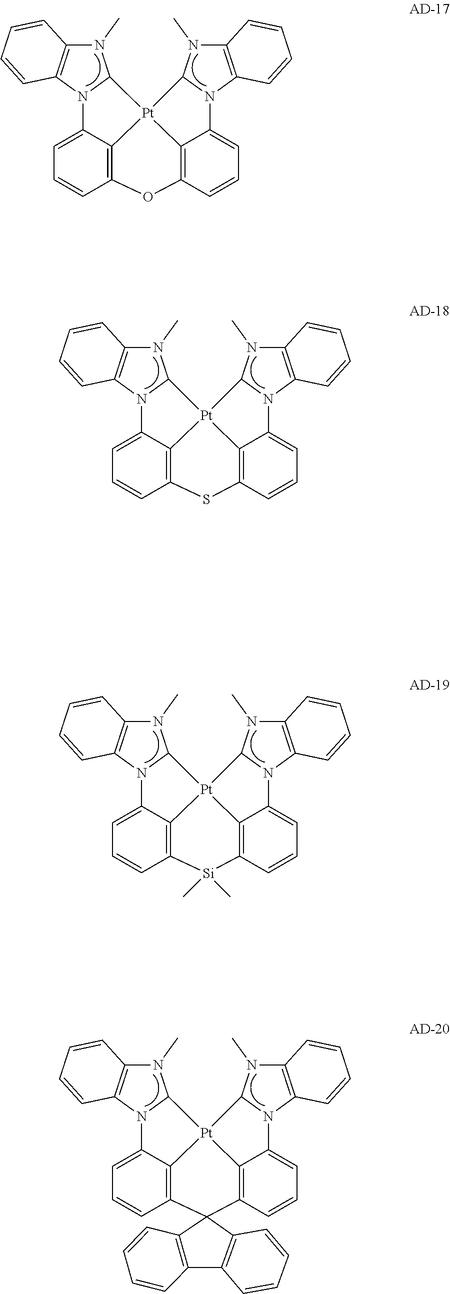

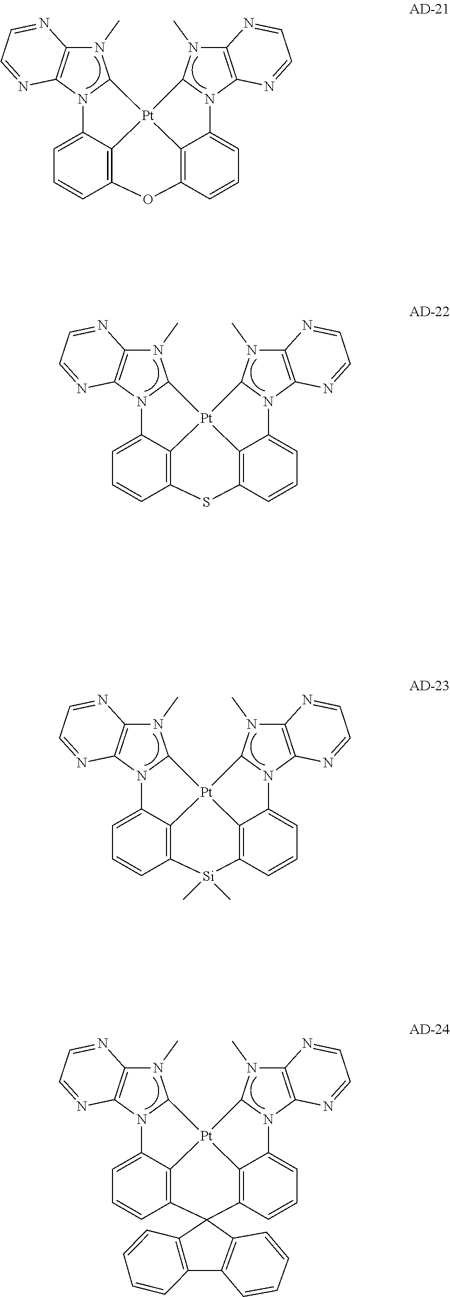

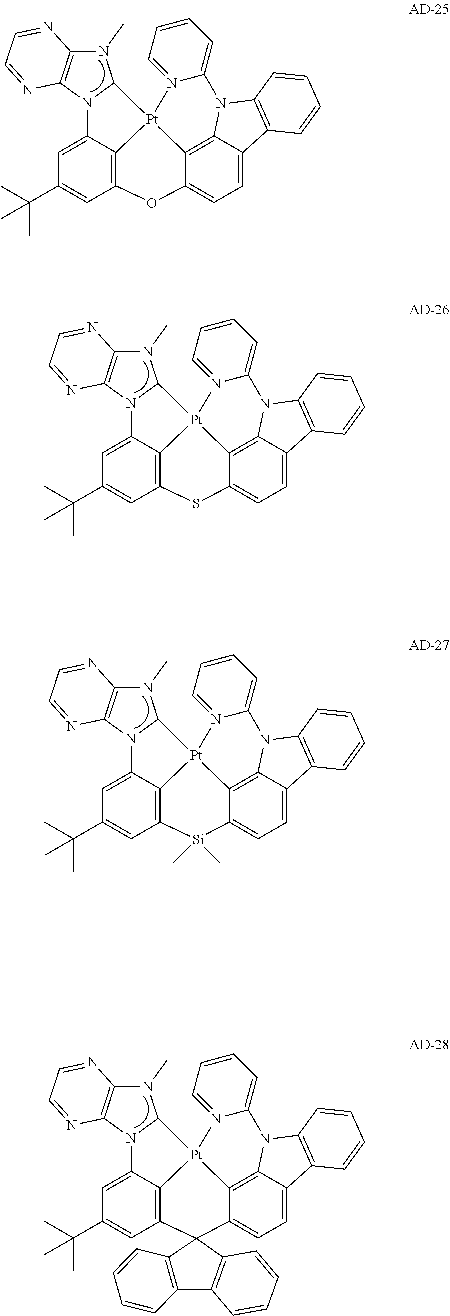

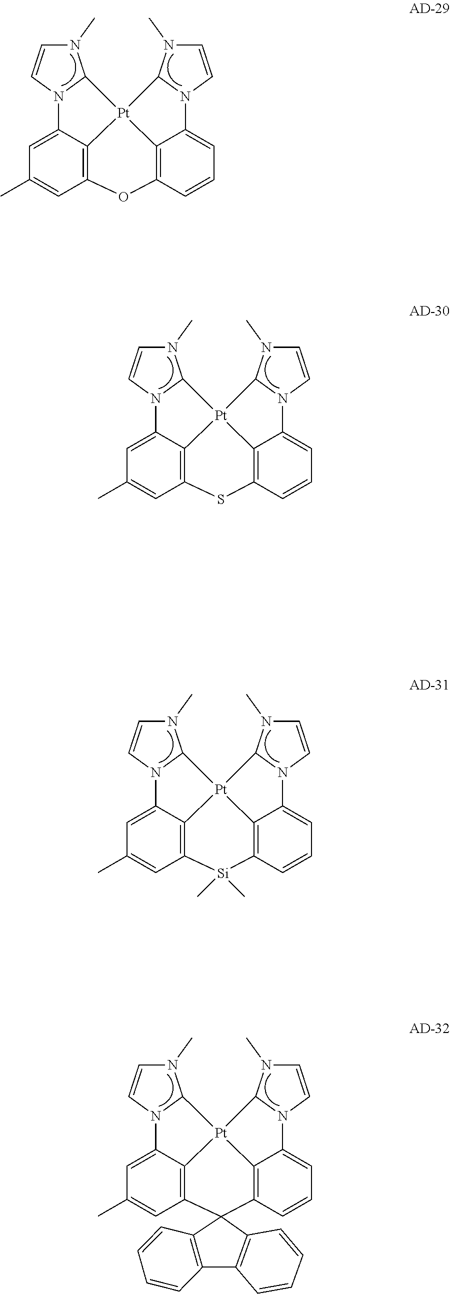

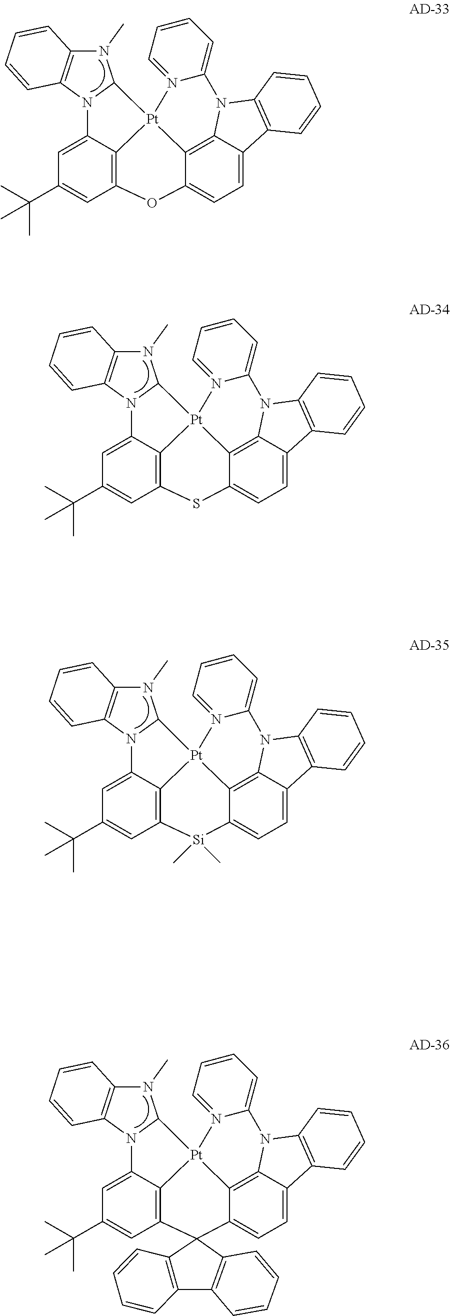

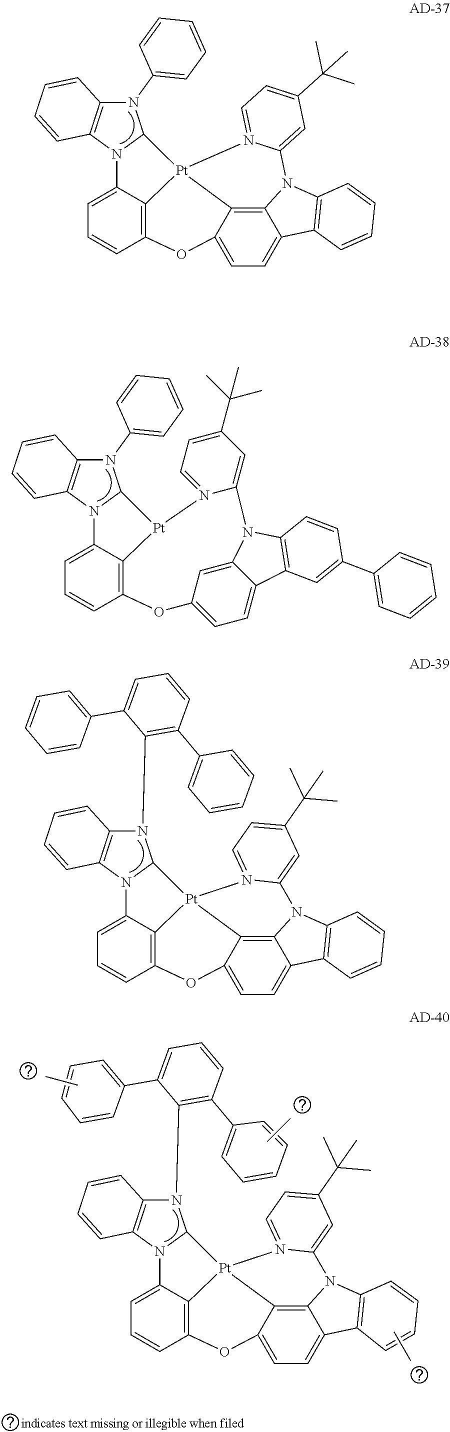

In the compounds provided as examples in Compound Group AD, “D” indicates a deuterium atom.

In one or more embodiments, in addition to the first compound and the second compound as described in one or more embodiments, the emission layers EML may each include an anthracene derivative, a pyrene derivative, a fluoranthene derivative, a chrysene derivative, a dihydrobenzanthracene derivative, or a triphenylene derivative. For example, the first emission layer EML1 may include an anthracene derivative or a pyrene derivative.

Each of the emission layers EML may be formed or provided using one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The emission layers EML may each include a host and a dopant, and the emission layers EML may each include a compound represented by Formula E-1. For example, the blue emission layers EML-B1 and EML-B2 may further include the compound represented by Formula E-1, in addition to the second compound represented by Formula 2. The compound represented by Formula E-1 herein may be used as a fluorescence host material.

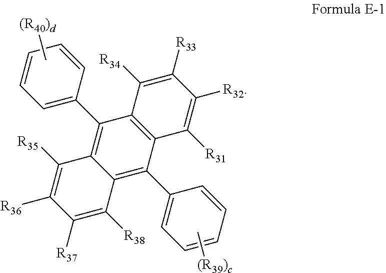

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. R₃₁ to R₄₀ may each be bonded to an adjacent group to form a saturated hydrocarbon ring, an unsaturated hydrocarbon ring, a substituted heterocycle, or an unsubstituted heterocycle.

In Formula E-1, c and d may each independently be an integer of 0 to 5.

Formula E-1 may be represented by any one selected from among Compounds E1 to E19.

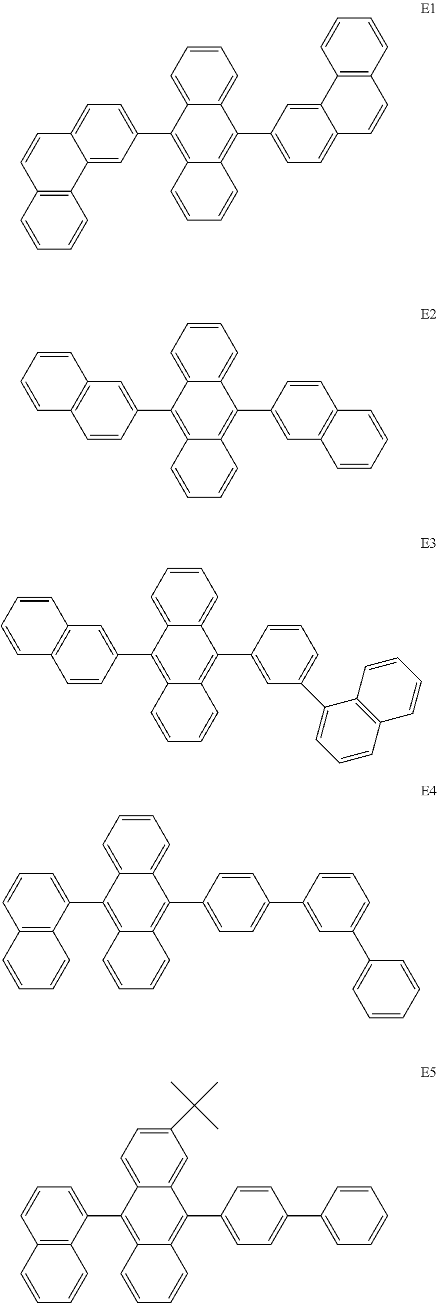

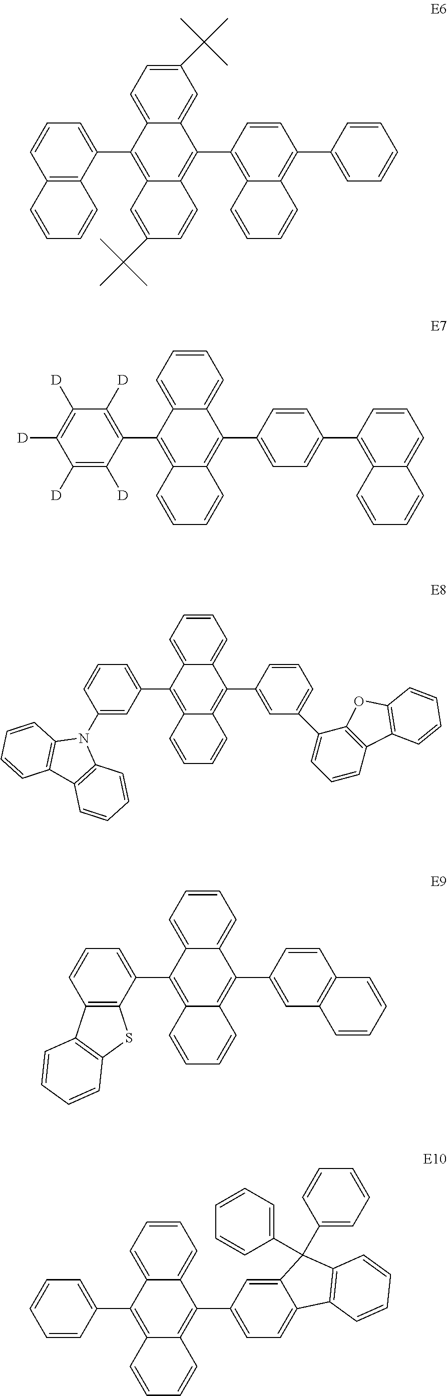

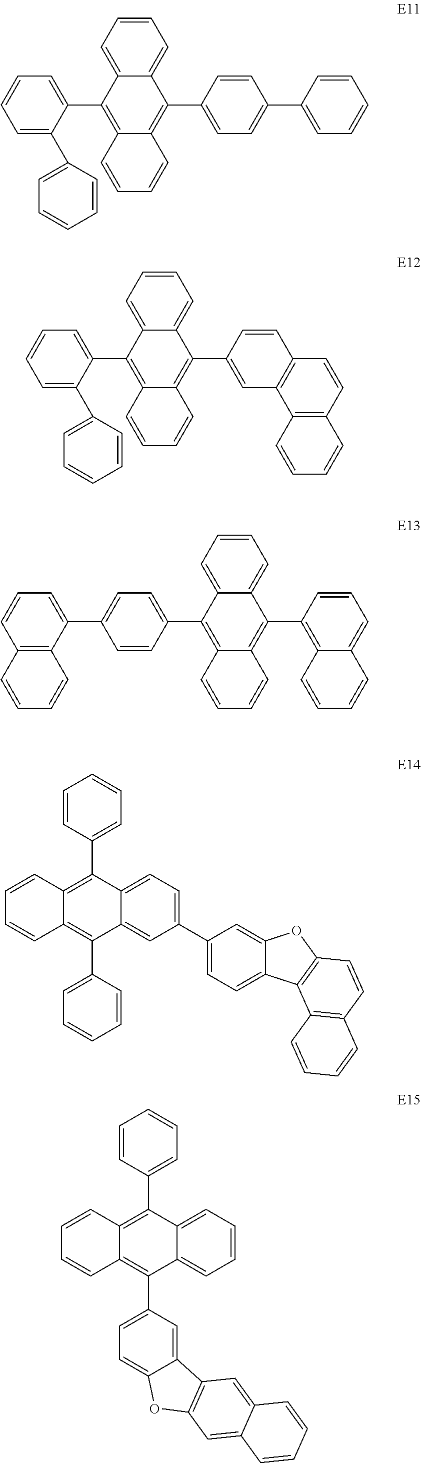

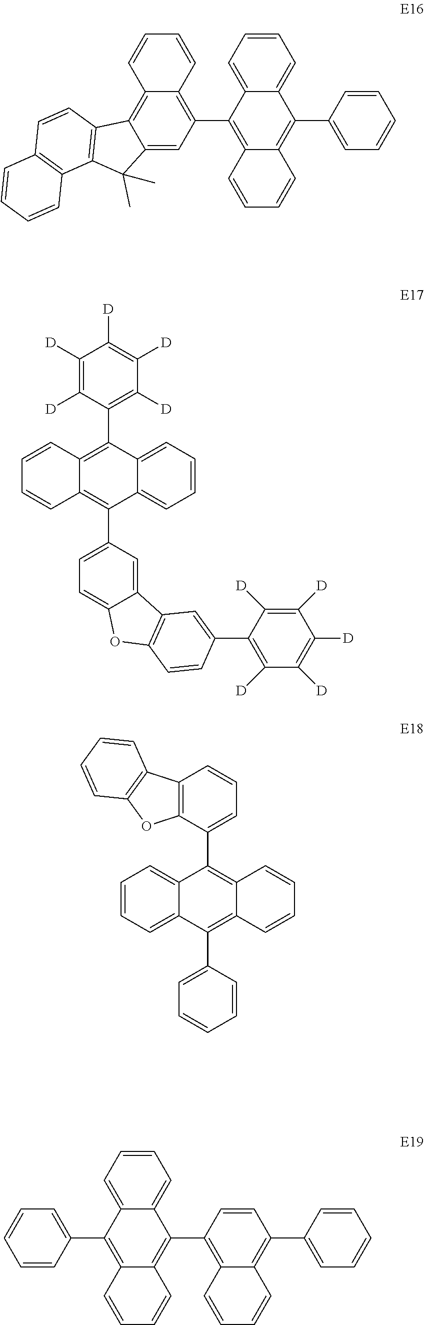

In one or more embodiments, the emission layers EML1 and EML2 may each include a compound represented by Formula E-2a or E-2b. For example, the red emission layers EML-R₁ and EML-R₂ may each include the compound represented by Formula E-2a or E-2b. The compound represented by Formula E-2a or E-2b may be used as a host material for phosphorescent light element.

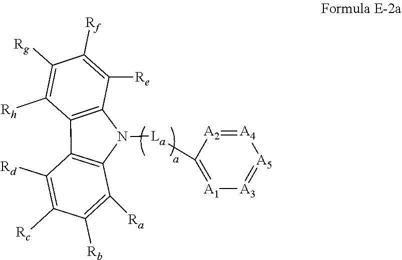

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. If (e.g., when) a is an integer of 2 or more, two or more La may each independently be a substituted or unsubstituted arylene group having 6 to 30 1 ring-forming carbon atoms or a substituted or unsubstituted heteroarylene group having 2 to 30 ring-forming carbon atoms.

In Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. Rₐ to Rᵢ may each be bonded to an adjacent group to form a hydrocarbon ring, or a heterocycle including N, O, or S as a ring-forming carbon atom.

In Formula E-2a, two or three selected from among A₁ to A₅ may be N, and the remainder may be CRᵢ.

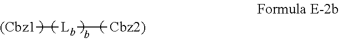

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer of 0 to 10, and if (e.g., when) b is an integer of 2 or more, two or more L_{b} may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or E-2b may be represented by any one selected from among the compounds in Compound Group E-2. However, the compounds listed in Compound Group E-2 are examples, and the compound represented by Formula E-2a or E-2b is not limited to those listed in Compound Group E-2.

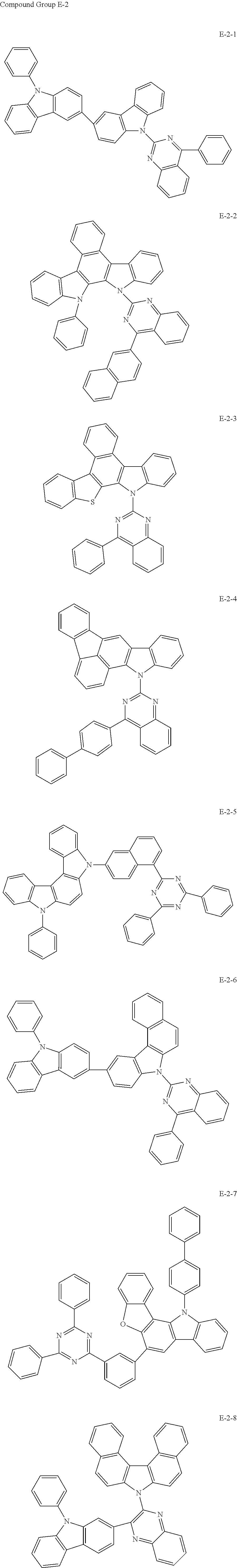

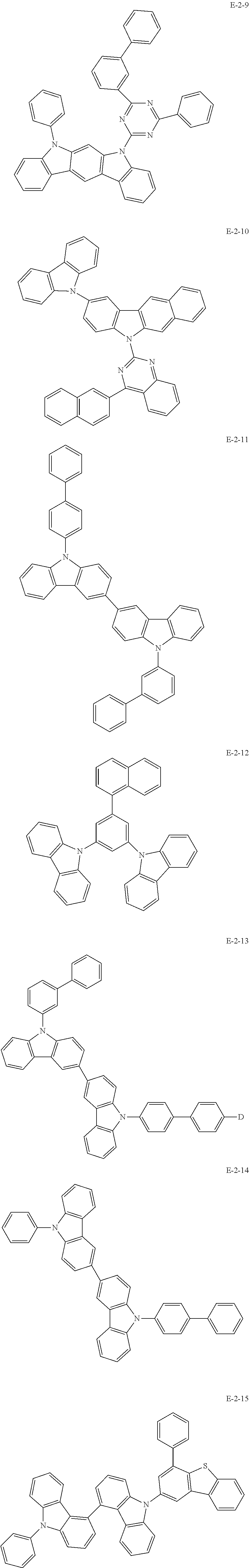

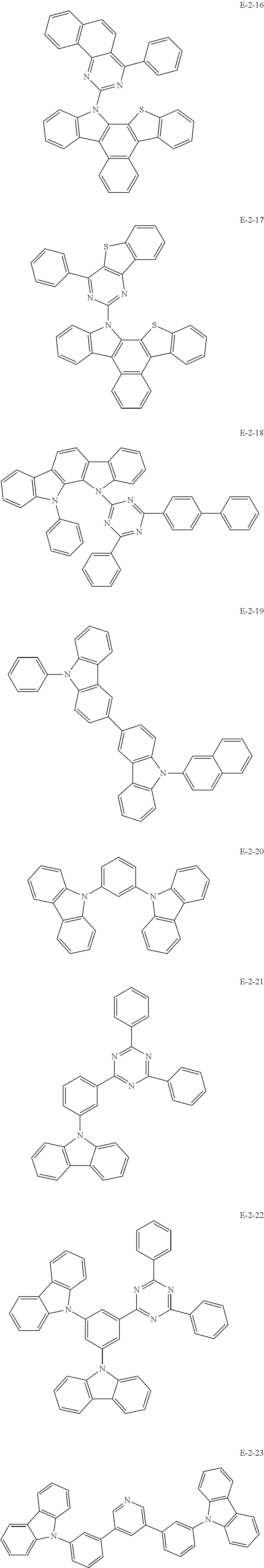

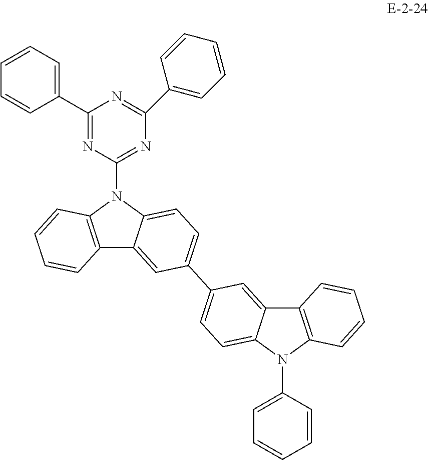 [SMILES: c1ccc(-c2nc(-c3ccccc3)nc(-n3c4ccccc4c4cc(-c5ccc6c(c5)c5ccccc5n6-c5ccccc5)ccc43)n2)cc1]

Each of the emission layers EML1 and EML2 may further include, as a host material, a material generally used in this technical field. For example, each of the emission layers EML1 and EML2 may include, as a host material, at least one selected from among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, embodiments of the present disclosure are not limited thereto, and for example, tris(8-hydroxyquinolino)aluminum (Alq₃), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be used as a host material.

The emission layers EML1 and EML2 may each include a compound represented by Formula M-a. The compound represented by Formula M-a may be used as a phosphorescent dopant material.

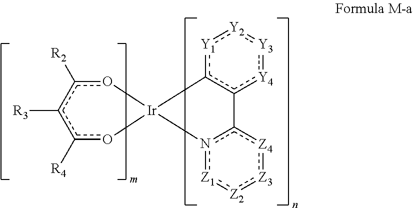

In Formula M-a, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, if (e.g., when) m is 0, n may be 3, and if (e.g., when) m is 1, n may be 2.

The compound represented by Formula M-a may be used as a phosphorescent dopant.

The compound represented by Formula M-a may be represented by any one selected from among Compounds M-a1 to M-a25. However, Compounds M-a1 to M-a25 are examples, and the compound represented by Formula M-a is not limited to those represented as Compounds M-a1 to M-a25.

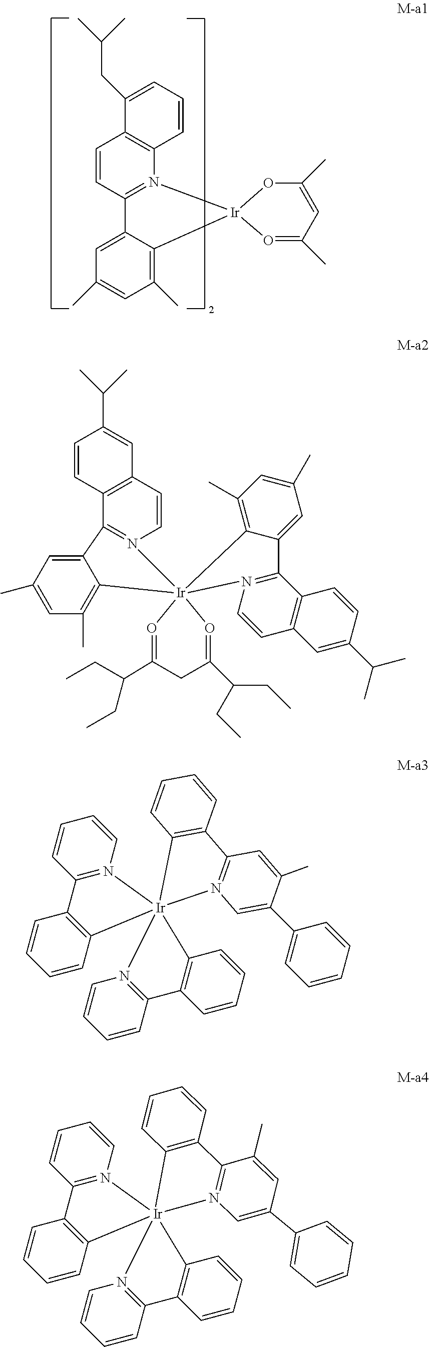

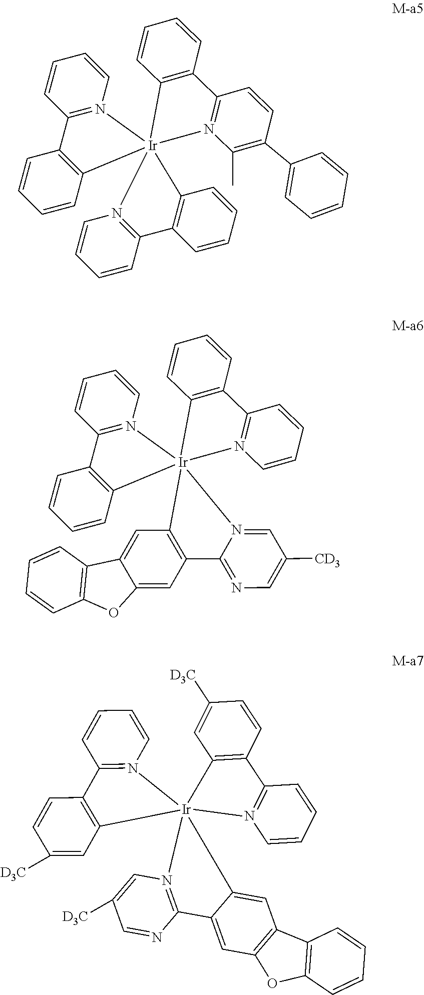

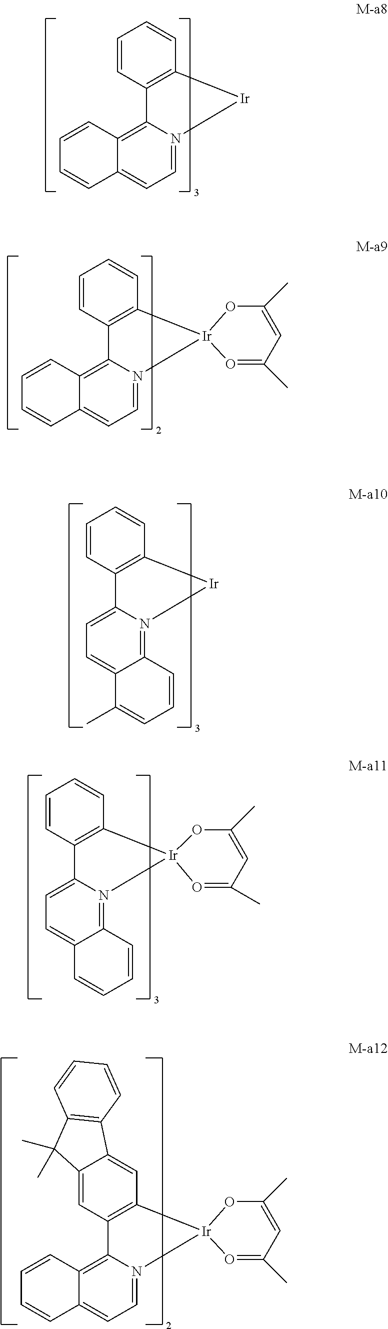

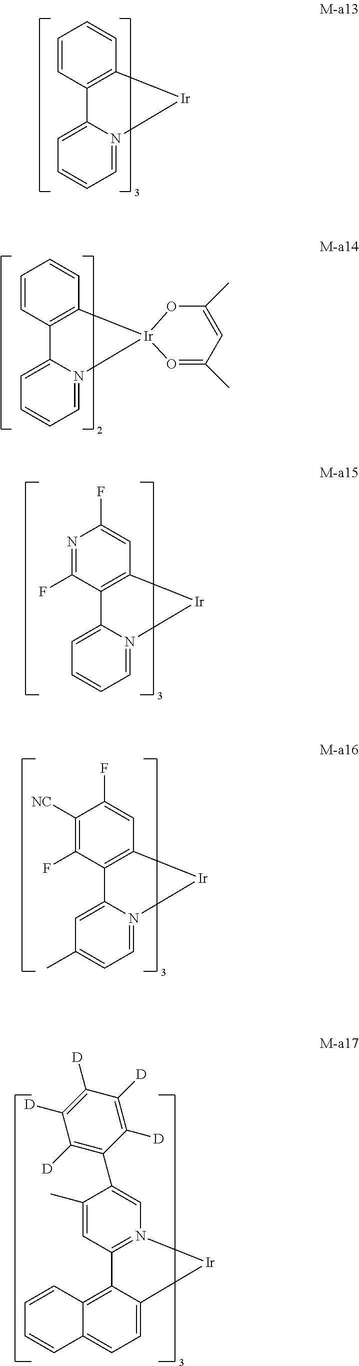

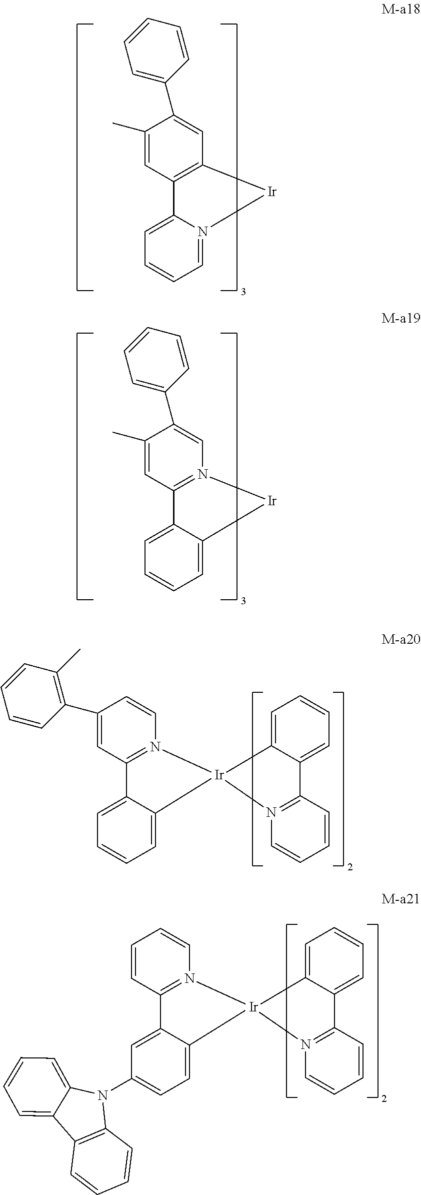

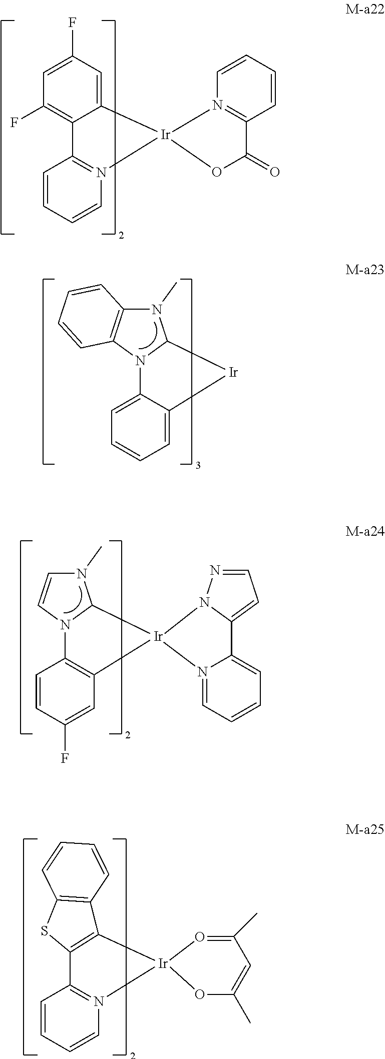

Each of the emission layers EML1 and EML2 may further include a compound represented by any one selected from among Formulae F-a to F-c. The compounds represented by Formulae F-a to F-c may be used as fluorescence dopant materials.

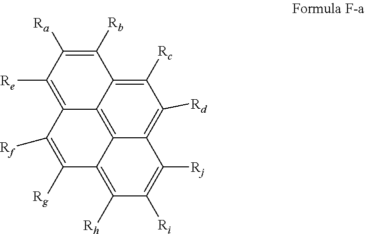

In Formula F-a, two selected from among Rₐ to Rⱼ may each independently be substituted with *—NArₐ₁Arₐ₂. Among Rₐ to Rⱼ, the remainder unsubstituted with *—NArₐ₁Arₐ₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NArₐ₁Arₐ₂, Arₐ₁ and Arₐ₂ may each independently be a substituted or unsubstituted aryl group having 6 to 30 ring-forming carbon atoms or a substituted or unsubstituted heteroaryl group having 2 to 30 ring-forming carbon atoms. For example, at least one selected from Arₐ₁ and/or Arₐ₂ may be a heteroaryl group including O or S as a ring-forming carbon atom.

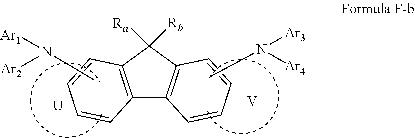

In Formula F-b, Rₐ₁ and R_{b1} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. Ar_{b1} to Ar_{b4} may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. At least one selected from among Ar_{b1} to Ar_{b4} may be a heteroaryl group including O or S as a ring-forming carbon atom.

In Formula F-b, the number of rings represented by U and V may each independently be 0 or 1. For example, in Formula F-b, a case where the number of U or V is 1 refers to that one ring may form a fused ring at a part indicated by U or V, and a case where the number of U or V is 0 refers to that a ring indicated by U or V may not exist. For example, if (e.g., when) the number of U is 0 and the number of V is 1 or if (e.g., when) the number of U is 1 and the number of V is 0, a fused ring having a fluorene core in Formula F-b may be a ring compound with four rings. Also, if (e.g., when) both (e.g., simultaneously) the number of U and the number of V are 0, the fused ring in Formula F-b may be a ring compound with three rings. If (e.g., when) both (e.g., simultaneously) the number of U and the number of V are 1, the fused ring having a fluorene core in Formula F-b may be a ring compound with five rings.

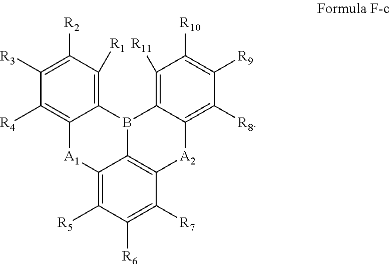

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R_{c1} to R_{c11} may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to substituents of an adjacent ring to form a fused ring. For example, if (e.g., when) A₁ and A₂ are each independently NRₘ, A₁ may be bonded to R_{c4} or R_{c5} to form a ring. In one or more embodiments, A₂ may be bonded to R_{c7} or R_{c8} to form a ring.

In one or more embodiments, each of the emission layers EML1 and EML2 may further include, as a generally used dopant material, a styryl derivative (e.g., 1,4-bis[2-(3-N-ethylcarbazoryl) vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl) naphthalen-2-yl) vinyl)phenyl)-N-phenylbenzenamine (N-BDAVBi)), 4,4′-bis[2-(4-(N,N-diphenylamino)phenyl) vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino) pyrene), and/or the like.

Each of the emission layers EML1 and EML2 may further include a generally used phosphorescent dopant material. For example, a metal complex including iridium (Ir), platinum (Pt), osmium (Os), gold (Au), titanium (Ti), zirconium (Zr), hafnium (Hf), europium (Eu), terbium (Tb), and/or thulium (Tm) may be used as a phosphorescent dopant. For example, iridium (III) bis(4,6-difluorophenylpyridinato-N,C2′) picolinate (Flrpic), bis(2,4-difluorophenylpyridinato)-tetrakis(1-pyrazolyl) borate iridium (III) (Flr6), and/or platinum octaethyl porphyrin (PtOEP) may be used as the phosphorescent dopant. However, embodiments of the present disclosure are not limited thereto.

The emission layers EML1 and EML2 may each include a quantum dot material. A core of a quantum dot may be selected from among a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound, such as In₂S₃ and/or In₂Se₃, a ternary compound, such as InGaS₃ and/or InGaSe₃, or any suitable combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound, such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each of elements included in a multi-element compound, such as the binary compound, the ternary compound, and the quaternary compound, may be present in a particle at a uniform (e.g., substantially uniform) concentration or non-uniform concentration. For example, the foregoing formulae indicate types or kinds of the elements included in the compound, and ratios of elements in the compound may be different. For example, AgInGaS₂ may indicate AgInₓGa₁₋ₓS₂ (where x is a real number between 0 and 1).

In one or more embodiments, the quantum dot may have a single structure, in which the concentration of each element included in the corresponding quantum dot is uniform (e.g., substantially uniform), or a core-shell dual structure. For example, a material included in the core and a material included in the shell may be different.

The shell of the quantum dot may serve as a protective layer to prevent a chemical change (or reduce a degree or occurrence of a chemical change) of the core to maintain semiconductor characteristics, and/or a charging layer to impart or increase electrophoretic characteristics to the quantum dot. The shell may have a single-layer structure or a multilayer structure. An interface between the core and the shell may have a concentration gradient in which the concentration of elements present in the shell gradually decreases toward the center.

In one or more embodiments, the quantum dot may have a core-shell structure including a core having the nanocrystal as described in one or more embodiments and a shell around (e.g., surrounding) the core. The shell of the quantum dot may serve as a protective layer to prevent a chemical change (or reduce a degree or occurrence of a chemical change) of the core to maintain semiconductor characteristics, and/or a charging layer to impart or increase electrophoretic characteristics to the quantum dot. The shell may have a single-layer structure or a multilayer structure. Examples of the shell of the quantum dot may include a metal oxide, a nonmetal oxide, a semiconductor compound, or a combination thereof.

For example, the metal oxide and/or the nonmetal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound, such as MgAl₂O₄, CoFe₂O₄, NiFe₂O₄, and/or CoMn₂O₄, but embodiments of the present disclosure are not limited thereto.

In one or more embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb, but embodiments of the present disclosure are not limited thereto.

Each of elements included in a multi-element compound, such as the binary compound and the ternary compound, may be present in a particle at a uniform (e.g., substantially uniform) concentration or non-uniform concentration. For example, the foregoing formulae indicate types or kinds of the elements included in the compound, and ratios of elements in the compound may be different.

The quantum dot may have a full width of half maximum (FWHM) of an emission wavelength spectrum of about 45 nm or less, for example, about 40 nm or less, for example about 30 nm or less, and, in the foregoing ranges, color purity and/or color reproducibility may be improved or enhanced. Moreover, light emitted through such quantum dots may be emitted in all directions, thereby improving or enhancing the viewing angle of light.

In one or more embodiments, the form of the quantum dot may be a form generally used in this field, and is not particularly limited. For example, however, the quantum dot may have a spherical (e.g., substantially spherical), pyramidal (e.g., substantially pyramidal), or multi-armed (e.g., substantially multi-armed) form or have the form of cubic nanoparticles, nanotubes, nanowires, nanofibers, nanoplate particles, and/or the like.

As an energy band gap is adjustable by adjusting the size of the quantum dot and/or by adjusting the ratio of elements in a quantum dot compound, light having one or more suitable wavelength bands may be obtained in a quantum dot emission layer. Thus, a light emitting element that emits light having several wavelengths may be achieved by using the quantum dots (having different sizes and/or having different ratios of elements in the quantum dot compound) as described in one or more embodiments. For example, the size of the quantum dot and/or the ratio of elements in the quantum dot compound may be selectively adjusted such that red, green, and/or blue light is emitted. In one or more embodiments, the quantum dots may be configured or provided so as to emit white light by combining light of one or more suitable colors.

The electron transport regions ETR1 and ETR2 may each include at least one selected from among a hole blocking layer, an electron auxiliary layer, the electron transport layers ETL1 and ETL2, and/or the electron injection layers EIL1 and EIL2, but embodiments of the present disclosure are not limited thereto.

Each of the electron transport regions ETR1 and ETR2 may have a single layer made of a single material, or a single layer made of a plurality of different materials, or a multilayer structure having a plurality of layers made of a plurality of different materials.

For example, the electron transport regions ETR1 and ETR2 may have single-layer structures of the electron injection layers EIL1 and EIL2 or the electron transport layers ETL1 and ETL2, respectively, or may each have a single-layer structure made of an electron injection material and an electron transport material. In one or more embodiments, each of the electron transport regions ETR1 and ETR2 may have a single-layer structure made of a plurality of different materials or have a structure in which the electron transport layers ETL1 and ETL2/electron injection layers EIL1 and EIL2, the electron auxiliary layers/electron transport layers ETL1 and ETL2, the electron auxiliary layers/electron transport layers ETL1 and ETL2/electron injection layers EIL1 and EIL2, or the hole blocking layers/electron transport layers ETL1 and ETL2/electron injection layers EIL1 and EIL2 are stacked in sequence on the emission layers EML1 and EML2, respectively. However, embodiments of the present disclosure are not limited thereto. Each of the electron transport regions ETR1 and ETR2 may have a thickness of, for example, about 1,000 Å to about 1,500 Å.

Each of the electron transport regions ETR1 and ETR2 may be formed or provided using one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The electron transport regions ETR1 and ETR2 may each include a compound represented by Formula ET.

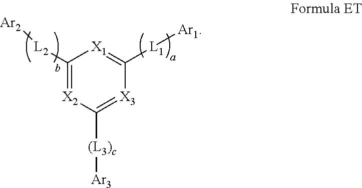

In Formula ET, at least one selected from among X₁ to X₃ may be N, and the remainder may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET, a to c may each independently be an integer of 0 to 10. In Formula ET, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. If (e.g., when) a to c are each an integer of 2 or more, L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport regions ETR1 and ETR2 may each include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzimidazol-1-yl)phenyl)-9,10-dinaphthylanthracene, 1,3,5-tri (1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate) (Bebq2), 9,10-di(naphthalene-2-yl) anthracene (ADN), 1,3-bis[3,5-di(pyridin-3-yl)phenyl]benzene (BmPyPhB), and a compound thereof.

The electron transport regions ETR1 and ETR2 may each include at least one selected from among Compounds ET1 to ET36. In one or more embodiments, Compounds ET1 to ET36 may be used as hole transporting host materials of the emission layers EML1 and EML2.

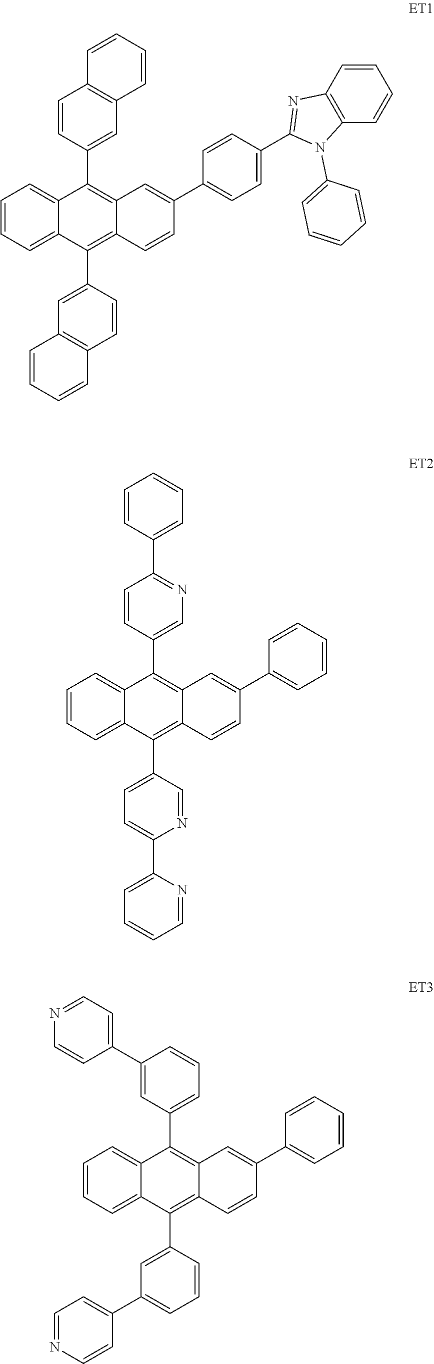 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccc5)nc4)c3c2)cc1 ; c1ccc(-c2ccc3c(-c4cccc(-c5ccncc5)c4)c4ccccc4c(-c4cccc(-c5ccncc5)c4)c3c2)cc1]

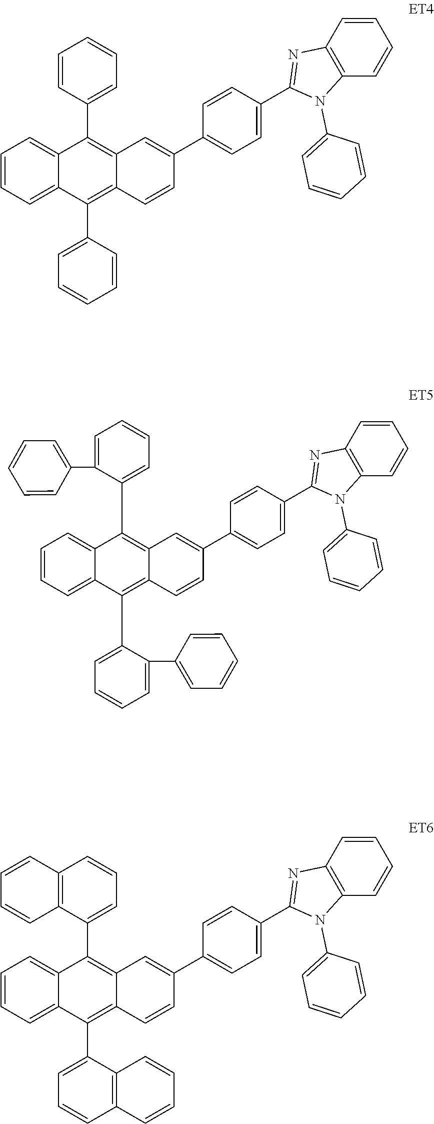 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

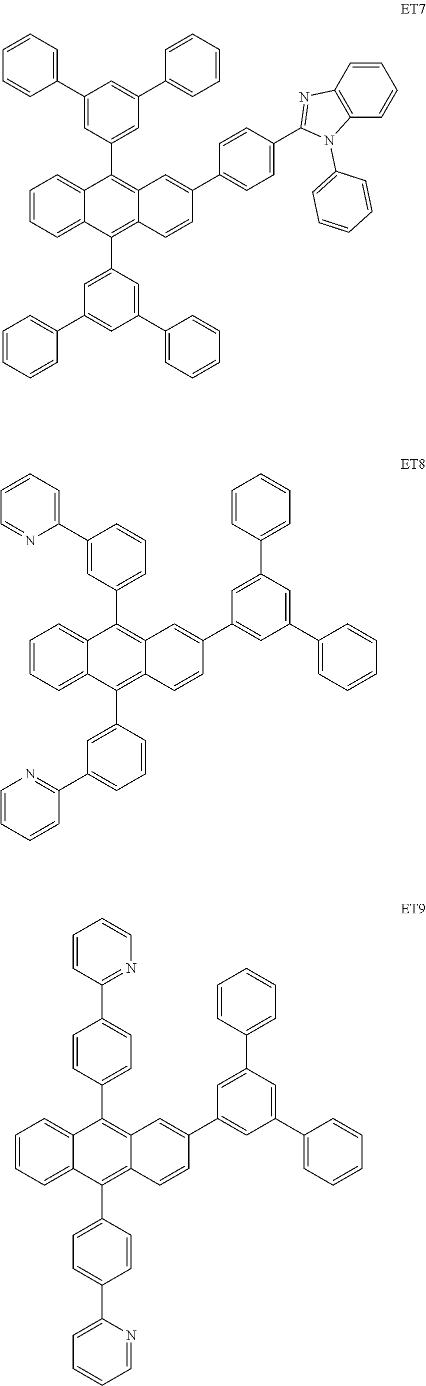 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

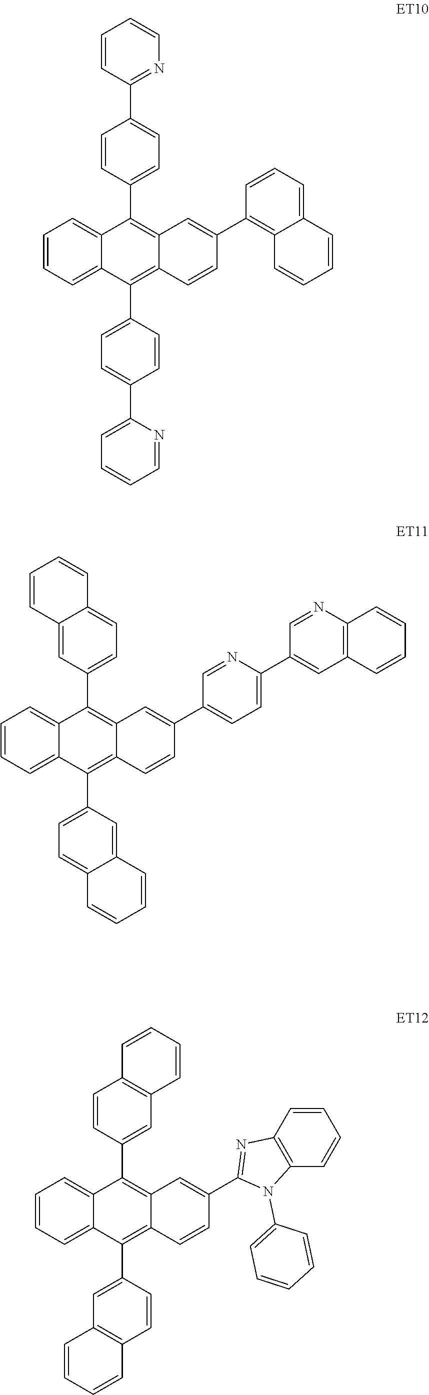 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

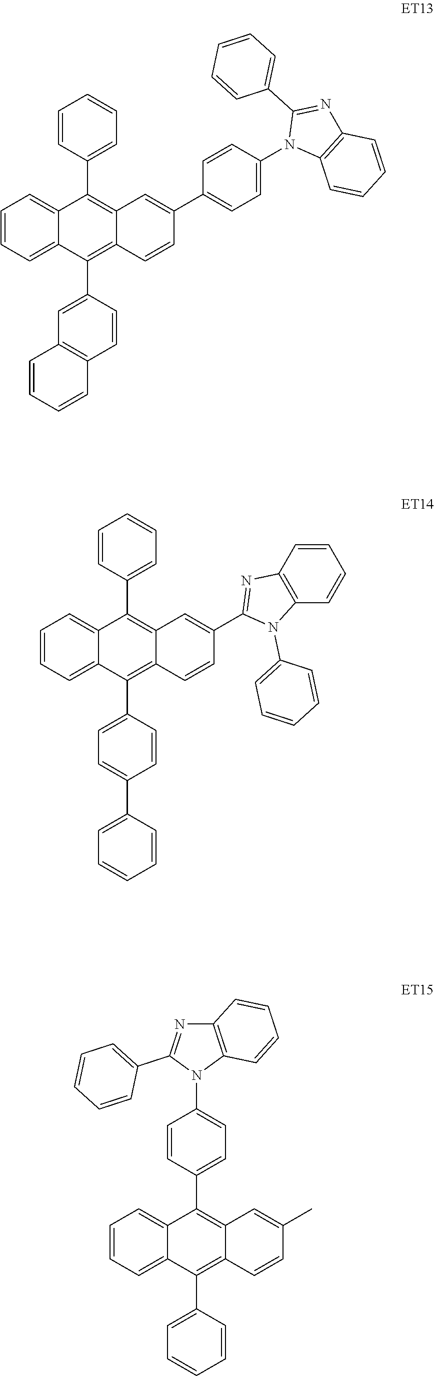 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

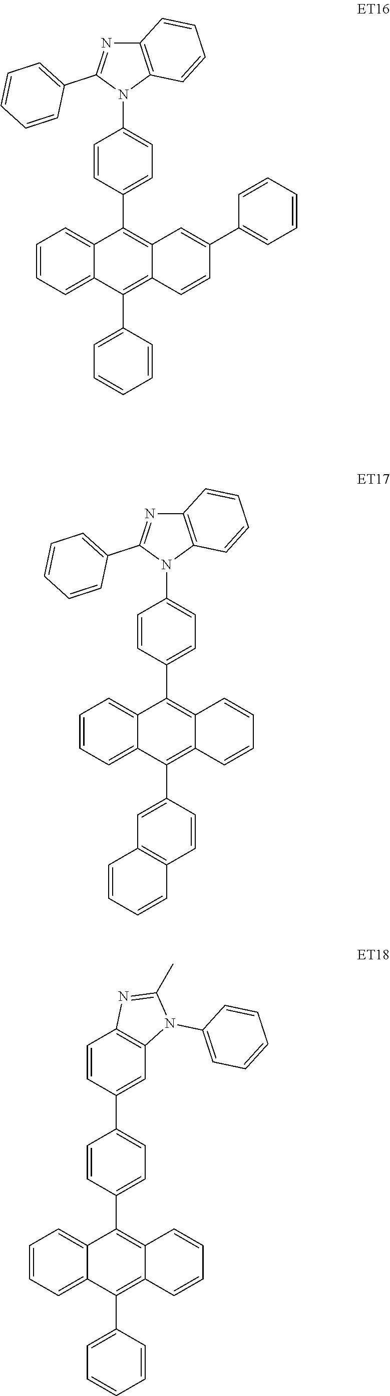 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

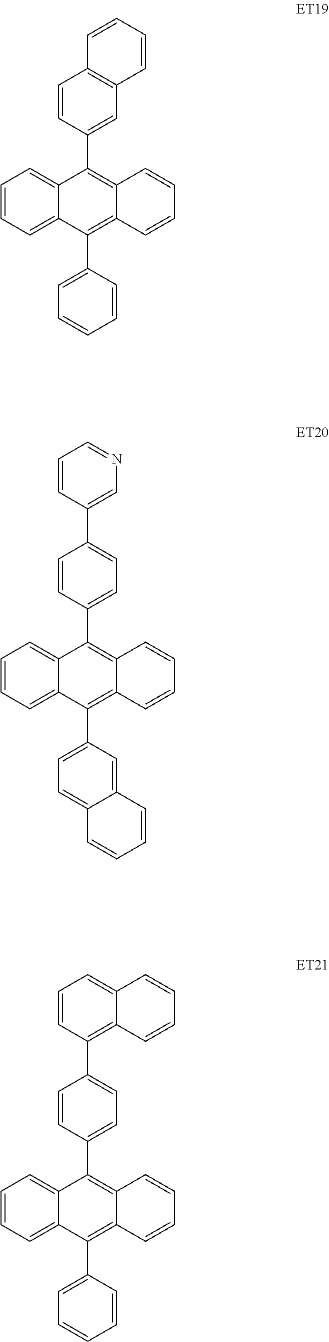

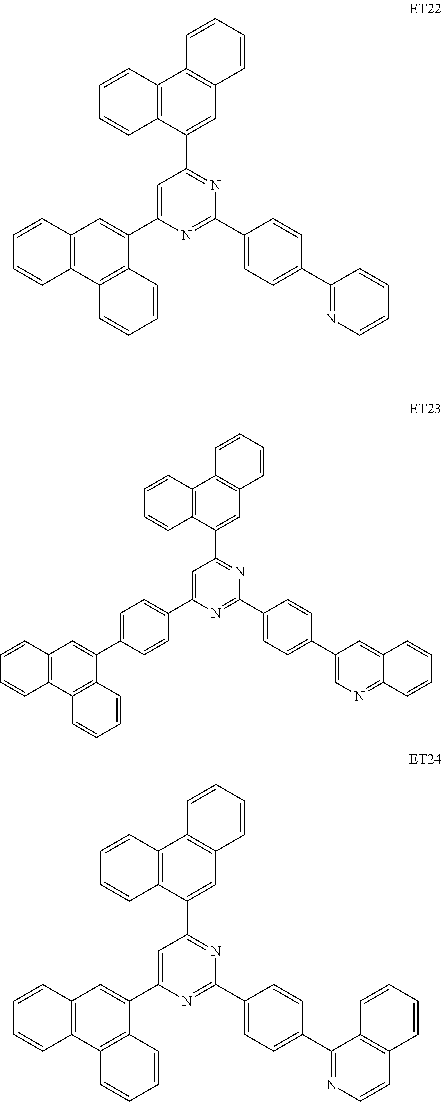 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

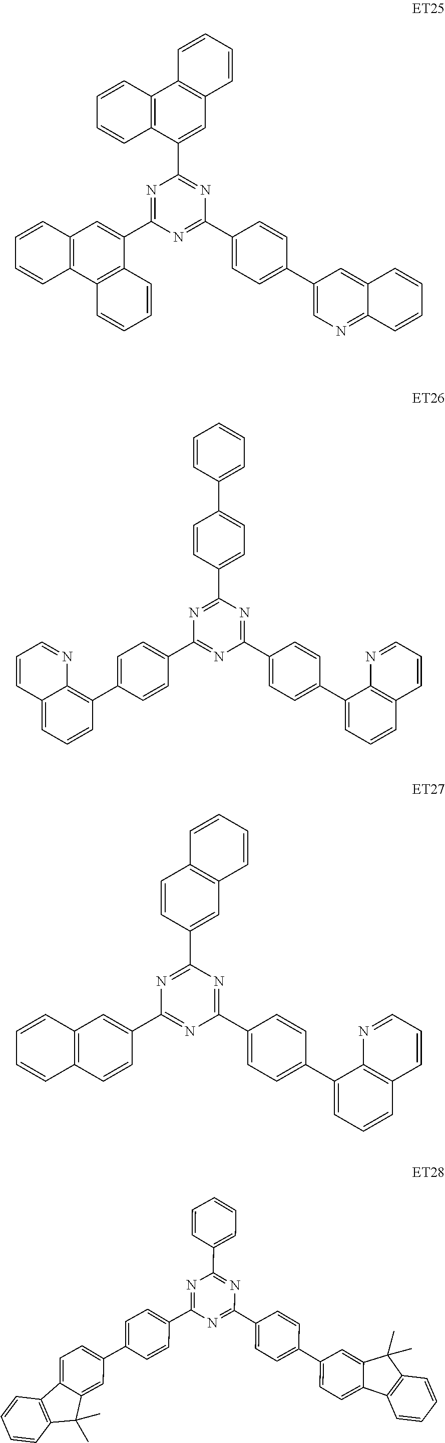 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

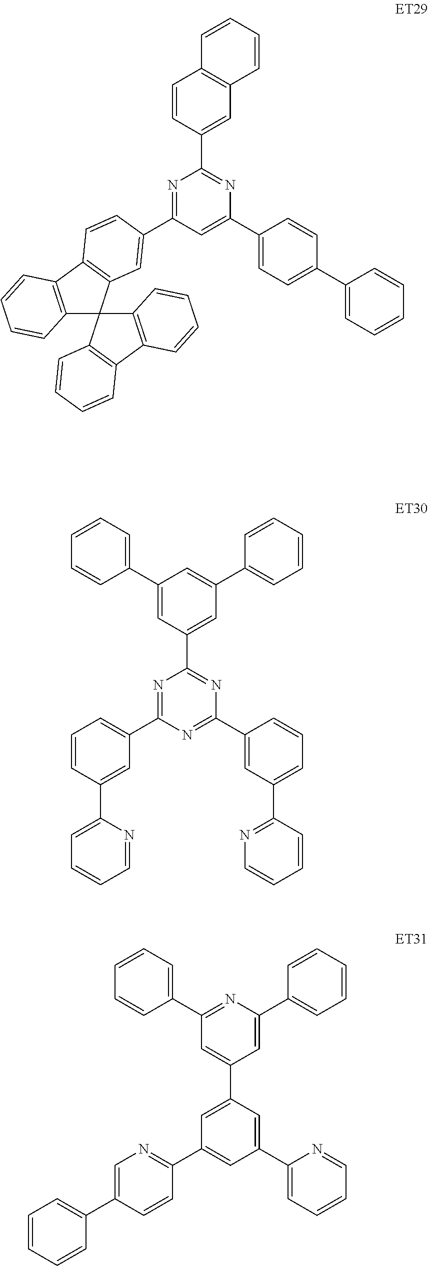 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

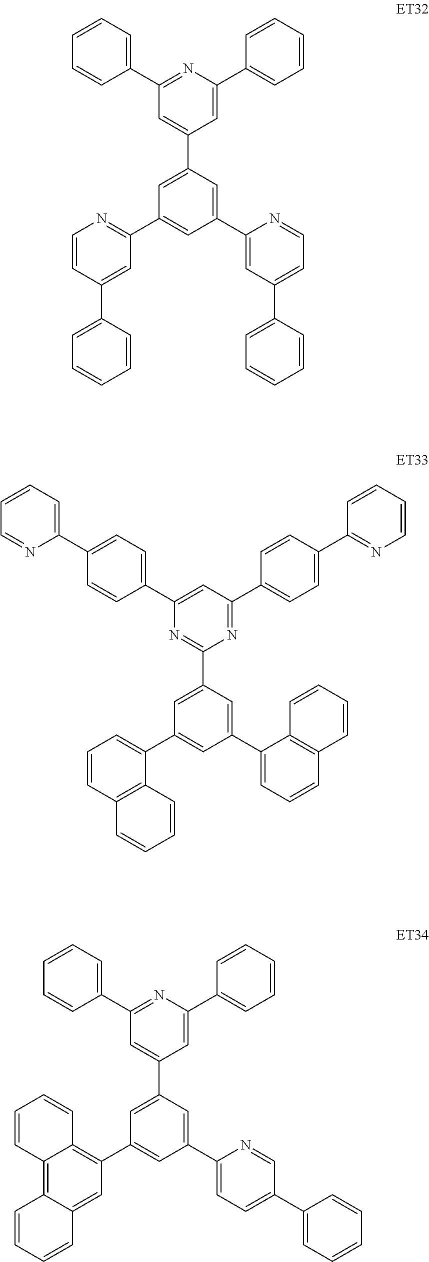 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

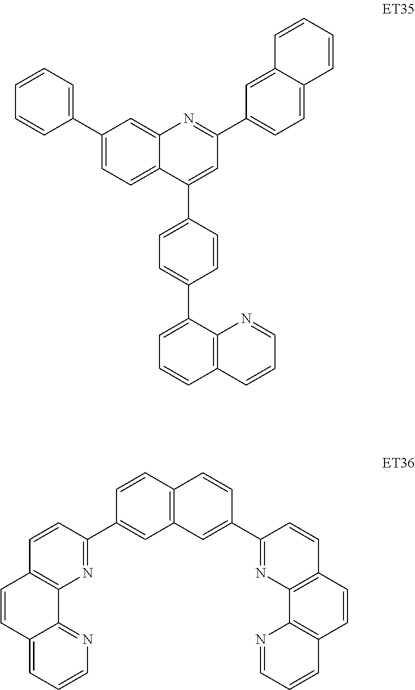 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport regions ETR1 and ETR2 may each include a halogenated metal, such as LiF, NaCl, CsF, RbCl, RbI, CuI, and/or KI, a lanthanum group metal, such as Yb, or a co-deposition material of the halogenated metal and the lanthanum group metal. For example, the electron transport regions ETR1 and ETR2 may include KI:Yb, RbI:Yb, LiF:Yb, and/or the like as the co-deposition material. A metal oxide, such as Li₂O and/or BaO, 8-hydroxyl-lithium quinolate (Liq), and/or the like may be used for the electron transport regions ETR1 and ETR2, but embodiments of the present disclosure are not limited thereto. The electron transport region ETR may also include a material in which an electron transport material and an insulating (e.g., electrically insulating) organo metal salt (or organometallic salt) are mixed. The organo metal salt (or the organometallic salt) may be a material having an energy band gap of about 4 eV or more. For example, the organo-metal salt (or the organometallic salt) may include metal acetate, metal benzoate, metal acetoacetate, metal acetylacetonate, and/or metal stearate.

Each of the electron transport regions ETR1 and ETR2 may further include, in addition to the materials as described in one or more embodiments, at least one selected from among 2,9-dimethyl-4,7-diphenyl-1,10-phenanthroline (BCP), diphenyl(4-(triphenylsilyl)phenyl)phosphine oxide (TSPO1), and/or 4,7-diphenyl-1,10-phenanthroline (Bphen), but embodiments of the present disclosure are not limited thereto.

In each of the electron transport regions ETR1 and ETR2, the compounds of the electron transport region ETR1 and ETR2 as described in one or more embodiments may be included in at least one selected from among the electron injection layers EIL1 and EIL2, the electron transport layers ETL1 and ETL2, and/or the hole blocking layer.

In a case where the electron transport regions ETR1 and ETR2 include the electron transport layers ETL1 and ETL2, respectively, the electron transport layers ETL1 and ETL2 may each have a thickness of about 100 Å to about 1,000 Å, for example, about 150 Å to about 500 Å. If (e.g., when) the thicknesses of the electron transport layers ETL1 and ETL2 satisfy the foregoing ranges, satisfactory or suitable electron transport properties may be obtained without a substantial increase in driving voltage. In a case where the electron transport regions ETR1 and ETR2 include the electron injection layers EIL1 and EIL2, respectively, the electron injection layers EIL1 and EIL2 may each have a thickness of about 1 Å to about 100 Å, for example, about 3 Å to about 90 Å. If (e.g., when) the thicknesses of the electron injection layers EIL1 and EIL2 satisfy the foregoing ranges, satisfactory or suitable electron injection properties may be obtained without a substantial increase in driving voltage.

FIGS. 3A to 3D illustrate respective components that constitute the first emission unit OL1 and the second emission unit OL2 so as to correspond to each other. However, a stack structure of each of the first emission unit OL1 and the second emission unit OL2 is not limited to the illustrated embodiments and may be provided through one or more suitable combinations according to characteristics of display quality desired or required by the light emitting element ED. For example, in the light emitting element ED according to one or more embodiments, the second hole transport region HTR2 of the second emission unit OL2 may have a structure including the second emission auxiliary layers SE-R2, SE-G2, and SE-B2, and the first hole transport region HTR1 of the first emission unit OL1 may have a structure not including the first emission auxiliary layers SE-R1, SE-G1, and SE-B1. In one or more embodiments, the second electron transport region ETR2 of the second emission unit OL2 may have a structure including the second electron injection layer EIL2, and the first electron transport region ETR1 of the first emission unit OL1 may have a structure not including the first electron injection layer EIL1.

The charge generation unit CGL may be disposed or provided between the first emission unit OL1 and the second emission unit OL2. If (e.g., when) a voltage is applied, the charge generation unit CGL may generate charges (electrons and holes) by forming a complex through an oxidation-reduction reaction. And the charge generation unit CGL may provide the generated charges to each of adjacent emission unit OL1 and OL2. The charge generation unit CGL may increase or enhance efficiency of current generated from the adjacent emission unit OL1 and OL2 and may serve to adjust the balance of the charges between the adjacent emission unit OL1 and OL2.

The charge generation unit CGL may include a p-type charge generation layer p-CGL and an n-type charge generation layer n-CGL. The charge generation unit CGL may have a stack structure in which the p-type charge generation layer p-CGL and the n-type charge generation layer n-CGL are bonded to each other. The charge generation unit CGL may have a stack structure in which the n-type charge generation layer n-CGL and the p-type charge generation layer p-CGL are stacked in sequence.

The n-type charge generation layer n-CGL may be a charge generation layer that provides electrons to the adjacent emission unit OL1 and OL2. The n-type charge generation layer n-CGL may include an n-dopant. The n-type charge generation layer n-CGL may be a layer in which a base material is doped with the n-dopant. For example, in the n-type charge generation layer n-CGL, the electron transporting host, such as 4,7-diphenyl-1,10-phenanthroline (BPhen), may be doped with Yb as the n-dopant, but embodiments of the present disclosure are not limited thereto.

The p-type charge generation layer p-CGL may be a charge generation layer that provides holes to the adjacent emission unit OL1 and OL2. The p-type charge generation layer p-CGL may include a p-dopant. The p-type charge generation layer p-CGL may be a layer in which a base material is doped with the p-dopant. The p-type charge generation layer p-CGL may be a layer which includes the first compound according to one or more embodiments of the present disclosure as a host, and in which the host is doped with the p-dopant. In the p-type charge generation layer p-CGL, the hole transporting host, such as F4-TCNQ, may be doped with at least one selected from among the compounds of Compound Group H as the p-dopant, but embodiments of the present disclosure are not limited thereto. In one or more embodiments, a buffer layer may be further disposed or provided between the n-type charge generation layer n-CGL and the p-type charge generation layer p-CGL.

The charge generation unit CGL may include an n-type aryl amine-based material or include a p-type metal oxide. For example, the charge generation unit CGL may include a charge generation compound including an aryl amine-based organic compound, a metal, an oxide, carbide, or fluoride of metal, or a mixture thereof.

For example, the aryl amine-based organic compound may be a-NPD, 2-TNATA, TDATA, MTDATA, sprio-TAD, or sprio-NPB. For example, the metal may be cesium (Cs), molybdenum (Mo), vanadium (V), titanium (Ti), tungsten (W), barium (Ba), or lithium (Li). Also, for example, the oxide, carbide, and fluoride of metal may be Re₂O₇, MoO₃, V₂O₅, WO₃, TiO₂, CS₂CO₃, BaF₂, LiF, or CsF.

The second electrode EL2 may be provided on the second electron transport region ETR2. The second electrode EL2 may be a common electrode. The second electrode EL2 may be a cathode or an anode, but embodiments of the present disclosure are not limited thereto. For example, in a case where the first electrode EL1 1 is an anode, the second electrode EL2 may be a cathode, and in a case where the first electrode EL1 is a cathode, the second electrode EL2 may be an anode.

The second electrode EL2 may be a transmissive electrode, a semi-transmissive electrode, or a reflective electrode. In a case where the second electrode EL2 is a transmissive electrode, the second electrode EL2 may include a transparent (e.g., substantially transparent) metal oxide, for example, indium tin oxide (ITO), indium zinc oxide (IZO), zinc oxide (e.g., ZnO), indium tin zinc oxide (ITZO), and/or the like.

In a case where the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In one or more embodiments, the second electrode EL2 may have a multilayer structure including a reflective film or a semi-transmissive film, each of which is made of the material as described in one or more embodiments, and a transparent (e.g., substantially transparent) conductive (e.g., electrically conductive) film made of indium tin oxide (ITO), indium zinc oxide (IZO), zinc oxide (e.g., ZnO), indium tin zinc oxide (ITZO), and/or the like. For example, the second electrode EL2 may include the metal material as described in one or more embodiments, a combination of two or more metal materials selected from among the metal materials as described in one or more embodiments, an oxide of the metal materials as described in one or more embodiments, and/or the like.

In one or more embodiments, the second electrode EL2 may be connected to an auxiliary electrode. If (e.g., when) the second electrode EL2 is connected to the auxiliary electrode, resistance of the second electrode EL2 may be reduced.

The capping layer CPL may be disposed or provided on the second electrode EL2 of the light emitting element ED according to one or more embodiments. The capping layer CPL may have a multilayer structure or a single-layer structure.

In one or more embodiments, the capping layer CPL may be an organic layer or an inorganic layer. For example, in a case where the capping layer CPL includes an inorganic substance, the inorganic substance may include an alkali metal compound, such as LiF, an alkaline earth metal compound, such as MgF₂, SiON, SiNx (wherein 0<X≤2), SiO_{y} (wherein 0<y≤2; e.g., SiO₂), and/or the like.

For example, in a case where the capping layer CPL includes an organic substance, the organic substance may include a-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl)triphenylamine (TCTA), and/or the like, or include an epoxy resin, and/or an acrylate, such as a methacrylate. However, embodiments of the present disclosure are not limited thereto, and the capping layer CPL may include at least one selected from among Compounds P1 to P5 as follows.

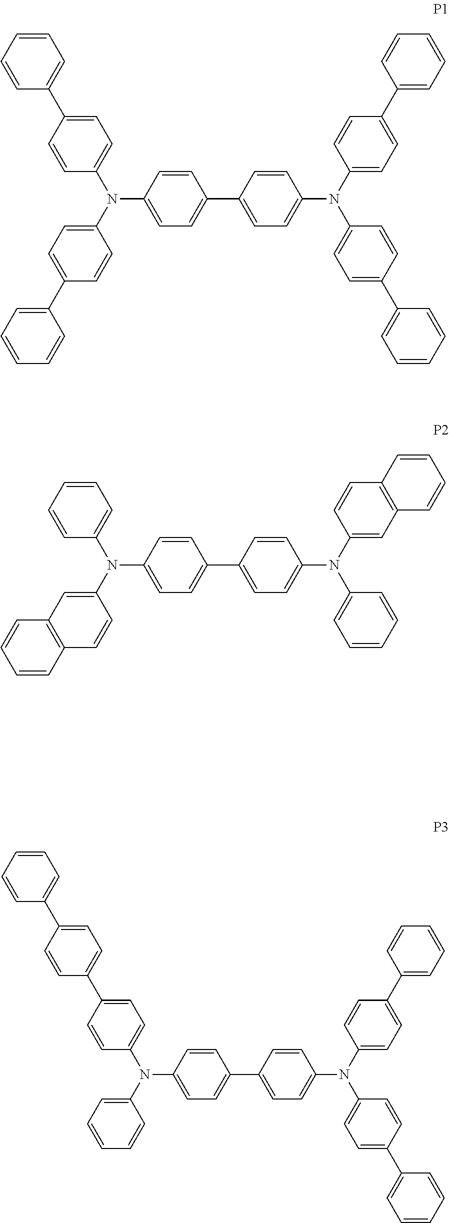 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

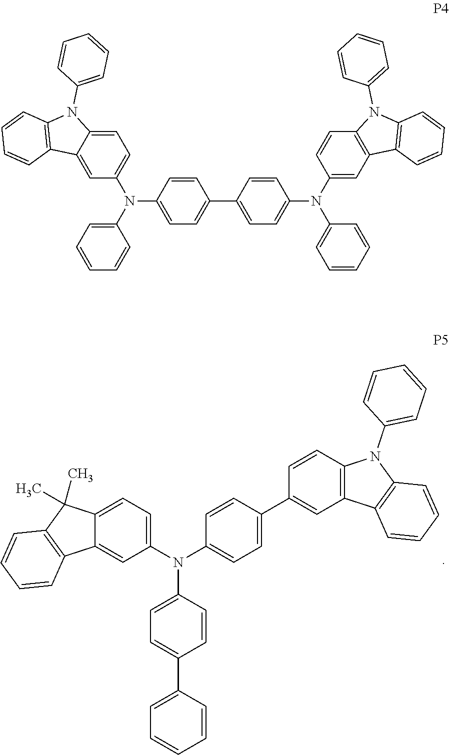 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index of about 1.6 or more. For example, the refractive index of the capping layer CPL with respect to light in a wavelength region of about 550 nm to about 660 nm may be about 1.6 or more.

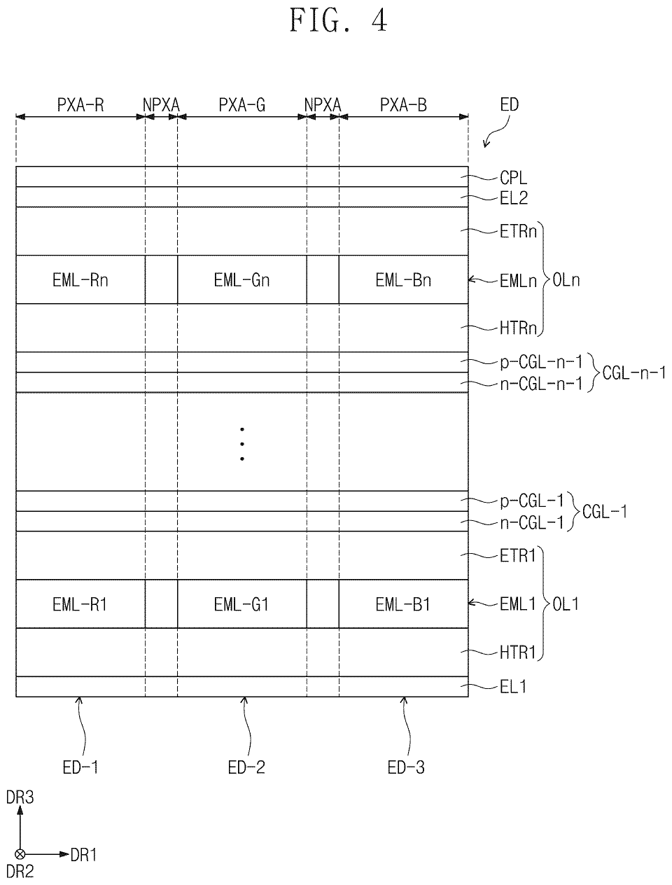

FIG. 4 is a schematic cross-sectional view illustrating one light emitting element according to one or more embodiments.

In one or more embodiments, a light emitting element ED as illustrated in FIG. 4 may include n emission units OL1 to OLn. In the present disclosure, n in FIG. 4 indicates an integer of 2 or more. For example, n may be 2, 3, or 4, but embodiments of the present disclosure are not limited thereto. Referring to FIG. 4, the light emitting element ED according to one or more embodiments may include a first electrode EL1, a second electrode EL2, the n emission units OL1 to OLn stacked in sequence between the first electrode EL1 and the second electrode EL2 in the thickness direction, and n-1 charge generation layers CGL-1 to CGL-n-1, each of which is disposed or provided between adjacent emission units of the emission units OL1 to OLn. A first emission unit OL1 to an n-th emission unit OLn may include first to n-th hole transport regions HTR1 to HTRn, a first emission layer EML1 to an n-th emission layer EMLn, and first to n-th electron transport regions ETR1 to ETRn, which are stacked in sequence, respectively. The first emission layer EML1 to the n-th emission layer EMLn may include first to n-th red emission layers EML-R₁ to EML-Rn, first to n-th green emission layers EML-G1 to EML-Gn, and first to n-th blue emission layers EML-B1 to EML-Bn, respectively. The charge generation layers CGL-1 to CGL-n-1, each of which is disposed or provided between the adjacent emission units of the emission units OL1 to OLn, may include p-type charge generation layers p-CGL-1 to p-CGL-n-1 and n-type charge generation layers n-CGL-1 to n-CGL-n-1, respectively.

In the light emitting element ED in FIG. 4, the contents about the light emitting element ED as described with reference to FIGS. 3A to 3D may apply to FIG. 4. For example, the contents about the first hole transport region HTR1 and the second hole transport region HTR2 may apply to the n-th hole transport region HTRn. The contents about the first electron transport region ETR1 and the second electron transport region ETR2 may apply to the n-th electron transport region ETRn. In one or more embodiments, the contents about the first emission layer EML1 and the second emission layer EML2 may apply to the n-th emission layer EMLn.

In one or more embodiments, the first light emitting material as described in one or more embodiments may be included in each of the first emission layer EML1 to the n-th emission layer EMLn disposed or provided in substantially the same emission area among the first emission area PXA-R, the second emission area PXA-G, and the third emission area PXA-B. For example, the first light emitting materials may be included in the first emission layer EML1 to the n-th emission layer EMLn disposed or provided to correspond to the second emission area PXA-G. In one or more embodiments, the first light emitting materials may be included in the first emission layer EML1 to the n-th emission layer EMLn disposed or provided to correspond to the third emission area PXA-B.

For example, in the light emitting element ED according to one or more embodiments, the first compound of the first light emitting materials as described in one or more embodiments may be included in each of the first green emission layer EML-G1 to the n-th green emission layer EML-Gn of a second light emitting element ED-2. The second compound of the first light emitting materials as described in one or more embodiments may be included in each of the first blue emission layer EML-B1 to the n-th blue emission layer EML-Bn of a third light emitting element ED-3. The respective first light emitting materials included in the first emission layer EML1 to the n-th emission layer EMLn may be different or substantially the same.

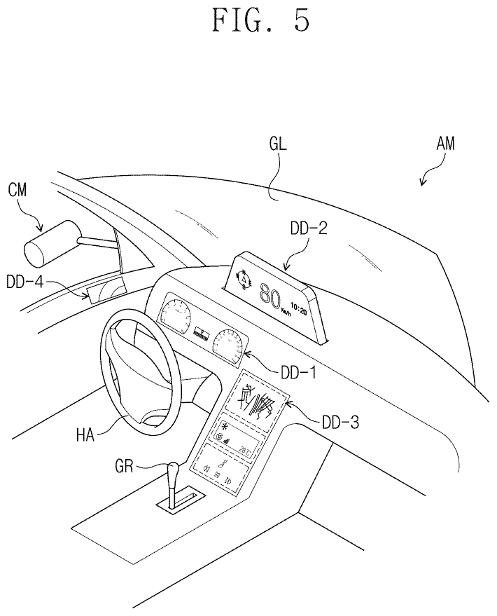

FIG. 5 is a view illustrating a vehicle AM in which a display device according to one or more embodiments is disposed or provided.

Referring to FIG. 5, an electronic apparatus according to one or more embodiments may include display devices DD-1, DD-2, DD-3, and DD-4 for a vehicle AM. At least one selected from among a first display device DD-1, a second display device DD-2, a third display device DD-3, and a fourth display device DD-4 may include substantially the same/similar components as/to those of the display device DD according to one or more embodiments as described with reference to FIG. 1.

In FIG. 5, the first display device DD-1, the second display device DD-2, the third display device DD-3, and the fourth display device DD-4 are illustrated as display devices for the vehicle AM to be disposed or provided inside the vehicle AM. However, this is illustrative, and the first display device DD-1, the second display device DD-2, the third display device DD-3, and the fourth display device DD-4 may be disposed or provided in other transport units, such as bicycles, motorcycles, trains, ships, and/or airplanes. At least one selected from among the first display device DD-1, the second display device DD-2, the third display device DD-3, and the fourth display device DD-4, which include substantially the same/similar components as/to those of the display device DD according to one or more embodiments, may also be employed in a personal computer, a notebook computer, a personal digital assistant, a game console, a portable electronic device, a television, a monitor, an outdoor billboard, and/or the like. These examples are just provided as embodiments, and the display device may be employed in other electronic devices as long as not departing from the teachings of the present disclosure.

At least one selected from among the first display device DD-1, the second display device DD-2, the third display device DD-3, and the fourth display device DD-4 may include the light emitting element ED according to one or more embodiments as described with reference to FIGS. 2, 3A to 3D, and 4.

Referring to FIG. 5, the vehicle AM may include a steering wheel HA and a gear GR for an operation of the vehicle AM. In one or more embodiments, the vehicle AM may include a front window GL disposed or provided to be opposite to (e.g., face) a driver.

The first display device DD-1 may be disposed or provided in a first region that overlaps the steering wheel HA. For example, the first display device DD-1 may be a digital cluster that displays first information of the vehicle AM. The first information may include a first graduation which indicates a driving speed of the vehicle AM, a second graduation which indicates revolutions of an engine (e.g., revolutions per minute (RPM)), an image which indicates a fuel level, and/or the like. The first graduation and the second graduation may be displayed as digital images.

The second display device DD-2 may be disposed or provided in a second region that is opposite to (e.g., faces) a driver's seat and that overlaps the front window GL. The driver's seat may be a seat where the steering wheel HA is disposed or provided. For example, the second display device DD-2 may be a head up display (HUD) that displays second information of the vehicle AM. The second display device DD-2 may be optically transparent (e.g., substantially transparent). The second information may include digital numbers which indicate the driving speed of the vehicle AM, and further include information, such as current time. In one or more embodiments, the second information of the second display device DD-2 may be projected and displayed on the front window GL.

The third display device DD-3 may be disposed or provided in a third region adjacent to the gear GR. For example, the third display device DD-3 may be a center information display (CID) for vehicle, which is disposed or provided between the driver's seat and a passenger's seat and displays third information. The passenger's seat may be a seat spaced and/or apart (e.g., spaced apart or separated) from the driver's seat having the gear GR therebetween. The third information may include information on road conditions (e.g., navigation information), on playing music or radio, on playing a dynamic image (or a still image), on the temperature inside the vehicle AM, and/or the like.

The fourth display device DD-4 may be disposed or provided in a fourth region spaced and/or apart (e.g., spaced apart or separated) from the steering wheel HA and the gear GR and adjacent to a side of the vehicle AM. For example, the fourth display device DD-4 may be a digital side mirror which displays fourth information. The fourth display device DD-4 may display an external image of the vehicle AM, taken by a camera module CM disposed or provided on an outer side of the vehicle AM. The fourth information may include the external image of the vehicle AM.

The first information to the fourth information as described in one or more embodiments is provided as examples, and the first display device DD-1, the second display device DD-2, the third display device DD-3, and the fourth display device DD-4 may further display information on the inside and outside of the vehicle AM. The first information to the fourth information may include different information. However, embodiments of the present disclosure are not limited thereto, and a portion of the first information to the fourth information may include substantially the same information.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

Hereinafter, a light emitting element according to one or more embodiments of the present disclosure will be described in more detail with reference to Examples and Comparative Examples. Examples as described in one or more embodiments are each one example for enhancing understanding, and the scope of the present disclosure is not limited thereto.

### EXAMPLES

### 1. Manufacture of Light Emitting Elements

A light emitting element according to Example and a light emitting element according to Comparative Example were manufacture in the following method.

A light emitting element in which a first light emitting material according to one or more embodiments or a comparative example compound was included in each of a first emission layer and a second emission layer was manufactured in the following method. For example, a first compound according to one or more embodiments was used as a host material of each of a first green emission layer and a second green emission layer, and a second compound according to one or more embodiments was used as a host material of each of a first blue emission layer and a second blue emission layer to manufacture a light emitting element according to Example 1. A light emitting element according to Comparative Example 1 was manufactured by using Comparative Example Compound X1 as host materials of a first green emission layer and a second green emission layer and using Comparative Example Compound X2 as host materials of a first blue emission layer and a second blue emission layer.

A glass substrate (product by Corning Co.) of ITO/Ag/ITO (120 Å/500 Å/120 Å) with 15 Ω/cm² as a first electrode was cut into a size of about 50 mm×50 mm×0.7 mm. The cut glass substrates were washed under ultrasonic waves using isopropyl alcohol and pure water for about 5 minutes each, cleaned by being irradiated with ultraviolet rays for about 30 minutes and exposed to ozone, and then mounted on a vacuum deposition apparatus.

A first emission unit was formed or provided on the first electrode. For example, a material in which a hole transporting host was doped with a p-dopant (about 2%) was deposited to be about 10 nm thick on the first electrode, and then the hole transporting host was deposited to be about 30 nm thick, thereby forming or providing a first hole transport region as a common layer. H-1-1 was used as the hole transporting host, and F4-TCNQ was used as the p-dopant. Thereafter, a material in which a light emitting host was doped with a light emitting dopant was deposited to be about 40 nm thick on the first hole transport region so as to overlap a first emission area, thereby forming or providing a first red emission layer. A material in which a light emitting host was doped with a light emitting dopant was deposited to be about 30 nm thick on the first hole transport region so as to overlap a second emission area, thereby forming or providing a first green emission layer. A material in which a light emitting host was doped with BD as a light emitting dopant was deposited to be about 20 nm thick on the first hole transport region so as to overlap a third emission area, thereby forming or providing a first blue emission layer. Accordingly, a first emission layer was formed or provided as a pattern layer. In the first red emission layer, E-2-1 was used as the light emitting host, and M-a1 was used as the light emitting dopant. In the first green emission layer, E1-11 or Comparative Example Compound X1 was used as the light emitting host, and M-a20 was used as the light emitting dopant. In the first blue emission layer, E2-17 or Comparative Example Compound X2 was used as the light emitting host, and BD was used as the light emitting dopant. Thereafter, electron transporting host ETH87 was deposited to be about 30 nm thick, thereby forming or providing a first electron transport region as a common layer.

Thereafter, a charge generation unit was formed or provided on the first electron transport region. For example, a material in which an electron transporting host was doped with Yb as a dopant was deposited to be about 15 nm thick, thereby forming or providing an n-type charge generation layer as a common layer. A material in which an electron transporting host was doped with a p-dopant (about 8%) was deposited to be about 10 nm thick on the n-type charge generation layer, and then the electron transporting host was deposited to be about 30 nm thick, thereby forming or providing a p-type charge generation layer as a common layer. In the forming or providing of the n-type charge generation layer, 4,7-diphenyl-1,10-phenanthroline (BPhen) was used as the electron transporting host, and in the forming or providing of the p-type charge generation layer, F4-TCNQ and H-1-19 were used as the electron transporting host and the p-dopant, respectively.

Thereafter, a second emission unit was formed or provided on the p-type charge generation layer. For example, on the p-type charge generation layer, H-1-17 was deposited to be about 50 nm thick to form or provide a red auxiliary layer, H-1-3 was deposited to be about 20 nm thick to form or provide a green auxiliary layer, and H-1-15 was deposited to be about 10 nm thick to form or provide a blue auxiliary layer, thereby forming or providing an emission auxiliary layer. Each of the red auxiliary layer, the green auxiliary layer, and the blue auxiliary layer may be formed or provided as a pattern layer so as to correspond to a pixel area thereof. A second red emission layer, a second green emission layer, and a blue emission layer of a second emission layer were formed or provided on the emission auxiliary layer by using substantially the same materials as the first red emission layer, the first green emission layer, and the first emission layer of the first emission layer to have substantially the same thicknesses, respectively. Accordingly, the second emission layer was formed or provided as a pattern layer. Thereafter, electron transporting host ET28 was deposited to be about 10 nm thick to form or provide a first electron auxiliary layer, and electron transporting host ETH87 was deposited to be about 30 nm thick on the first electron auxiliary layer, thereby a second electron transport region as a common layer.

Then, Ag:Mg (about 10%) was deposited on the second electron transport region to form or provide a second electrode having a thickness of about 90 Å. Thereafter, on the second electrode, CPL1 was deposited to be about 60 nm thick, and CPL2 was deposited to be about 40 nm thick to form or provide a capping layer, thereby manufacturing the light emitting element. Each of the layers was formed or provided using a vacuum deposition method.

Light Emitting Materials used in Manufacture of Light Emitting Elements

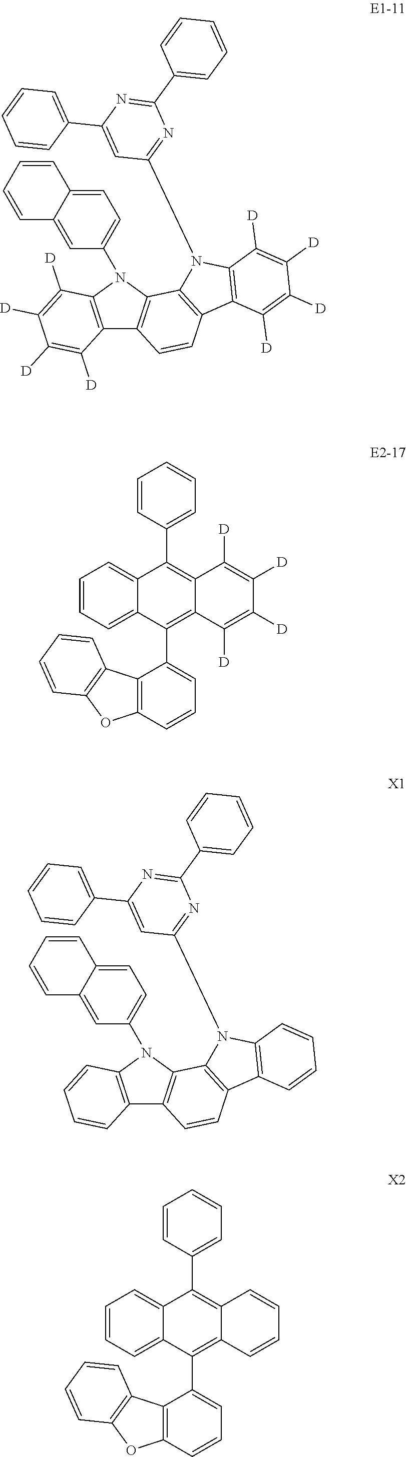 [SMILES: [2H]c1c([2H])c([2H])c2c(c1[2H])c1ccc3c4c([2H])c([2H])c([2H])c([2H])c4n(-c4cc(-c5ccccc5)nc(-c5ccccc5)n4)c3c1n2-c1ccc2ccccc2c1 ; [2H]c1c([2H])c([2H])c2c(-c3cccc4oc5ccccc5c34)c3ccccc3c(-c3ccccc3)c2c1[2H] ; c1ccc(-c2cc(-n3c4ccccc4c4ccc5c6ccccc6n(-c6ccc7ccccc7c6)c5c43)nc(-c3ccccc3)n2)cc1 ; c1ccc(-c2c3ccccc3c(-c3cccc4oc5ccccc5c34)c3ccccc23)cc1]

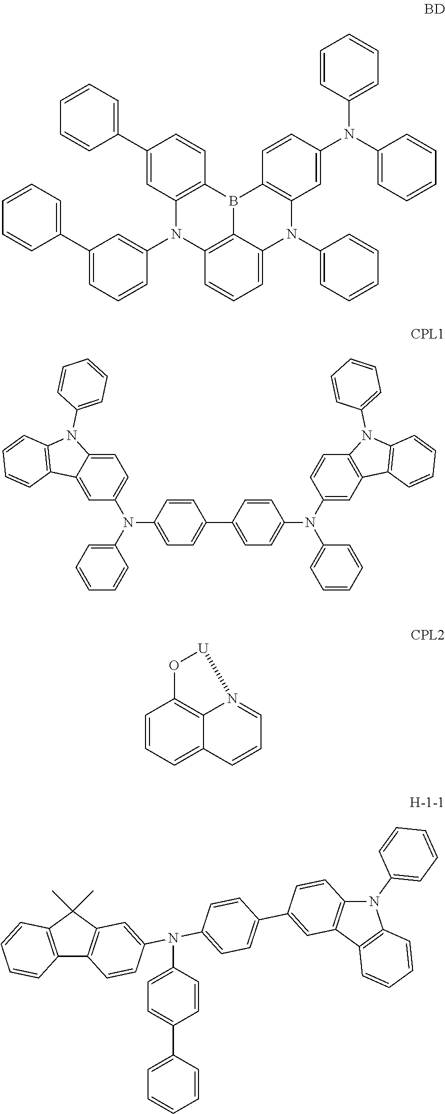

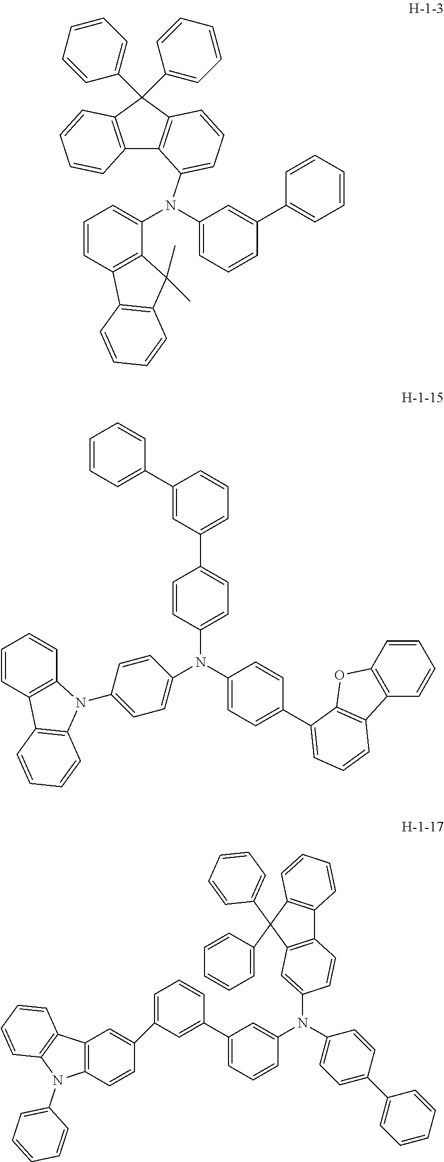 [SMILES: CC1(C)c2ccccc2-c2cccc(N(c3cccc(-c4ccccc4)c3)c3cccc4c3-c3ccccc3C4(c3ccccc3)c3ccccc3)c21 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

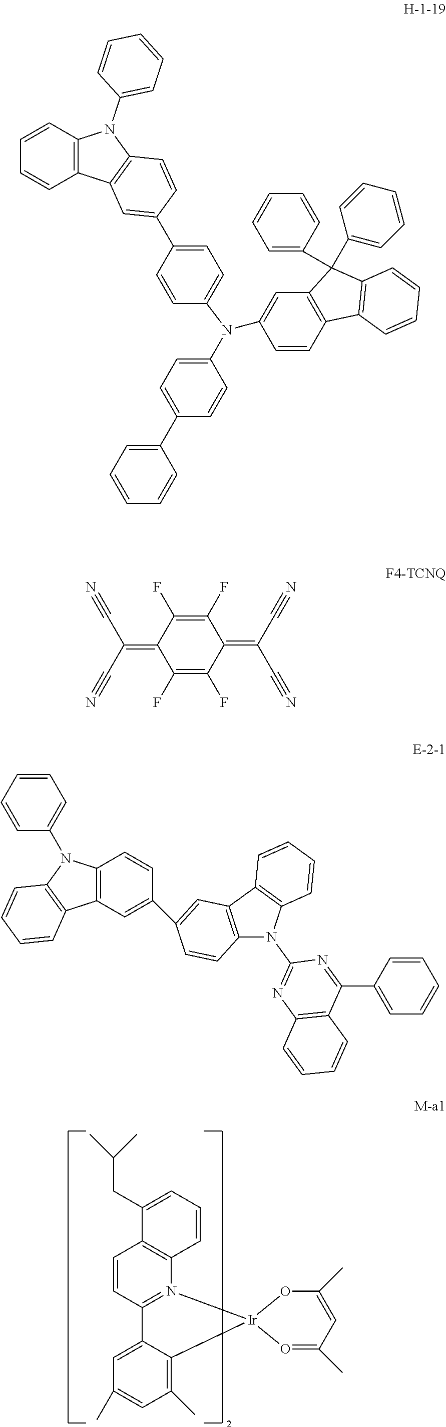

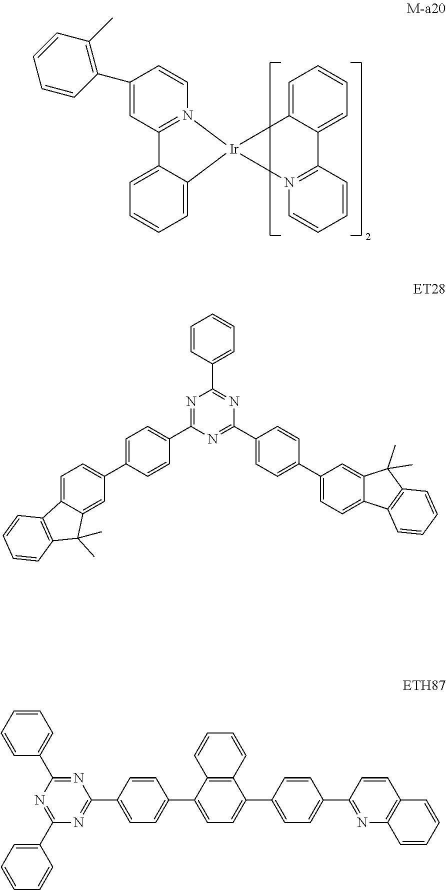

### 2. Characteristic Evaluation of Light Emitting Elements

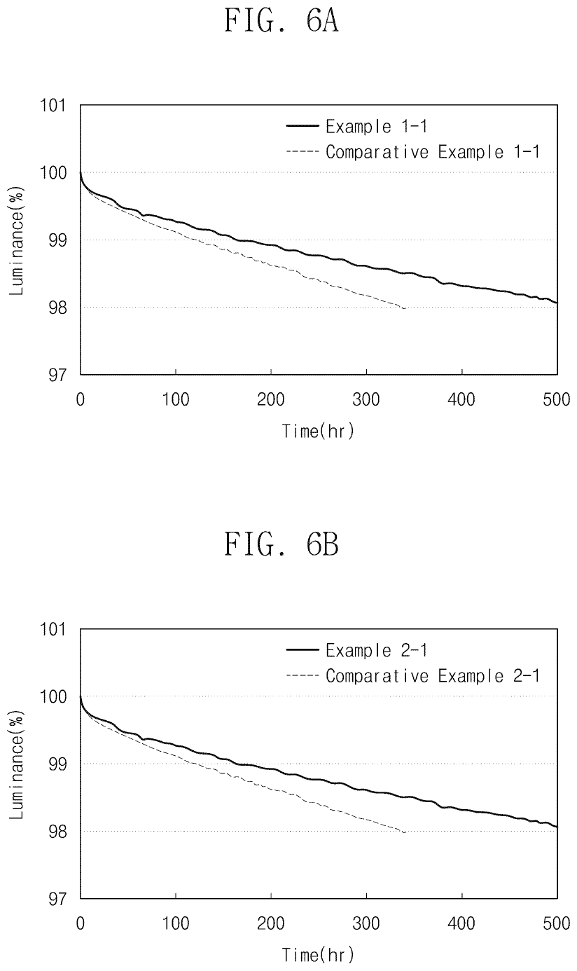

The light emitting elements according to Example 1 and Comparative Example 1 were evaluated on lifespan. Time periods for which luminance reached a level of about 98% of an initial luminance were measured to evaluate the lifespan characteristics of the light emitting elements according to Example and Comparative Example, and the measurement results are shown in Table 1 and FIGS. 6A and 6B. Table 1 and FIG. 6A show the results of the evaluation on the lifespan of the green light emitting elements according to Example 1 and Comparative Example 1. The green light emitting element according to Example 1 is designated by Example 1-1, and the green light emitting element according to Comparative Example 1 is designated by Comparative Example 1-1. Also, Table 1 and FIG. 6B show the results of the evaluation on the lifespan of the blue light emitting elements according to Example 1 and Comparative Example 1. The blue light emitting element according to Example 1 is designated by Example 2-1, and the blue light emitting element according to Comparative Example 1 is designated by Comparative Example 2-1. The evaluation on the lifespan of each of the light emitting elements was performed by applying a current density that corresponds to luminance desired or required by each of the green light emitting element and the blue light emitting element.

TABLE 1

| | Host | Dopant | Lifespan (h) |
|---|---|---|---|
| Example 1-1 | E1-11 | M-a20 | 500 |
| Example 2-1 | E2-17 | BD | 500 |
| Comparative Example 1-1 | X1 | M-a20 | 340 |
| Comparative Example 2-1 | X2 | BD | 340 |

Referring to Table 1 and FIGS. 6A and 6B, Examples 1-1 and 2-1 each exhibited the lifespan characteristics superior to those of Comparative Examples 1-1 and 2-1. For example, in the light emitting elements according to Examples 1-1 and 2-1, about 500 hours or more was taken for the luminance to reach the level of about 98% of the initial luminance, but in the light emitting elements according to Comparative Examples 1-1 and 2-1, about 340 hours was taken for the luminance to reach the level of about 98% of the initial luminance. For example, Examples 1-1 and 2-1 showed the longer time taken for the initial luminance to be decreased up to about 98% than Comparative Examples 1-1 and 2-1, and thus exhibited improved or enhanced lifespan characteristics compared to Comparative Examples.

According to one or more embodiments of the present disclosure, in the tandem light emitting element including the plurality of emission units, the emission layers that correspond to the at least two emission areas of the red emission area, the green emission area, and the blue emission area may each include the light emitting material including the deuterium atom to improve or enhance the element lifespan. Accordingly, the display device including the tandem light emitting element may exhibit excellent or suitable display quality.

Although one or more embodiments of the present disclosure have been described, it should be understood that the present disclosure should not be limited to these embodiments but one or more suitable changes and modifications can be made by one ordinary skilled in the art within the spirit and scope of the present disclosure as hereinafter claimed or equivalents thereof. Therefore, the scope of the present disclosure is not limited to the contents described in the detailed description of the specification, but should be determined by the appended claims and equivalents thereof.

What is claimed is:

1. A display device, comprising:
a display element layer comprising a first emission area that emits light of a first color, a second emission area that emits light of a second color having a shorter wavelength than the first color, and a third emission area that emits light of a third color having a shorter wavelength than the second color, the first emission area, the second emission area, and the third emission area being spaced apart from each other on a plane,
wherein the display element layer further comprises a first light emitting element, a second light emitting element, and a third light emitting element that correspond to the first emission area, the second emission area, and the third emission area, respectively,
wherein each of the first light emitting element, the second light emitting element, and the third light emitting element comprises:
a first electrode;
a second electrode opposite to the first electrode;
a first emission unit provided between the first electrode and the second electrode and comprising a first emission layer;
a charge generation layer provided on the first emission unit and comprising a p-type charge generation layer and an n-type charge generation layer; and
a second emission unit provided on the charge generation layer and comprising a second emission layer,
wherein, in at least two selected from among the first light emitting element, the second light emitting element, the third light emitting element, the first emission layer and the second emission layer each comprise a first light emitting material comprising a deuterium atom.

2. The display device as claimed in claim 1, wherein:
the first light emitting element emits red light of the first color,
the second light emitting element emits green light of the second color,
the third light emitting element emits blue light of the third color,
the first emission layer and the second emission layer of the first light emitting element do not comprise the first light emitting material, and
the first emission layer and the second emission layer of each of the second light emitting element and the third light emitting element each comprise the first light emitting material.

3. The display device as claimed in claim 1, wherein the first light emitting material comprises at least one of a first compound or a second compound,
wherein the first compound comprises a deuterium atom, a carbazole moiety, and a nitrogen-containing moiety, and
wherein the second compound comprises a deuterium atom and an anthracene moiety.

4. The display device as claimed in claim 3, wherein:
the first emission layer comprises a first red emission layer, a first green emission layer, and a first blue emission layer which correspond to the first emission area, the second emission area, and the third emission area, respectively, and
the second emission layer comprises a second red emission layer, a second green emission layer, and a second blue emission layer which correspond to the first emission area, the second emission area, and the third emission area, respectively,
wherein each of the first green emission layer and the second green emission layer comprises the first compound, and
wherein each of the first blue emission layer and the second blue emission layer comprises the second compound.

5. The display device as claimed in claim 3, wherein the first compound is represented by Formula 1: 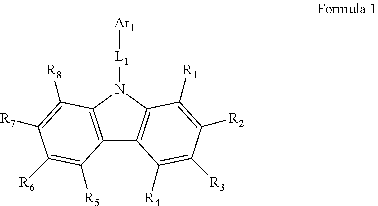
where in Formula 1,
L₁ is a direct linkage or a substituted or unsubstituted arylene group having 6 to 30 ring-forming carbon atoms,
R₁ to R₈ are each independently a hydrogen atom, a deuterium atom, a substituted or unsubstituted amine group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
Ar₁ is a substituted or unsubstituted aryl group having 6 to 30 ring-forming carbon atoms, or a substituted or unsubstituted heteroaryl group having 3 to 30 ring-forming carbon atoms, or represented by Formula 1-A,
if Ar₁ in Formula 1 is not represented by Formula 1-A, at least one selected from among Ar₁ and R₁ to R₈ is a substituted or unsubstituted heteroaryl group having 2 to 30 ring-forming carbon atoms comprising a nitrogen atom as a ring-forming atom, or comprises, as a substituent, a substituted or unsubstituted heteroaryl group having 2 to 30 ring-forming carbon atoms comprising a nitrogen atom as a ring-forming atom, and
at least one of L₁, R₁ to R₈, or Ar₁ is a deuterium atom or comprises a substituent comprising a deuterium atom, 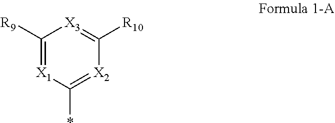
where in Formula 1-A,
at least one selected from among X₁ to X₃ is a nitrogen atom, and the remainder are CR₁₁, and
R₉ to R₁₁ are each independently a hydrogen atom, a deuterium atom, a substituted or unsubstituted amine group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

6. The display device as claimed in claim 5, wherein the first compound is represented by any one selected from among the compounds in Compound Group 1: 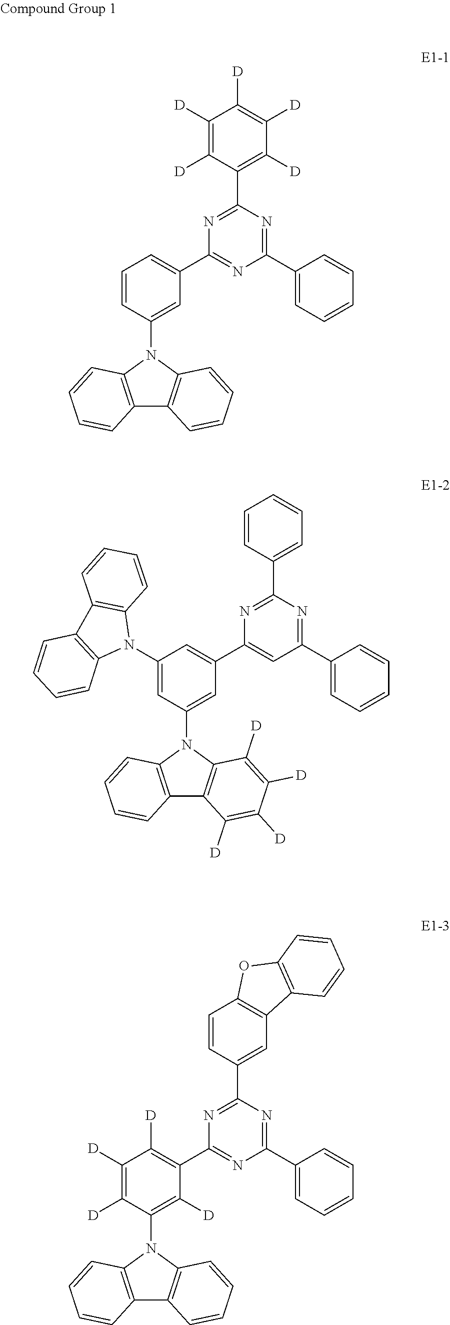 [SMILES: [2H]c1c([2H])c([2H])c(-c2nc(-c3ccccc3)nc(-c3cccc(-n4c5ccccc5c5ccccc54)c3)n2)c([2H])c1[2H] ; [2H]c1c([2H])c([2H])c2c(c1[2H])c1ccccc1n2-c1cc(-c2cc(-c3ccccc3)nc(-c3ccccc3)n2)cc(-n2c3ccccc3c3ccccc32)c1 ; [2H]c1c([2H])c(-c2nc(-c3ccccc3)nc(-c3ccc4oc5ccccc5c4c3)n2)c([2H])c(-n2c3ccccc3c3ccccc32)c1[2H]] 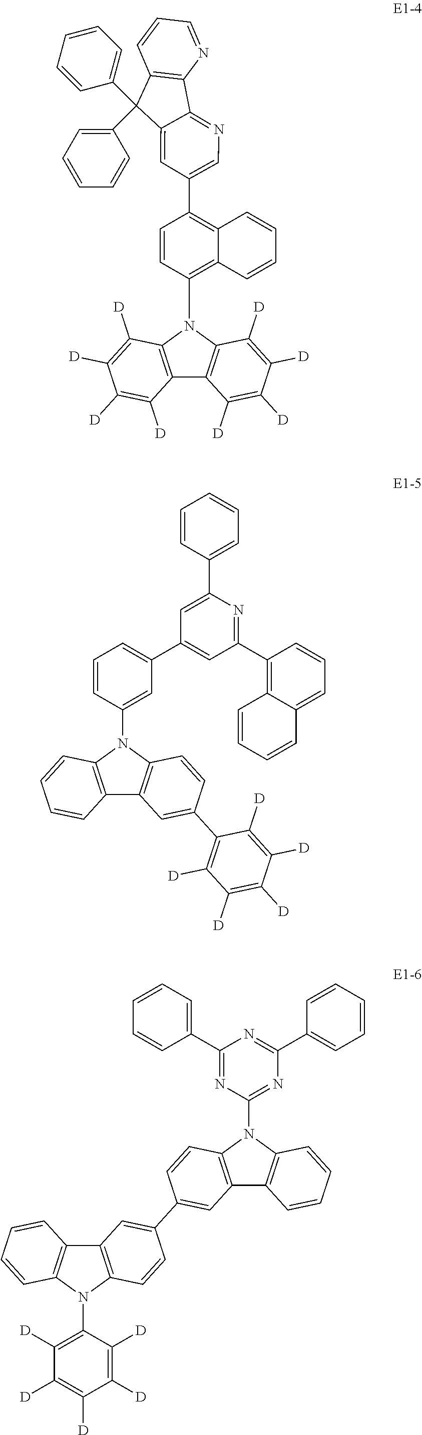 [SMILES: [2H]c1c([2H])c([2H])c2c(c1[2H])c1c([2H])c([2H])c([2H])c([2H])c1n2-c1ccc(-c2cnc3c(c2)C(c2ccccc2)(c2ccccc2)c2cccnc2-3)c2ccccc12 ; [2H]c1c([2H])c([2H])c(-c2ccc3c(c2)c2ccccc2n3-c2cccc(-c3cc(-c4ccccc4)nc(-c4cccc5ccccc45)c3)c2)c([2H])c1[2H] ; [2H]c1c([2H])c([2H])c(-n2c3ccccc3c3cc(-c4ccc5c(c4)c4ccccc4n5-c4nc(-c5ccccc5)nc(-c5ccccc5)n4)ccc32)c([2H])c1[2H]] 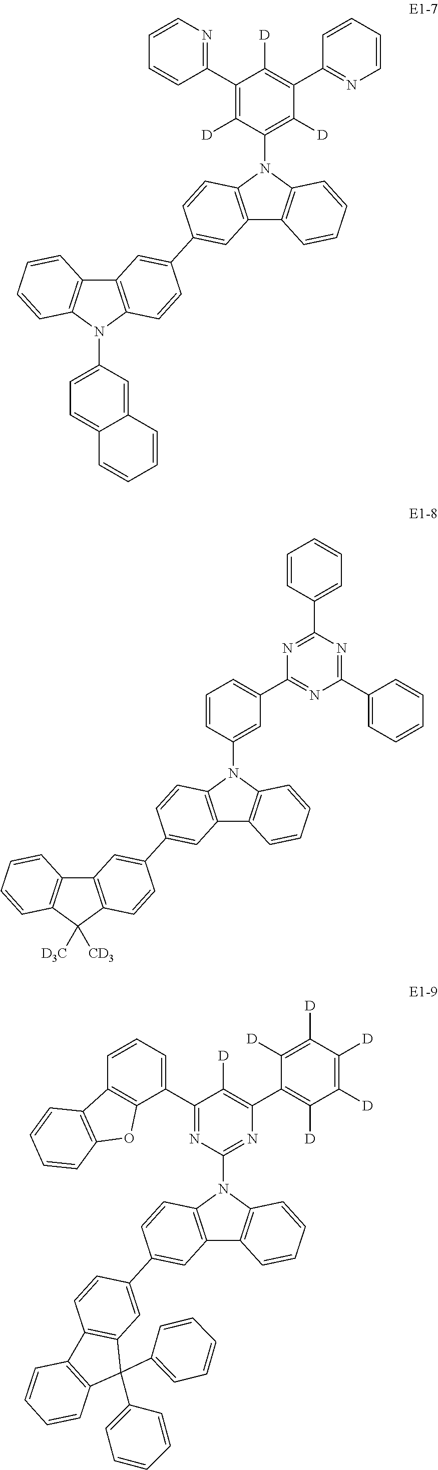 [SMILES: [2H]c1c(-c2ccccn2)c([2H])c(-n2c3ccccc3c3cc(-c4ccc5c(c4)c4ccccc4n5-c4ccc5ccccc5c4)ccc32)c([2H])c1-c1ccccn1 ; [2H]C([2H])([2H])C1(C([2H])([2H])[2H])c2ccccc2-c2cc(-c3ccc4c(c3)c3ccccc3n4-c3cccc(-c4nc(-c5ccccc5)nc(-c5ccccc5)n4)c3)ccc21 ; [2H]c1c(-c2c([2H])c([2H])c([2H])c([2H])c2[2H])nc(-n2c3ccccc3c3cc(-c4ccc5c(c4)C(c4ccccc4)(c4ccccc4)c4ccccc4-5)ccc32)nc1-c1cccc2c1oc1ccccc12] 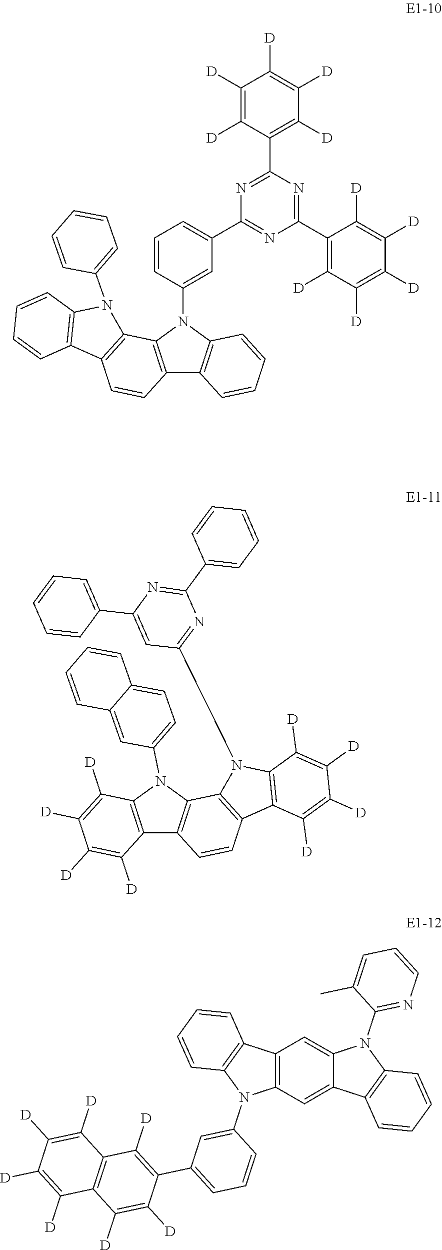 [SMILES: [2H]c1c([2H])c([2H])c(-c2nc(-c3cccc(-n4c5ccccc5c5ccc6c7ccccc7n(-c7ccccc7)c6c54)c3)nc(-c3c([2H])c([2H])c([2H])c([2H])c3[2H])n2)c([2H])c1[2H] ; [2H]c1c([2H])c([2H])c2c(c1[2H])c1ccc3c4c([2H])c([2H])c([2H])c([2H])c4n(-c4cc(-c5ccccc5)nc(-c5ccccc5)n4)c3c1n2-c1ccc2ccccc2c1 ; [2H]c1c([2H])c([2H])c2c([2H])c(-c3cccc(-n4c5ccccc5c5cc6c(cc54)c4ccccc4n6-c4ncccc4C)c3)c([2H])c([2H])c2c1[2H]] 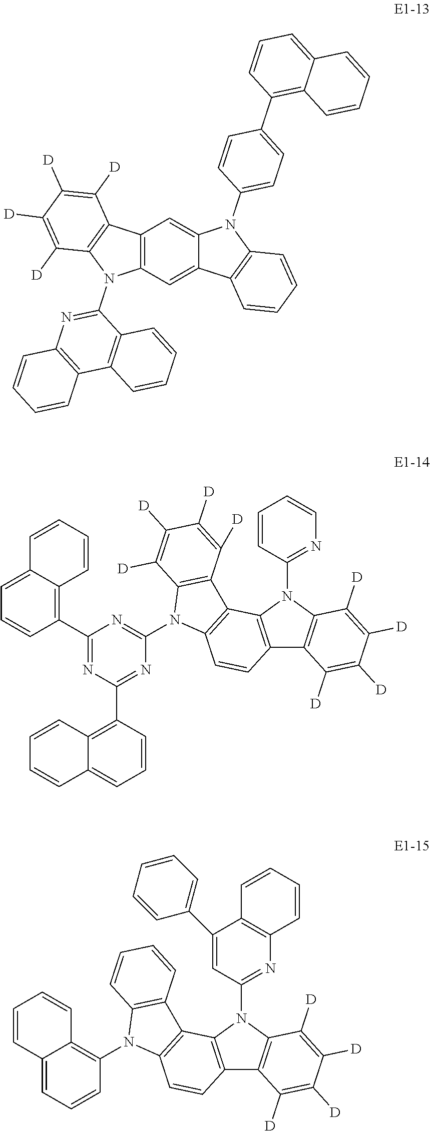 [SMILES: [2H]c1c([2H])c([2H])c2c(c1[2H])c1cc3c(cc1n2-c1nc2ccccc2c2ccccc12)c1ccccc1n3-c1ccc(-c2cccc3ccccc23)cc1 ; [2H]c1c([2H])c([2H])c2c(c1[2H])c1c(ccc3c4c([2H])c([2H])c([2H])c([2H])c4n(-c4ccccn4)c31)n2-c1nc(-c2cccc3ccccc23)nc(-c2cccc3ccccc23)n1 ; [2H]c1c([2H])c([2H])c2c(c1[2H])c1ccc3c(c4ccccc4n3-c3cccc4ccccc34)c1n2-c1cc(-c2ccccc2)c2ccccc2n1] 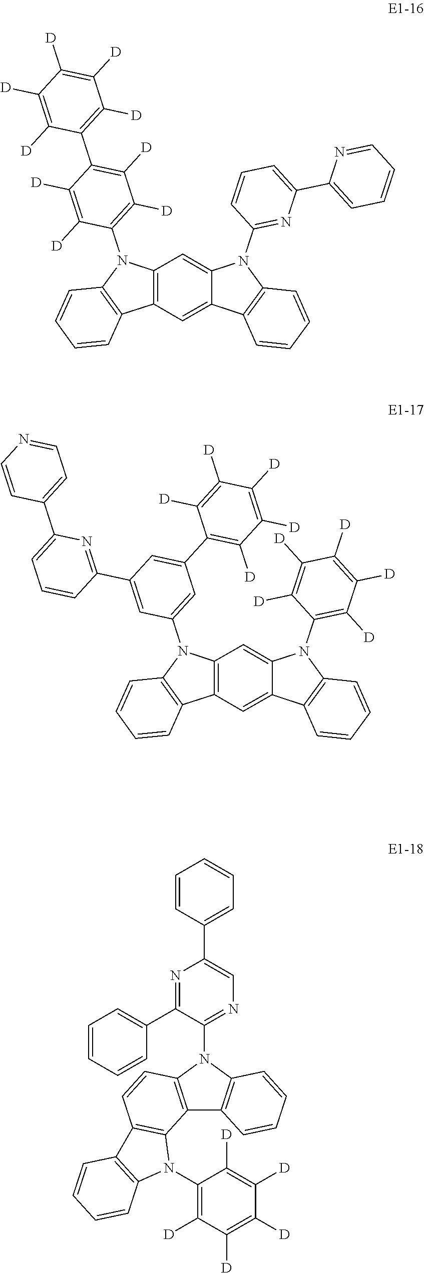 [SMILES: [2H]c1c([2H])c([2H])c(-c2c([2H])c([2H])c(-n3c4ccccc4c4cc5c6ccccc6n(-c6cccc(-c7ccccn7)n6)c5cc43)c([2H])c2[2H])c([2H])c1[2H] ; [2H]c1c([2H])c([2H])c(-c2cc(-c3cccc(-c4ccncc4)n3)cc(-n3c4ccccc4c4cc5c6ccccc6n(-c6c([2H])c([2H])c([2H])c([2H])c6[2H])c5cc43)c2)c([2H])c1[2H] ; [2H]c1c([2H])c([2H])c(-n2c3ccccc3c3ccc4c(c5ccccc5n4-c4ncc(-c5ccccc5)nc4-c4ccccc4)c32)c([2H])c1[2H]] 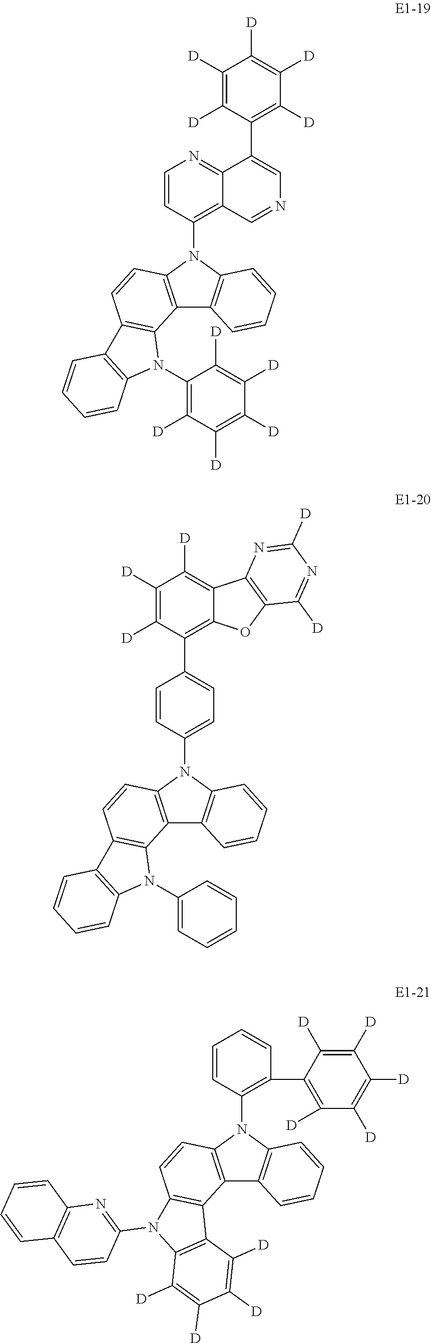 [SMILES: [2H]c1c([2H])c([2H])c(-c2cncc3c(-n4c5ccccc5c5c4ccc4c6ccccc6n(-c6c([2H])c([2H])c([2H])c([2H])c6[2H])c45)ccnc23)c([2H])c1[2H] ; [2H]c1nc([2H])c2oc3c(-c4ccc(-n5c6ccccc6c6c5ccc5c7ccccc7n(-c7ccccc7)c56)cc4)c([2H])c([2H])c([2H])c3c2n1 ; [2H]c1c([2H])c([2H])c(-c2ccccc2-n2c3ccccc3c3c4c5c([2H])c([2H])c([2H])c([2H])c5n(-c5ccc6ccccc6n5)c4ccc32)c([2H])c1[2H]] 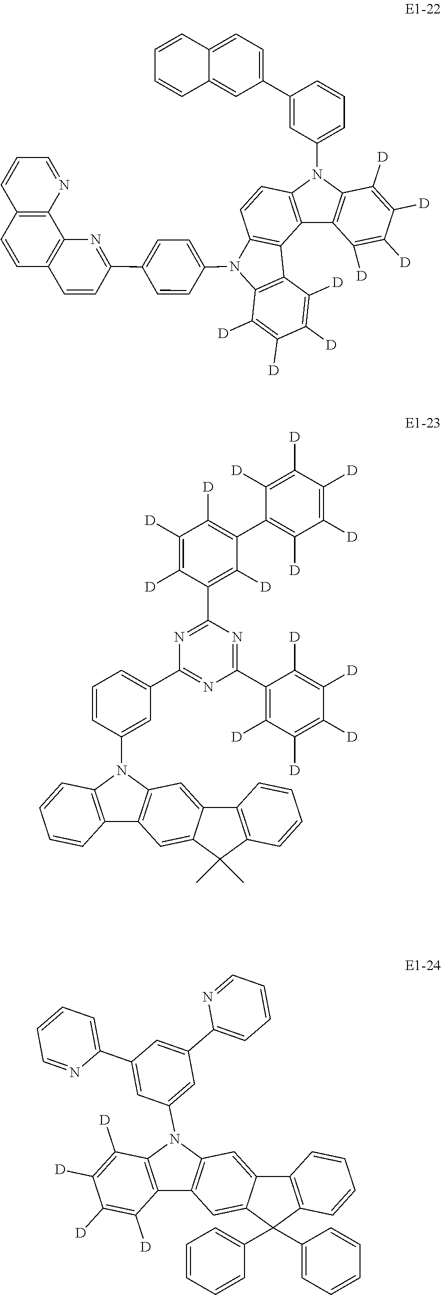 [SMILES: [2H]c1c([2H])c([2H])c2c(c1[2H])c1c3c4c([2H])c([2H])c([2H])c([2H])c4n(-c4cccc(-c5ccc6ccccc6c5)c4)c3ccc1n2-c1ccc(-c2ccc3ccc4cccnc4c3n2)cc1 ; [2H]c1c([2H])c([2H])c(-c2nc(-c3cccc(-n4c5ccccc5c5cc6c(cc54)-c4ccccc4C6(C)C)c3)nc(-c3c([2H])c([2H])c([2H])c(-c4c([2H])c([2H])c([2H])c([2H])c4[2H])c3[2H])n2)c([2H])c1[2H] ; [2H]c1c([2H])c([2H])c2c(c1[2H])c1cc3c(cc1n2-c1cc(-c2ccccn2)cc(-c2ccccn2)c1)-c1ccccc1C3(c1ccccc1)c1ccccc1] 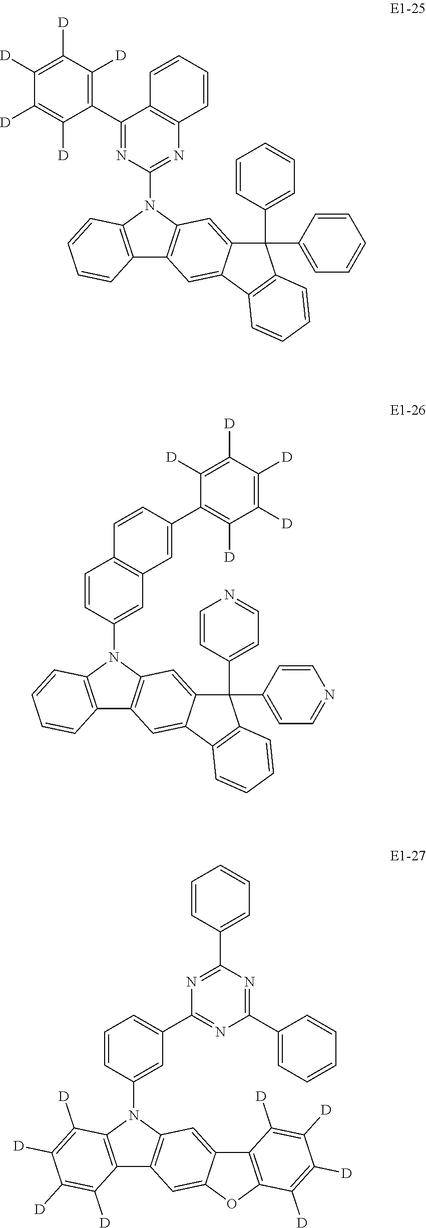 [SMILES: [2H]c1c([2H])c([2H])c(-c2nc(-n3c4ccccc4c4cc5c(cc43)C(c3ccccc3)(c3ccccc3)c3ccccc3-5)nc3ccccc23)c([2H])c1[2H] ; [2H]c1c([2H])c([2H])c(-c2ccc3ccc(-n4c5ccccc5c5cc6c(cc54)C(c4ccncc4)(c4ccncc4)c4ccccc4-6)cc3c2)c([2H])c1[2H] ; [2H]c1c([2H])c([2H])c2c(oc3cc4c5c([2H])c([2H])c([2H])c([2H])c5n(-c5cccc(-c6nc(-c7ccccc7)nc(-c7ccccc7)n6)c5)c4cc32)c1[2H]] 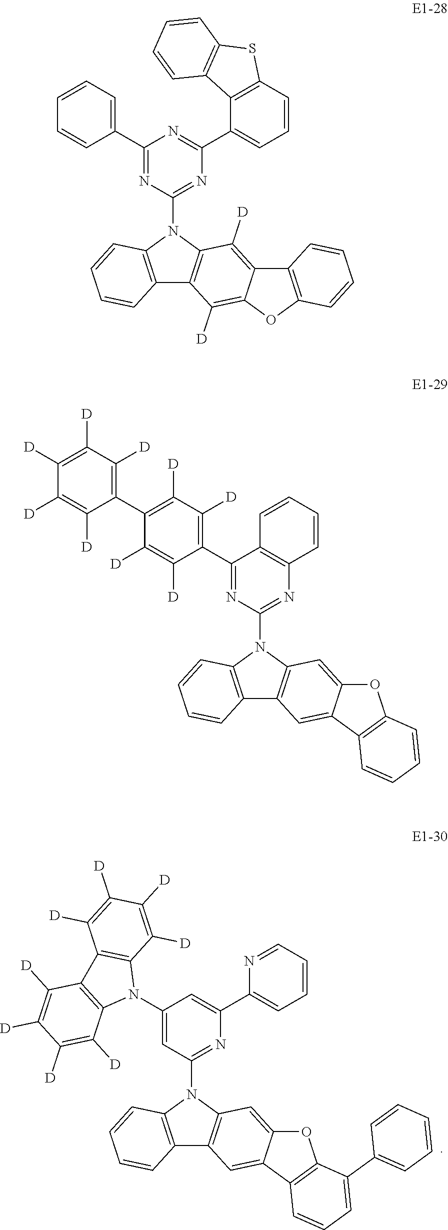 [SMILES: [2H]c1c2oc3ccccc3c2c([2H])c2c1c1ccccc1n2-c1nc(-c2ccccc2)nc(-c2cccc3sc4ccccc4c23)n1 ; [2H]c1c([2H])c([2H])c(-c2c([2H])c([2H])c(-c3nc(-n4c5ccccc5c5cc6c(cc54)oc4ccccc46)nc4ccccc34)c([2H])c2[2H])c([2H])c1[2H] ; [2H]c1c([2H])c([2H])c2c(c1[2H])c1c([2H])c([2H])c([2H])c([2H])c1n2-c1cc(-c2ccccn2)nc(-n2c3ccccc3c3cc4c(cc32)oc2c(-c3ccccc3)cccc24)c1]
where in Compound Group 1, D is a deuterium atom.

7. The display device as claimed in claim 3, wherein the second compound is represented by Formula 2: 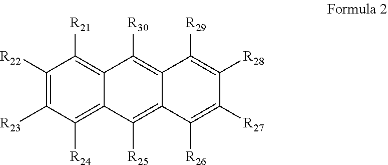
where in Formula 2,
R₂₁ to R₃₀ are each independently a hydrogen atom, a deuterium atom, a substituted or unsubstituted aryl group having 6 to 30 ring-forming carbon atoms, or a substituted or unsubstituted heteroaryl group or 5 to 30 ring-forming carbon atoms, and
at least one selected from among R₂₁ to R₃₀ is a deuterium atom or comprises a substituent comprising a deuterium atom.

8. The display device as claimed in claim 7, wherein the second compound is represented by any one selected from among the compounds in Compound Group 2: 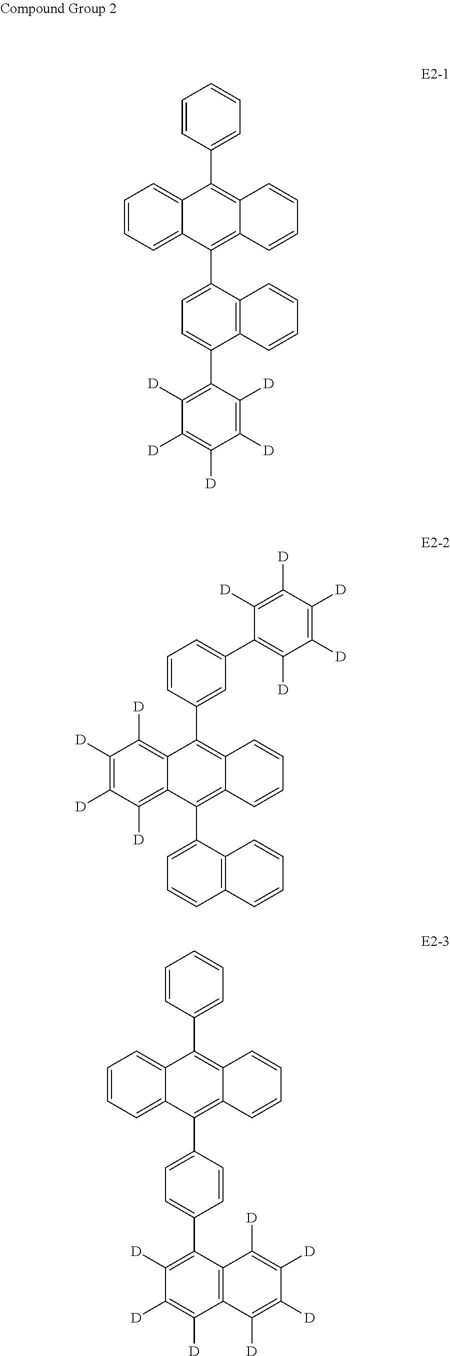 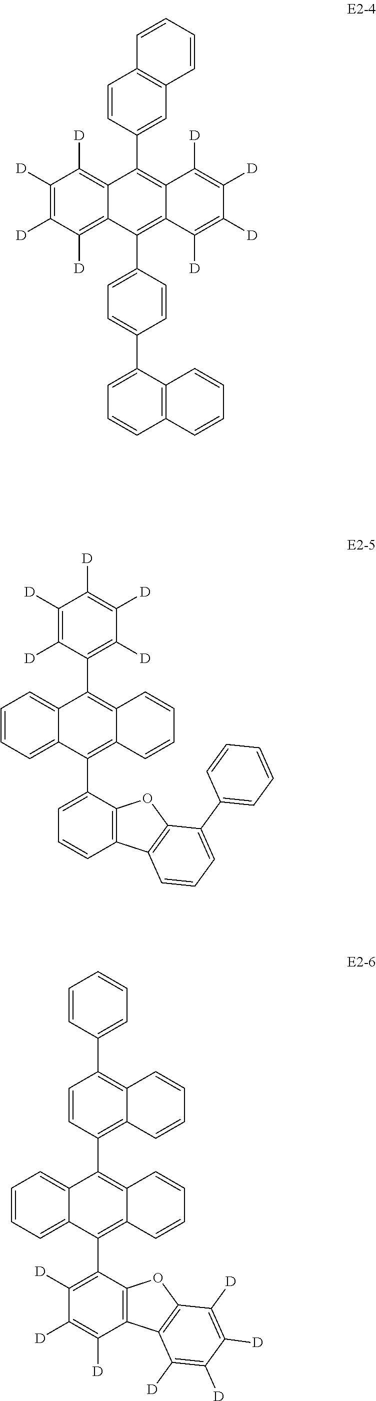 [SMILES: [2H]c1c([2H])c([2H])c2c(-c3ccc4ccccc4c3)c3c([2H])c([2H])c([2H])c([2H])c3c(-c3ccc(-c4cccc5ccccc45)cc3)c2c1[2H] ; [2H]c1c([2H])c([2H])c(-c2c3ccccc3c(-c3cccc4c3oc3c(-c5ccccc5)cccc34)c3ccccc23)c([2H])c1[2H] ; [2H]c1c([2H])c([2H])c2c(oc3c(-c4c5ccccc5c(-c5ccc(-c6ccccc6)c6ccccc56)c5ccccc45)c([2H])c([2H])c([2H])c32)c1[2H]] 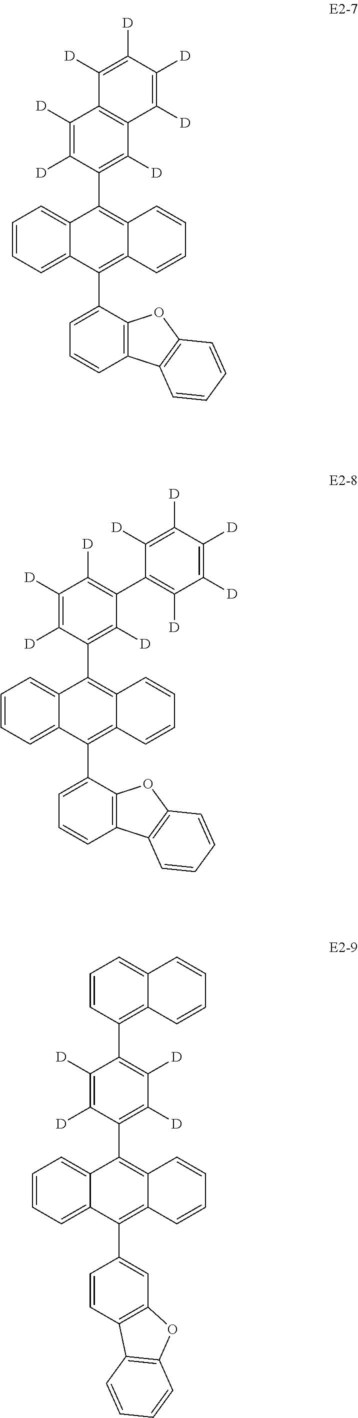 [SMILES: [2H]c1c([2H])c([2H])c2c([2H])c(-c3c4ccccc4c(-c4cccc5c4oc4ccccc45)c4ccccc34)c([2H])c([2H])c2c1[2H] ; [2H]c1c([2H])c([2H])c(-c2c([2H])c([2H])c([2H])c(-c3c4ccccc4c(-c4cccc5c4oc4ccccc45)c4ccccc34)c2[2H])c([2H])c1[2H] ; [2H]c1c([2H])c(-c2c3ccccc3c(-c3ccc4c(c3)oc3ccccc34)c3ccccc23)c([2H])c([2H])c1-c1cccc2ccccc12] 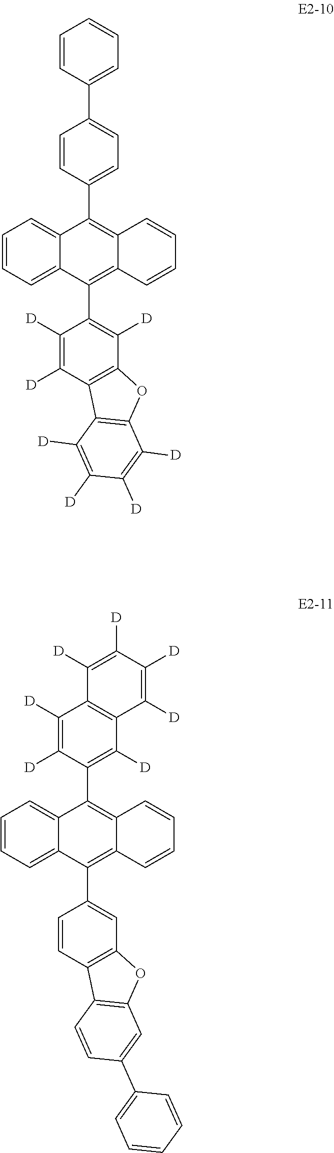 [SMILES: [2H]c1c([2H])c([2H])c2c(oc3c([2H])c(-c4c5ccccc5c(-c5ccc(-c6ccccc6)cc5)c5ccccc45)c([2H])c([2H])c32)c1[2H] ; [2H]c1c([2H])c([2H])c2c([2H])c(-c3c4ccccc4c(-c4ccc5c(c4)oc4cc(-c6ccccc6)ccc45)c4ccccc34)c([2H])c([2H])c2c1[2H]] 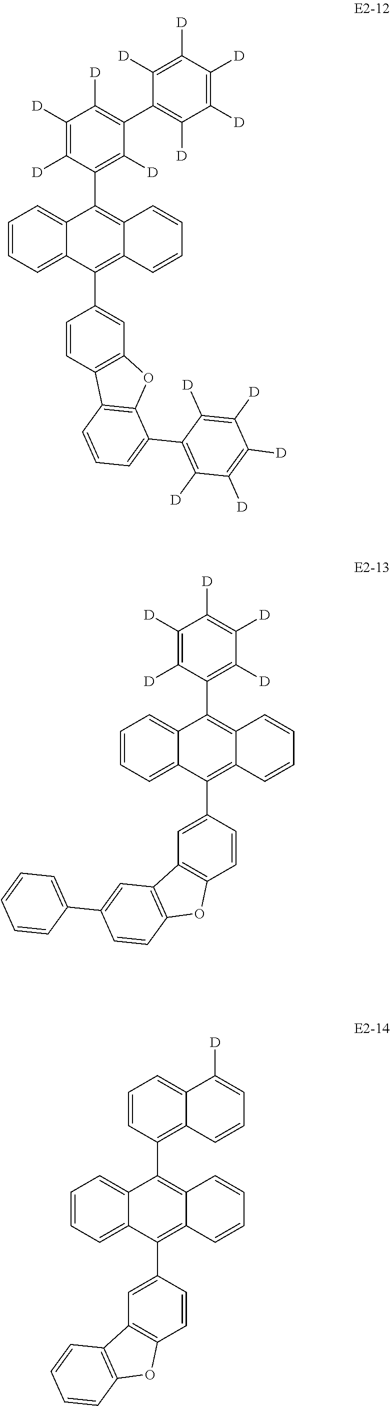 [SMILES: [2H]c1c([2H])c([2H])c(-c2c([2H])c([2H])c([2H])c(-c3c4ccccc4c(-c4ccc5c(c4)oc4c(-c6c([2H])c([2H])c([2H])c([2H])c6[2H])cccc45)c4ccccc34)c2[2H])c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H] ; [2H]c1cccc2c(-c3c4ccccc4c(-c4ccc5oc6ccccc6c5c4)c4ccccc34)cccc12] 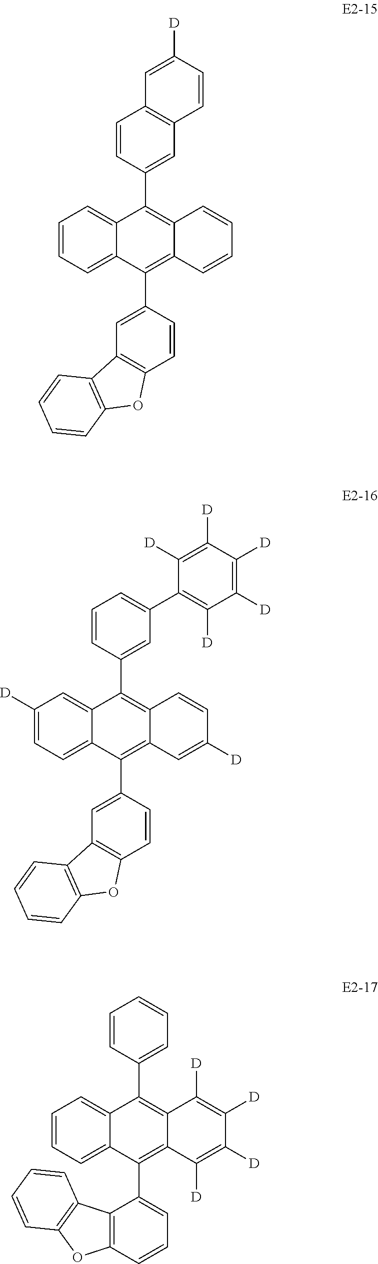 [SMILES: [2H]c1ccc2cc(-c3c4ccccc4c(-c4ccc5oc6ccccc6c5c4)c4ccccc34)ccc2c1 ; [2H]c1ccc2c(-c3ccc4oc5ccccc5c4c3)c3cc([2H])ccc3c(-c3cccc(-c4c([2H])c([2H])c([2H])c([2H])c4[2H])c3)c2c1 ; [2H]c1c([2H])c([2H])c2c(-c3cccc4oc5ccccc5c34)c3ccccc3c(-c3ccccc3)c2c1[2H]] 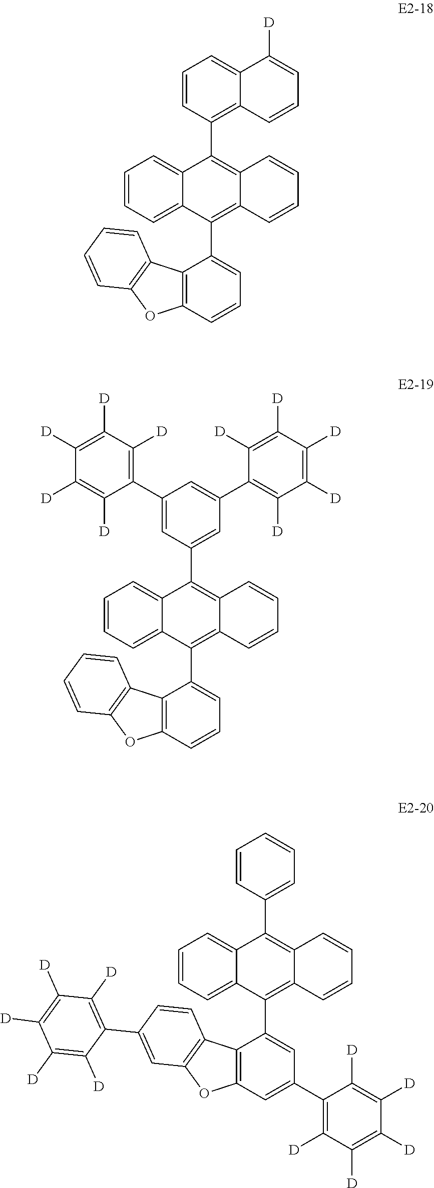 [SMILES: [2H]c1cccc2c(-c3c4ccccc4c(-c4cccc5oc6ccccc6c45)c4ccccc34)cccc12 ; [2H]c1c([2H])c([2H])c(-c2cc(-c3c([2H])c([2H])c([2H])c([2H])c3[2H])cc(-c3c4ccccc4c(-c4cccc5oc6ccccc6c45)c4ccccc34)c2)c([2H])c1[2H] ; [2H]c1c([2H])c([2H])c(-c2ccc3c(c2)oc2cc(-c4c([2H])c([2H])c([2H])c([2H])c4[2H])cc(-c4c5ccccc5c(-c5ccccc5)c5ccccc45)c23)c([2H])c1[2H]] 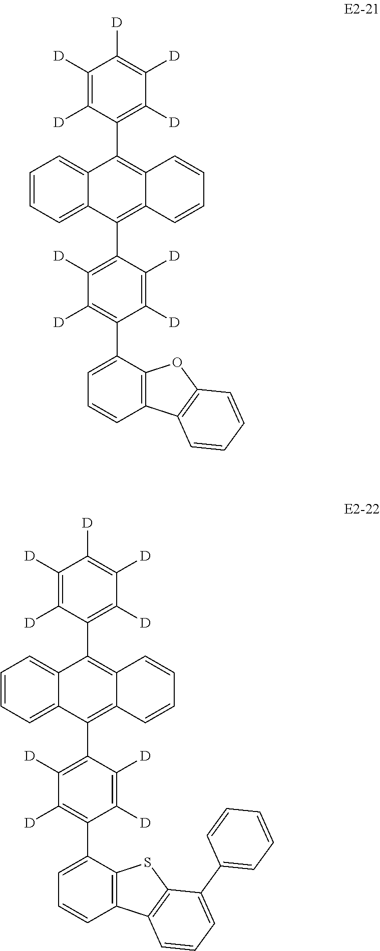 [SMILES: [2H]c1c([2H])c([2H])c(-c2c3ccccc3c(-c3c([2H])c([2H])c(-c4cccc5c4oc4ccccc45)c([2H])c3[2H])c3ccccc23)c([2H])c1[2H] ; [2H]c1c([2H])c([2H])c(-c2c3ccccc3c(-c3c([2H])c([2H])c(-c4cccc5c4sc4c(-c6ccccc6)cccc45)c([2H])c3[2H])c3ccccc23)c([2H])c1[2H]] 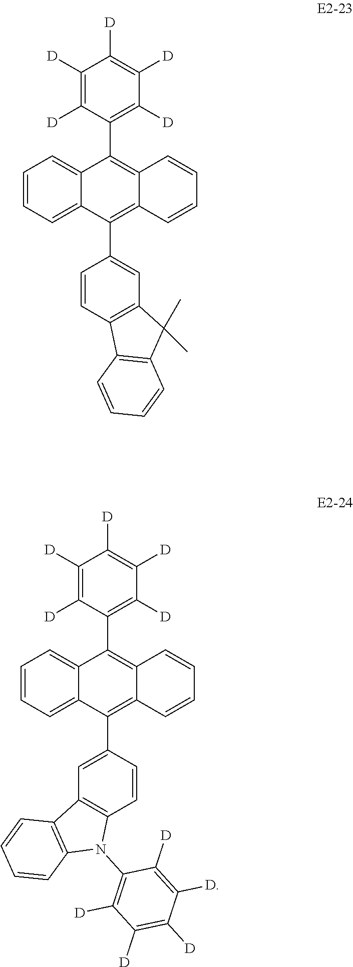
where in Compound Group 2, D is a deuterium atom.

9. The display device as claimed in claim 1, wherein:
the first emission unit further comprises:
a first hole transport region between the first electrode and the first emission layer; and
a first electron transport region between the first emission layer and the charge generation layer, and
the second emission unit further comprises:
a second hole transport region between the charge generation layer and the second emission layer; and
a second electron transport region between the second emission layer and the second electrode.

10. The display device as claimed in claim 9, wherein:
the first hole transport region comprises a first hole injection layer, a first hole transport layer, and a first emission auxiliary layer which are provided in sequence on the first electrode, and
the second hole transport region comprises a second hole transport layer and a second emission auxiliary layer which are provided in sequence on the charge generation layer.

11. The display device as claimed in claim 10,
wherein each of the first hole injection layer, the first hole transport layer, and the second hole transport layer is provided as a common layer on the first emission area, the second emission area, and the third emission area,
wherein the first emission auxiliary layer comprises a first red emission auxiliary layer, a first green emission auxiliary layer, and a first blue emission auxiliary layer which correspond to the first emission area, the second emission area, and the third emission area, respectively,
wherein the second emission auxiliary layer comprises a second red emission auxiliary layer, a second green emission auxiliary layer, and a second blue emission auxiliary layer which correspond to the first emission area, the second emission area, and the third emission area, respectively, and
wherein each of the first green emission auxiliary layer, the second green emission auxiliary layer, the first blue emission auxiliary layer, and the second blue emission auxiliary layer comprises the first light emitting material.

12. The display device as claimed in claim 11, wherein:
each of the first green emission auxiliary layer and the second green emission auxiliary layer comprises a first compound comprising a deuterium atom, a carbazole moiety, and a nitrogen-containing moiety, and
each of the first blue emission auxiliary layer and the second blue emission auxiliary layer comprise a second compound comprising a deuterium atom and an anthracene moiety.

13. The display device as claimed in claim 9, wherein:
the first electron transport region comprises a first electron transport layer, and
the second electron transport region comprises a second electron transport layer and a second electron injection layer which are provided in sequence.

14. The display device as claimed in claim 1, wherein:
the n-type charge generation layer is adjacent to the first emission unit, and
the p-type charge generation layer is adjacent to the second emission unit.

15. The display device as claimed in claim 1, wherein at least one of the first emission layer or the second emission layer further comprises at least one of a compound represented by Formula HT-1, a compound represented by Formula ET-1, or a compound represented by Formula D-1: 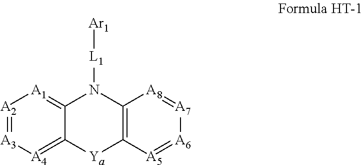
where in Formula HT-1,
A₁ to A₈ are each independently N or CR₅₁,
Yₐ is a direct linkage, CR₅₂R₅₃, or SiR₅₄R₅₅,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
Ar₁ is a substituted or unsubstituted aryl group having 6 to 30 ring-forming carbon atoms or a substituted or unsubstituted heteroaryl group having 2 to 30 ring-forming carbon atoms, and
L₁ is a direct linkage, a substituted or unsubstituted arylene group having 6 to 30 ring-forming carbon atoms, or a substituted or unsubstituted heteroarylene group having 2 to 30 ring-forming carbon atoms, 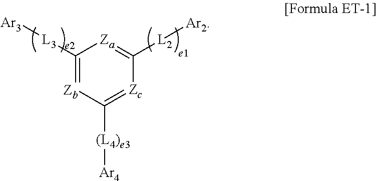
where in Formula ET-1,
at least one selected from among Zₐ to Z_{c} is N, and the remainder are CRₐ₆,
Rₐ₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
Ar_{b} to Ar_{d} are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and
b1 to b3 are each independently an integer of 0 to 10, 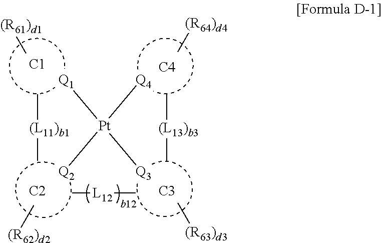
where in Formula D-1,
Q₁ to Q₄ are each independently C or N,
C₁ to C₄ are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 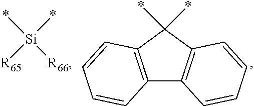
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and
d1 to d4 are each independently an integer of 0 to 4.

16. The display device as claimed in claim 1, wherein at least one of the first emission layer or the second emission layer further comprises a compound represented by any one selected from among Formulae F-a to F-c: 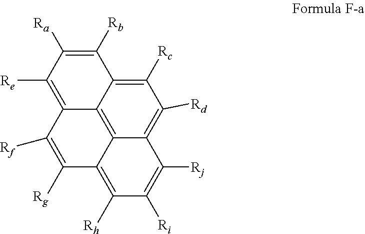
where in Formula F-a,
two selected from among Rₐ to Rⱼ are each independently substituted with *—NArₐ₁Arₐ₂, and among Rₐ to Rⱼ, the remainder unsubstituted with *—NArₐ₁Arₐ₂ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atom, and
Arₐ₁ and Arₐ₂ are each independently a substituted or unsubstituted aryl group having 6 to 30 ring-forming carbon atoms or a substituted or unsubstituted heteroaryl group having 2 to 30 ring-forming carbon atoms, 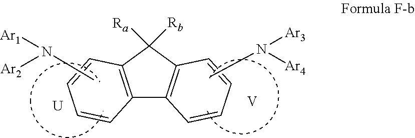
where in Formula F-b,
Rₐ₁ and R_{b1} are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring,
Ar_{b1} to Ar_{b4} are each independently a substituted or unsubstituted aryl group having 6 to 30 ring-forming carbon atoms or a substituted or unsubstituted heteroaryl group having 2 to 30 ring-forming carbon atoms, and
U and V are each independently a substituted or unsubstituted hydrocarbon ring having 5 to 30 ring-forming carbon atoms or a substituted or unsubstituted heterocycle having 2 to 30 ring-forming carbon atoms, 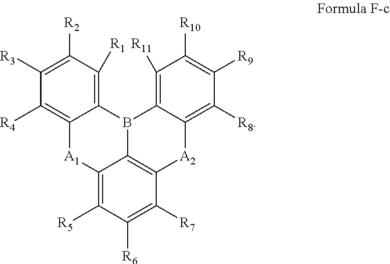
where in Formula F-c,
A₁ and A₂ are each independently O, S, Se, or NRₘ,
Rₘ is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R_{c1} to R_{c11} are each independently a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

17. A display device, comprising:
a display element layer comprising a red emission area, a green emission area, and a blue emission area which are apart from each other on a plane,
wherein the display element layer further comprises a first light emitting element, a second light emitting element, and a third light emitting element that correspond to the red emission area, the green emission area, and the blue emission area, respectively,
wherein each of the first light emitting element, the second light emitting element, and the third light emitting element comprises n emission units and n-1 charge generation layers, each of the n−1 charge generation layers is between the n emission units,
wherein n is an integer of 2 or more,
wherein each of the n emission units comprises a hole transport region, an emission layer, and an electron transport region, and
wherein each of the emission layer that corresponds to the green emission area and the emission layer that corresponds to the blue emission area comprises a first light emitting material comprising a deuterium atom.

18. The display device as claimed in claim 17, wherein:
the first light emitting material comprises at least one of:
a first compound comprising a deuterium atom, a carbazole moiety, and a nitrogen-containing moiety; or
a second compound comprising a deuterium atom and an anthracene moiety,
wherein the emission layer that corresponds to the green emission area comprises the first compound, and
wherein the emission layer that corresponds to the blue emission area comprises the second compound.

19. An electronic device comprising a display device, wherein the display device comprises:
a display element layer comprising a first emission area that emits light of a first color, a second emission area that emits light of a second color having a shorter wavelength than the first color, and a third emission area that emits light of a third color having a shorter wavelength than the second color, the first emission area, the second emission area, and the third emission area being spaced apart from each other on a plane,
wherein the display element layer further comprises a first light emitting element, a second light emitting element, and a third light emitting element that correspond to the first emission area, the second emission area, and the third emission area, respectively,
wherein each of the first light emitting element, the second light emitting element, and the third light emitting element comprises:
a first electrode;
a second electrode opposite to the first electrode;
a first emission unit provided between the first electrode and the second electrode and comprising a first emission layer;
a charge generation layer provided on the first emission unit and comprising a p-type charge generation layer and an n-type charge generation layer; and
a second emission unit provided on the charge generation layer and comprising a second emission layer,
wherein, in at least two selected from among the first light emitting element, the second light emitting element, the third light emitting element, the first emission layer and the second emission layer each comprise a first light emitting material comprising a deuterium atom.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
